(19) United States
(12) Patent Application Publication
(10) Pub. No.: US 2026/0202596 A1
(43) Pub. Date: Jul. 16, 2026

(54) CURED FILM, OPTICAL FILM, AND IMAGE DISPLAY DEVICE

(71) Applicant: FUJIFILM Corporation, Tokyo (JP)

(72) Inventors: Hio SAKAI, Minamiashigara-shi (JP); Tomonori MIMURA, Minamiashigara-shi (JP); Tadashi KAJIYA, Minamiashigara-shi (JP)

(73) Assignee: FUJIFILM Corporation, Tokyo (JP)

(21) Appl. No.: 19/561,578

(22) Filed: Mar. 10, 2026

Related U.S. Application Data
(63) Continuation of application No. PCT/JP2024/033027, filed on Sep. 17, 2024.

(30) Foreign Application Priority Data
Sep. 29, 2023 (JP) 2023-169767
Apr. 5, 2024 (JP) 2024-061365

(51) Int. Cl. G02B 5/30; C09K 19/04; C09K 19/20; C09K 19/30; C09K 19/34; G02F 1/1335; H10K 59/80

(52) U.S. Cl. CPC G02B 5/3016; C09K 19/04; C09K 19/2007; C09K 19/3068; C09K 19/3405; C09K 19/3491; G02B 5/305; G02F 1/133528; H10K 59/8793; C09K 2019/0448; C09K 2019/2078; C09K 2019/3075; C09K 2019/3077; C09K 2019/3408; C09K 2219/03

(57) ABSTRACT

An object of the present invention is to provide a cured film, an optical film, and an image display device, in which adhesiveness to an adjacent layer provided on a surface opposite to a substrate is excellent. The cured film of the present invention is provided on a substrate, and is a film obtained by curing a composition containing a leveling agent containing a silicon atom and a polymerizable compound, in which a surface elastic modulus on a surface of the cured film opposite to the substrate is more than 3.0 GPa.

### CROSS-REFERENCE TO RELATED APPLICATIONS

This application is a Continuation of PCT International Application No. PCT/JP2024/033027 filed on Sep. 17, 2024, which claims priority under 35 U.S.C. § 119(a) to Japanese Patent Application No. 2023-169767 filed on Sep. 29, 2023 and Japanese Patent Application No. 2024-061365 filed on Apr. 5, 2024. The above applications are hereby expressly incorporated by reference, in their entirety, into the present application.

### BACKGROUND OF THE INVENTION

### 1. Field of the Invention

The present invention relates to a cured film, an optical film, and an image display device.

### 2. Description of the Related Art

Optical films such as an optical compensation sheet and a retardation film have been used in various image display devices in order to eliminate image coloration or widen a viewing angle.

A stretched birefringent film has been used as the optical film, but in recent years, it has been proposed to use an optical film having a liquid crystal cured layer instead of the stretched birefringent film.

As such a liquid crystal cured layer, for example, WO2021/193825A discloses an optically anisotropic layer obtained by curing a polymerizable liquid crystal composition which contains a rod-like liquid crystal compound, a monofunctional compound, and a leveling agent, and fixing an alignment state of the rod-like liquid crystal compound (see, for example, Claim 1, [0090], [0145], and the like).

### SUMMARY OF THE INVENTION

In recent years, use of perfluoroalkyl compounds and polyfluoroalkyl compounds (PFAS) has been restricted due to the difficulty in decomposition and toxicity, and an alternative material that does not use a fluorine atom as a leveling agent, typically, an alternative material containing a silicon atom, has been studied.

The present inventors have studied the optically anisotropic layer and the like of the known cured film disclosed in WO2021/193825A, and as a result, it has been clarified that, in the cured film provided on a substrate, the cured film obtained by curing a composition containing a leveling agent containing a silicon atom and a polymerizable compound has room for improvement in adhesiveness to an adjacent layer provided on a surface of the cured film opposite to the substrate, that is, a surface of the cured film on an air-interface side where the leveling agent is unevenly distributed.

Therefore, an object of the present invention is to provide a cured film, an optical film, and an image display device, in which adhesiveness to an adjacent layer provided on a surface opposite to a substrate is excellent.

As a result of intensive studies to achieve the above-described object, the present inventors have found that the adhesiveness to the adjacent layer provided on the surface opposite to the substrate is improved by setting a surface elastic modulus on a surface of the cured film opposite to the substrate to be more than 3.0 GPa, and have completed the present invention.

That is, the present inventors have found that the above-described object can be achieved by employing the following configurations.

[1]A cured film which is provided on a substrate, and is a film obtained by curing a composition containing a leveling agent containing a silicon atom and a polymerizable compound,
in which a surface elastic modulus on a surface of the cured film opposite to the substrate is more than 3.0 GPa.

[2] The cured film according to [1],
in which the surface elastic modulus is less than 9.0 GPa.

[3] The cured film according to [1] or [2],
in which the surface elastic modulus is 4.0 GPa or more and 6.0 GPa or less.

[4] The cured film according to any one of [1] to [3],
in which the leveling agent is a copolymer having a repeating unit A containing a silicon atom and a repeating unit B containing a polymerizable group.

[5] The cured film according to [4],
in which a mass ratio of a content a of the repeating unit A to a content b of the repeating unit B satisfies the following expression (A),

$$1. 2 < a / b < 3.4 . \qquad ( A )$$

[6] The cured film according to [4] or [5],
in which the copolymer further has a repeating unit C containing a mesogen group.

[7] The cured film according to [6],
in which the repeating unit C further contains a functional group capable of forming a covalent bond complex with a hydroxyl group.

[8] The cured film according to [6] or [7],
in which, with respect to a total mass of the copolymer, a content a of the repeating unit A is 50% to 60% by mass, a content b of the repeating unit B is 24% to 34% by mass, and a content c of the repeating unit C is 11% to 21% by mass.

[9] The cured film according to any one of [1] to [8],
in which a weight-average molecular weight of the leveling agent is 15,000 or more and 40,000 or less.

[10] The cured film according to any one of [1] to [9],
in which a content of the leveling agent is 0.1 parts by mass or more and 2 parts by mass or less with respect to 100 parts by mass of the polymerizable compound.

[11] The cured film according to any one of [1] to [10],
in which the polymerizable compound is a polymerizable liquid crystal compound.

[12] The cured film according to [11],
in which the cured film is a film obtained by immobilizing the polymerizable liquid crystal compound in a vertically aligned state.

[13] The cured film according to [11] or [12],
in which the polymerizable liquid crystal compound is a compound represented by Formula (I) described later.

[14] The cured film according to [13],
in which Ar in Formula (I) represents any aromatic ring selected from the group consisting of groups represented by Formulae (Ar-1) to (Ar-5) described later.

[15] The cured film according to any one of [11] to [14],
in which the polymerizable liquid crystal compound is a rod-like liquid crystal compound, and
a difference Δn in refractive index between a major axis direction and a minor axis direction of the rod-like liquid crystal compound satisfies an expression (II) described later.

[16] The cured film according to any one of [1] to [15],
in which E¹⁰⁰ (unit: kPa) representing a surface elastic modulus of the following composition S1 containing the leveling agent and E⁵⁰ (unit: kPa) representing a surface elastic modulus of the following composition S2 containing the leveling agent satisfy an expression (P) described later.

[17] An optical film comprising:
the cured film according to any one of [1] to [16].

[18] An image display device comprising:
the optical film according to [17].

[19] The image display device according to [18],
in which the image display device is a liquid crystal display device.

[20] The image display device according to [18],
in which the image display device is an organic electroluminescent display device.

According to the present invention, it is possible to provide a cured film, an optical film, and an image display device, in which adhesiveness to an adjacent layer provided on a surface opposite to a substrate is excellent.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Any numerical range expressed using “to” in the present specification refers to a range including the numerical values before and after the “to” as a lower limit value and an upper limit value, respectively.

In addition, in a range of numerical values described in stages in the present specification, the upper limit value or the lower limit value described in a certain range of numerical values may be replaced with an upper limit value or a lower limit value of the range of numerical values described in other stages. In addition, regarding the numerical range described in the present specification, an upper limit value or a lower limit value described in a numerical value may be replaced with a value described in Examples.

In addition, in the present specification, substances corresponding to respective components may be used alone or in combination of two or more kinds thereof. Here, in a case where two or more kinds of substances are used in combination for each component, the content of the component indicates the total content of the substances used in combination, unless otherwise specified.

In addition, in the present specification, “(meth)acrylate” denotes “acrylate” or “methacrylate”, “(meth)acryl” denotes “acryl” or “methacryl”, and “(meth)acryloyl” denotes “acryloyl” or “methacryloyl”.

In addition, in the present specification, a bonding direction of a divalent group (for example, —O—CO—) described is not particularly limited, and for example, in a case where L² in an “L¹-L²-L³” bond is —O—CO—, and a bonding position on the L¹ side is represented by *1 and a bonding position on the L³ side is represented by *2, L² may be *1-O—CO—*2 or *1-CO—O—*2.

In the present specification, Re(λ) and Rth(λ) respectively represent an in-plane retardation at a wavelength λ and a thickness-direction retardation at a wavelength λ. Unless otherwise specified, the wavelength λ refers to 550 nm.

In addition, in the present specification, Re(λ) and Rth(λ) are values measured at a wavelength λ using AxoScan OPMF-1 (manufactured by Optoscience, Inc.).

Specifically, by inputting an average refractive index ((nx+ny+nz)/3) and a film thickness (d (μm)) to AxoScan OPMF-1, it is possible to calculate:
a slow axis direction (°);

$$Re ( λ ) = R 0 ( λ ) ; and$$

$$Rth ( λ ) = ( ( n x + n y ) / 2 - nz ) \times d$$

are calculated.

In addition, R0(λ) is expressed in a numerical value calculated with AxoScan OPMF-1, and means Re(λ).

In the present specification, examples of a substituent (monovalent substituent) include substituents described in the following substituent group A.

In the present specification, “may have a substituent” includes not only an aspect of not having a substituent but also an aspect of having one or more substituents.

### <Substituent Group A>

Examples of the substituent include:
a halogen atom (for example, a fluorine atom, a chlorine atom, or a bromine atom, preferably a chlorine atom or a fluorine atom, and more preferably a fluorine atom);
an alkyl group (a linear, branched, or cyclic alkyl group having preferably 1 to 48 carbon atoms, more preferably 1 to 24 carbon atoms, and particularly preferably 1 to 8 carbon atoms, such as a linear alkyl group having 1 to 6 carbon atoms (for example, a methyl group, an ethyl group, a n-propyl group, a n-butyl group, a n-pentyl group, and a n-hexyl group), a branched alkyl group having 3 to 6 carbon atoms (for example, an isopropyl group, an isobutyl group, a tert-butyl group, a sec-butyl group, a neopentyl group, an isohexyl group, and a 3-methylpentyl group), and a cyclic alkyl group having 3 to 12 carbon atoms (for example, a cyclopropyl group, a cyclopentyl group, a cyclohexyl group, a 1-norbornyl group, and a 1-adamantyl group));
an alkenyl group (an alkenyl group having preferably 2 to 48 carbon atoms and more preferably 2 to 18 carbon atoms, such as a vinyl group, an allyl group, a 1-butenyl group, and a 2-butenyl group);
an alkynyl group (an alkynyl group having preferably 2 to 6 carbon atoms and more preferably 2 to 4 carbon atoms, such as an ethynyl group, a 1-propynyl group, a propargyl group, a 1-butynyl group, and a 2-butynyl group);
an aryl group (an aryl group having preferably 6 to 48 carbon atoms and more preferably 6 to 24 carbon atoms, such as a phenyl group, an oligoaryl group (a naphthyl group or an anthryl group), a phenanthrenyl group, a fluorenyl group, a pyrenyl group, a triphenylenyl group, and a biphenyl group);
a heteroaryl group (a heterocyclic group having preferably 1 to 32 carbon atoms and more preferably 1 to 18 carbon atoms, such as a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group);
an arylalkyl group (an arylalkyl group having preferably 7 to 15 carbon atoms, such as a benzyl group, a phenethyl group, a methylbenzyl group, a phenylpropyl group, a 1-methylphenylethyl group, a phenylbutyl group, a 2-methylphenylpropyl group, a tetrahydronaphthyl group, a naphthylmethyl group, a naphthylethyl group, an indenyl group, a fluorenyl group, an anthracenylmethyl group (an anthrylmethyl group), and a phenanthrenylmethyl group (a phenanthrylmethyl group));
a silyl group (a silyl group having preferably 3 to 38 carbon atoms and more preferably 3 to 18 carbon atoms, such as a trimethylsilyl group, a triethylsilyl group, a tributylsilyl group, a t-butyldimethylsilyl group, and a t-hexyldimethylsilyl group);
a hydroxy group; a cyano group; a nitro group; a morpholino group;
an alkoxy group (an alkoxy group having preferably 1 to 48 carbon atoms and more preferably 1 to 24 carbon atoms, such as a methoxy group, an ethoxy group, a 1-butoxy group, a 2-butoxy group, an isopropoxy group, a t-butoxy group, a dodecyloxy group, and a cycloalkyloxy group (for example, a cyclopentyloxy group or a cyclohexyloxy group));
an aryloxy group (an aryloxy group having preferably 6 to 48 carbon atoms and more preferably 6 to 24 carbon atoms, such as a phenoxy group and a 1-naphthoxy group);
an alkenyloxy group (an alkenyloxy group having preferably 2 to 6 carbon atoms, such as a vinyloxy group, a 1-propenyloxy group, a 2-n-propenyloxy group (an allyloxy group), a 1-n-butenyloxy group, and a prenyloxy group);
a heterocyclic oxy group (a heterocyclic oxy group having preferably 1 to 32 carbon atoms and more preferably 1 to 18 carbon atoms, such as a 1-phenyltetrazol-5-yloxy group and a 2-tetrahydropyranyloxy group);
a silyloxy group (a silyloxy group having preferably 1 to 32 carbon atoms and more preferably 1 to 18 carbon atoms, such as a trimethylsilyloxy group, a t-butyldimethylsilyloxy group, and a diphenylmethylsilyloxy group);
an acyloxy group (an acyloxy group having preferably 2 to 48 carbon atoms and more preferably 2 to 24 carbon atoms, such as an acetoxy group, a pivaloyloxy group, a benzoyloxy group, a dodecanoyloxy group, an acryloyloxy group, and a methacryloyloxy group);
a hydroxyalkyleneoxy group (a hydroxyalkyleneoxy group having preferably 2 to 10 carbon atoms, such as a hydroxyethyleneoxy group);
an alkoxycarbonyloxy group (an alkoxycarbonyloxy group having preferably 2 to 48 carbon atoms and more preferably 2 to 24 carbon atoms, such as an ethoxycarbonyloxy group, a t-butoxycarbonyloxy group, and a cycloalkyloxycarbonyloxy group (for example, a cyclohexyloxycarbonyloxy group));
an aryloxycarbonyloxy group (an aryloxycarbonyloxy group having preferably 7 to 32 carbon atoms and more preferably 7 to 24 carbon atoms, such as a phenoxycarbonyloxy group);
a carbamoyloxy group (a carbamoyloxy group having preferably 1 to 48 carbon atoms and more preferably 1 to 24 carbon atoms, such as an N,N-dimethylcarbamoyloxy group, an N-butylcarbamoyloxy group, an N-phenylcarbamoyloxy group, and an N-ethyl-N-phenylcarbamoyloxy group);
a sulfamoyloxy group (a sulfamoyloxy group having preferably 1 to 32 carbon atoms and more preferably 1 to 24 carbon atoms, such as an N,N-diethylsulfamoyloxy group and an N-propylsulfamoyloxy group);
an alkylsulfonyloxy group (an alkylsulfonyloxy group having preferably 1 to 38 carbon atoms and more preferably 1 to 24 carbon atoms, such as a methylsulfonyloxy group, a hexadecylsulfonyloxy group, and a cyclohexylsulfonyloxy group);
an arylsulfonyloxy group (an arylsulfonyloxy group having preferably 6 to 32 carbon atoms and more preferably 6 to 24 carbon atoms, such as a phenylsulfonyloxy group);
an acyl group (an acyl group having preferably 1 to 48 carbon atoms and more preferably 1 to 24 carbon atoms, such as a formyl group, an acetyl group, an acryloyl group, a methacryloyl group, a pivaloyl group, a benzoyl group, a tetradecanoyl group, and a cyclohexanoyl group);
an alkoxycarbonyl group (an alkoxycarbonyl group having preferably 2 to 48 carbon atoms and more preferably 2 to 24 carbon atoms, such as a methoxycarbonyl group, an ethoxycarbonyl group, an octadecyloxycarbonyl group, a cyclohexyloxycarbonyl group, and a 2,6-di-tert-butyl-4-methylcyclohexyloxycarbonyl group);
an aryloxycarbonyl group (an aryloxycarbonyl group having preferably 7 to 32 carbon atoms and more preferably 7 to 24 carbon atoms, such as a phenoxycarbonyl group);
a carbamoyl group (a carbamoyl group having preferably 1 to 48 carbon atoms and more preferably 1 to 24 carbon atoms, such as a carbamoyl group, an N,N-diethylcarbamoyl group, an N-ethyl-N-octylcarbamoyl group, an N,N-dibutylcarbamoyl group, an N-propylcarbamoyl group, an N-phenylcarbamoyl group, an N-methyl-N-phenylcarbamoyl group, and an N,N-dicyclohexylcarbamoyl group);
an amino group (an amino group having preferably 32 or less carbon atoms and more preferably 24 or less carbon atoms, such as an amino group, a methylamino group, an N,N-dimethylamino group, an N,N-dibutylamino group, a tetradecylamino group, a 2-ethylhexylamino group, and a cyclohexylamino group);
an anilino group (an anilino group having preferably 6 to 32 carbon atoms and more preferably 6 to 24 carbon atoms, such as an anilino group and an N-methylanilino group);
a heterocyclic amino group (a heterocyclic amino group having preferably 1 to 32 carbon atoms and more preferably 1 to 18 carbon atoms, such as a 4-pyridylamino group);
a carboxamide group (a carboxamide group having preferably 2 to 48 carbon atoms and more preferably 2 to 24 carbon atoms, such as an acetamide group, a benzamide group, a tetradecaneamide group, a pivaloylamide group, and a cyclohexaneamide group);
a ureido group (a ureido group having preferably 1 to 32 carbon atoms and more preferably 1 to 24 carbon atoms, such as a ureido group, an N,N-dimethylureido group, and an N-phenylureido group);
an imide group (an imide group having preferably 36 or less carbon atoms and more preferably 24 or less carbon atoms, such as an N-succinimide group and an N-phthalimide group);
an alkoxycarbonylamino group (an alkoxycarbonylamino group having preferably 2 to 48 carbon atoms and more preferably 2 to 24 carbon atoms, such as a methoxycarbonylamino group, an ethoxycarbonylamino group, a t-butoxycarbonylamino group, an octadecyloxycarbonylamino group, and a cyclohexyloxycarbonylamino group);
an aryloxycarbonylamino group (an aryloxycarbonylamino group having preferably 7 to 32 carbon atoms and more preferably 7 to 24 carbon atoms, such as a phenoxycarbonylamino group);
a sulfonamide group (a sulfonamide group having preferably 1 to 48 carbon atoms and more preferably 1 to 24 carbon atoms, such as a methanesulfonamide group, a butanesulfonamide group, a benzenesulfonamide group, a hexadecanesulfonamide group, and a cyclohexanesulfonamide group);
a sulfamoylamino group (a sulfamoylamino group having preferably 1 to 48 carbon atoms and more preferably 1 to 24 carbon atoms, such as an N,N-dipropylsulfamoylamino group and an N-ethyl-N-dodecylsulfamoylamino group);
an azo group (an azo group having preferably 1 to 32 carbon atoms and more preferably 1 to 24 carbon atoms, such as a phenylazo group and a 3-pyrazolylazo group);
an alkylthio group (an alkylthio group having preferably 1 to 48 carbon atoms and more preferably 1 to 24 carbon atoms, such as a methylthio group, an ethylthio group, an octylthio group, and a cyclohexylthio group);
an arylthio group (an arylthio group having preferably 6 to 48 carbon atoms and more preferably 6 to 24 carbon atoms, such as a phenylthio group);
a heterocyclic thio group (a heterocyclic thio group having preferably 1 to 32 carbon atoms and more preferably 1 to 18 carbon atoms, such as a 2-benzothiazolylthio group, a 2-pyridylthio group, and a 1-phenyltetrazolylthio group);
an alkylsulfinyl group (an alkylsulfinyl group having preferably 1 to 32 carbon atoms and more preferably 1 to 24 carbon atoms, such as a dodecanesulfinyl group);
an arylsulfinyl group (an arylsulfinyl group having preferably 6 to 32 carbon atoms and more preferably 6 to 24 carbon atoms, such as a phenylsulfinyl group);
an alkylsulfonyl group (an alkylsulfonyl group having preferably 1 to 48 carbon atoms and more preferably 1 to 24 carbon atoms, such as a methylsulfonyl group, an ethylsulfonyl group, a propylsulfonyl group, a butylsulfonyl group, an isopropylsulfonyl group, a 2-ethylhexylsulfonyl group, a hexadecylsulfonyl group, an octylsulfonyl group, and a cyclohexylsulfonyl group);
an arylsulfonyl group (an arylsulfonyl group having preferably 6 to 48 carbon atoms and more preferably 6 to 24 carbon atoms, such as a phenylsulfonyl group and a 1-naphthylsulfonyl group);
a sulfamoyl group (a sulfamoyl group having preferably 32 or less carbon atoms and more preferably 24 or less carbon atoms, such as a sulfamoyl group, an N,N-dipropylsulfamoyl group, an N-ethyl-N-dodecylsulfamoyl group, an N-ethyl-N-phenylsulfamoyl group, an N-cyclohexylsulfamoyl group, and an N-(2-ethylhexyl)sulfamoyl group);
a phosphonyl group (a phosphonyl group having preferably 1 to 32 carbon atoms and more preferably 1 to 24 carbon atoms, such as a phenoxyphosphonyl group, an octyloxyphosphonyl group, and a phenylphosphonyl group);
a phosphinoylamino group (a phosphinoylamino group having preferably 1 to 32 carbon atoms and more preferably 1 to 24 carbon atoms, such as a diethoxyphosphinoylamino group and a dioctyloxyphosphinoylamino group);
an epoxy group; —NHCOCH₃; —SO₂NHC₂H₄OCH₃; and —NHSO₂CH₃,
in which two or more thereof may be combined.

These substituents may be further substituted with these substituents. In addition, in a case of having two or more of the substituents, the substituents may be the same or different from each other. Furthermore, if possible, these substituents may be bonded to each other to form a ring.

### [Cured Film]

The cured film according to the embodiment of the present invention is provided on a substrate, and is a film obtained by curing a composition containing a leveling agent containing a silicon atom and a polymerizable compound.

In addition, in the cured film according to the embodiment of the present invention, a surface elastic modulus (hereinafter, also abbreviated as “surface elastic modulus (X)”) on a surface opposite to the substrate (hereinafter, also abbreviated as “surface X”) is more than 3.0 GPa.

The substrate on which the cured film according to the embodiment of the present invention is provided will be described in the optical film according to the embodiment of the present invention described later.

Here, the surface elastic modulus (X) can be measured on the surface X of the cured film with atomic force microscopy (AFM); but in the present invention, a value of the surface elastic modulus calculated by performing fitting according to a JKR contact mechanics model on a load-displacement curve obtained under the following conditions is adopted.
Probe: distal end curvature radius of 12 nm or less, spring constant of 20 to 80 N/m
Mode: Peak Force Tapping, 1 to 2 kHz
Maximum load: 100 nN
Penetration depth: <10 nm

In the present invention, as described above, adhesiveness to an adjacent layer provided on the surface X of the cured film is improved by setting the surface elastic modulus (X) on the surface X of the cured film to be more than 3.0 GPa.

The reason why the effect is exhibited is not clear in detail, but the present inventors have presumed the following.

First, the known example corresponding to Comparative Example 1 described later, that is, WO2021/193825A has deteriorated adhesiveness to the adjacent layer provided on the surface X of the cured film. This is considered to result from the following: as shown in Comparative Example 1 described later, since the surface elastic modulus (X) on the surface X of the cured film is less than 3.0 GPa, a surface layer region of the cured film opposite to the substrate is softer than other regions, which causes stress concentration due to a difference in hardness, and thus the adjacent layer is easily peeled off.

Therefore, in the present invention, it is considered that the adhesiveness to the adjacent layer provided on the surface X is improved because the stress concentration due to the difference in hardness in the cured film is relaxed by setting the surface elastic modulus (λ) on the surface X of the cured film to be more than 3.0 GPa, and thus the peeling is less likely to occur.

In the present invention, from the viewpoint of suppressing surface unevenness of the cured film, the surface elastic modulus (X) on the surface X of the cured film is preferably less than 9.0 GPa.

In addition, in the present invention, from the viewpoint of further suppressing the surface unevenness of the cured film, the surface elastic modulus (X) on the surface X of the cured film is preferably 6.0 GPa or less.

In addition, from the viewpoint of further improving the adhesiveness to the adjacent layer provided on the surface X of the cured film, the surface elastic modulus (X) on the surface X of the cured film is preferably 4.0 GPa or more.

That is, the surface elastic modulus (X) on the surface X of the cured film is preferably 4.0 GPa or more and 6.0 GPa or less.

### [Composition]

As described above, the cured film according to the embodiment of the present invention is a film obtained by curing a composition (hereinafter, also abbreviated as “composition for forming a cured film”) containing a leveling agent containing a silicon atom and a polymerizable compound.

In the present invention, from the viewpoint of suppressing the surface unevenness of the cured film, it is preferable that E¹⁰⁰ (unit: kPa) representing a surface elastic modulus of the following composition S1 containing the above-described leveling agent and E⁵⁰ (unit: kPa) representing a surface elastic modulus of the following composition S2 containing the above-described leveling agent satisfy the following expression (P).

$${E}^{50} - {E}^{100} \leq 0.5 kPa \qquad ( P )$$

### Composition S1:

a composition containing 100.0 parts by mass of the following liquid crystal compound X, 426.0 parts by mass of acetone, and 0.5 parts by mass of the above-described leveling agent

### Composition S2:

a composition containing 100.0 parts by mass of the following liquid crystal compound X, 160.0 parts by mass of acetone, and 0.5 parts by mass of the above-described leveling agent

### Liquid Crystal Compound X:

a mixture obtained by mixing the following liquid crystal compounds (RA), (RB), and (RC) at a mass ratio of 83:15:2 (Me in Formulae (RB) and (RC) represents a methyl group)

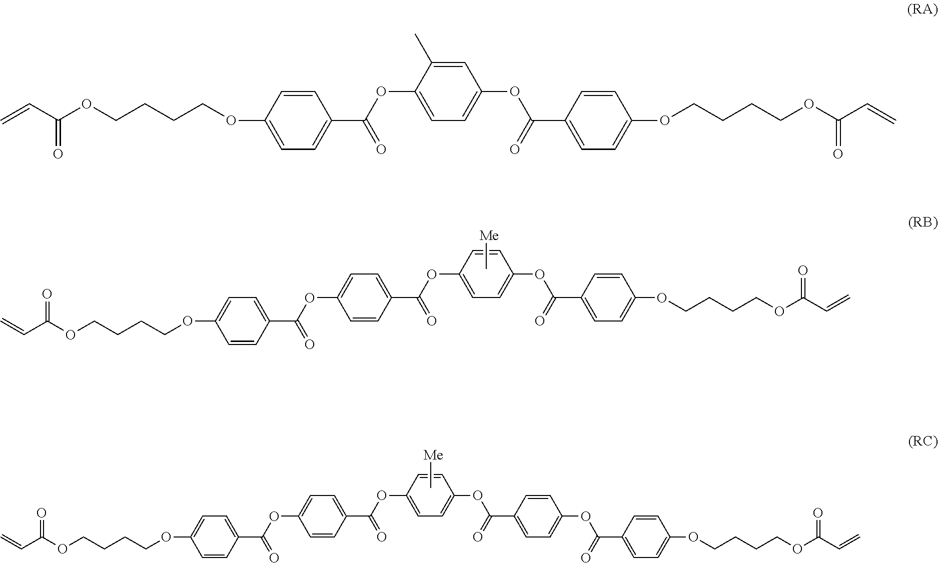

Here, the surface elastic modulus of the composition refers to a value measured as follows with reference to a method described in a literature [T. Kajiya et al. Eur. Phys. J. E. 45, 76 (2022)].

First, a tip with submicron sharpness, produced by electropolishing a tungsten wire in an alkaline aqueous solution, is used as a probe. The probe is mounted on a precision-adjustable stage, brought into contact from above with a droplet of the composition [6 μL, placed on a polytetrafluoroethylene (PTFE) substrate], and then withdrawn upward at a low speed. Next, an optical microscope is installed on a side surface, and a shape (meniscus) of the sample liquid droplet surface pulled up by the probe contact is observed. Based on the above-described literature, it is considered that a meniscus withdrawal distance h is determined by a balance between a surface tension a of the composition and an elastic force, and the surface elastic modulus E is calculated from the following relational expression (1).

$$h \approx σ / E \qquad ( 1 )$$

Here, as the surface tension a, a value measured according to a Wilhelmy method is adopted.

Using the above-described method, the surface elastic modulus E¹⁰⁰ (unit: kPa) of the above-described composition S1 and the surface elastic modulus E⁵⁰ (unit: kPa) of the above-described composition S2 are measured, and the change amount (E⁵⁰-E¹⁰⁰) is calculated.

In the present invention, as described above, the change amount (E⁵⁰-E¹⁰⁰) of the surface elastic modulus E¹⁰⁰ (unit: kPa) of the above-described composition S1 and the surface elastic modulus E⁵⁰ (unit: kPa) of the above-described composition S2 is 0.5 kPa or less, whereby the surface unevenness of the cured film is improved.

Although the reason why this effect is exhibited is not clear in detail, it is considered that an increase in the surface elastic modulus during the drying process of the composition is suppressed and thus leveling is improved, thereby reducing the surface unevenness of the cured film.

In the present invention, from the viewpoint of further suppressing the surface unevenness of the cured film, the change amount (E⁵⁰-E¹⁰⁰) of the surface elastic modulus E¹⁰⁰ (unit: kPa) of the above-described composition S1 and the surface elastic modulus E⁵⁰ (unit: kPa) of the above-described composition S2 is preferably 0.3 kPa or less.

In the present invention, from the viewpoint of further suppressing the surface unevenness of the cured film, the change amount (E⁵⁰-E¹⁰⁰) of the surface elastic modulus E¹⁰⁰ (unit: kPa) of the above-described composition S1 and the surface elastic modulus E⁵⁰ (unit: kPa) of the above-described composition S2 is preferably 0.15 kPa or less. The lower limit value of the change amount (E⁵⁰-E¹⁰⁰) is not particularly limited, but is preferably 0 kPa or more.

### <Leveling Agent>

As described above, the leveling agent contained in the composition for forming a cured film is a leveling agent containing a silicon atom, and is preferably a polymer having a repeating unit A containing a silicon atom.

### (Repeating Unit A)

The repeating unit A is a repeating unit containing a silicon atom.

The number of silicon atoms contained in the repeating unit A is 1 or more, preferably 2 or more, more preferably 3 to 6, and still more preferably 3 to 5.

It is preferable that the repeating unit A contains a silicon atom as a structure represented by Formula (Ia).

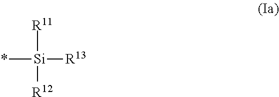

In Formula (Ia), * represents a bonding position.

R¹¹, R¹², and R¹³ each independently represent an alkyl group, an alkenyl group, an aryl group, or an alkylene-aryl group, which may have a substituent. Examples of the substituent include the substituents described in the above substituent group A, and among these, a halogen atom, an alkyl group, an alkylcarbonyl group, an alkoxycarbonyl group, an alkylcarbonyloxy group, or an alkoxy group is preferable.

Examples of the above-described alkyl group include a linear alkyl group having 1 to 18 carbon atoms and a branched or cyclic alkyl group having 3 to 18 carbon atoms. Specific examples thereof include a methyl group, an ethyl group, a propyl group, a butyl group, an isopropyl group, a tert-butyl group, and a cyclohexyl group.

Examples of the above-described alkenyl group include an alkenyl group having 2 to 12 carbon atoms.

Examples of the above-described aryl group include an aryl group having 6 to 12 carbon atoms.

Examples of the above-described alkylene-aryl group include an alkylene-aryl group having 7 to 30 carbon atoms.

From the viewpoint of suppressing the surface unevenness of the cured film, it is preferable that R¹¹, R¹², and R¹³ are all alkyl groups.

From the viewpoint of further improving the adhesiveness to the adjacent layer provided on the surface X of the cured film, the repeating unit A preferably includes two or more structures represented by Formula (Ia), more preferably includes 3 to 6 structures, and still more preferably includes 3 to 5 structures.

From the viewpoint of suppressing the surface unevenness of the cured film and further improving compatibility with the polymerizable compound (particularly, a polymerizable liquid crystal compound) described later, the repeating unit A is preferably a repeating unit represented by Formula (a1).

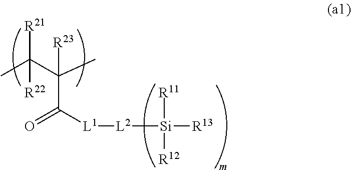

In Formula (a1), m represents an integer of 2 or more. m is preferably an integer of 3 or more, more preferably an integer of 3 to 6, and still more preferably an integer of 3 to 5.

In Formula (a1), R¹¹, R¹², and R¹³ are the same as R¹¹, R¹², and R¹³ in Formula (Ia). A plurality of R¹¹'s may be the same or different from each other, a plurality of R¹²'s may be the same or different from each other, and a plurality of R¹³'s may be the same or different from each other.

In Formula (a1), R²¹ and R²² each independently represent a hydrogen atom or an alkyl group.

Examples of the above-described alkyl group include a linear alkyl group having 1 to 18 carbon atoms and a branched or cyclic alkyl group having 3 to 18 carbon atoms. R²¹ and R²² are preferably a hydrogen atom.

In Formula (a1), R²³ represents a hydrogen atom or a substituent.

Examples of the above-described substituent include the substituents described in the above substituent group A (particularly, an alkyl group, an alkenyl group, or an aryl group), and a substituent having a linking group and a group containing a silicon atom. The substituent having a linking group and containing a silicon atom also includes —CH₂—CO-L¹-L²-(Si(R¹¹)(R¹²)(R¹³))_{M}. L¹, L², R¹¹, R¹², R¹³, and m are each the same as the definitions of the symbols in Formula (a1).

R²³ is preferably a hydrogen atom or an alkyl group, more preferably a hydrogen atom or a linear alkyl group having 1 to 4 carbon atoms, still more preferably a hydrogen atom, a methyl group, or an ethyl group, and particularly preferably a hydrogen atom or a methyl group.

In Formula (a1), L¹ represents —O— or NR^{Z}—. R^{Z} represents a hydrogen atom or a substituent.

Examples of the substituent represented by Rz include the substituents described in the above substituent group A; and among these, an alkyl group is preferable, a linear alkyl group having 1 to 4 carbon atoms is more preferable, and a methyl group or an ethyl group is still more preferable.

As L¹, —O— or —NH— is preferable, and —O— is more preferable.

In Formula (a1), L² represents an (m+1)-valent linking group.

Suitable examples of the above-described (m+1)-valent linking group include an (m+1)-valent hydrocarbon group having 1 to 10 carbon atoms, which may have a substituent,
in which a part of carbon atoms constituting the hydrocarbon group may be substituted with a heteroatom.

Examples of the substituent which may be included in the above-described hydrocarbon group include the substituents described in the above substituent group A; and among these, an alkyl group is preferable, a linear alkyl group having 1 to 4 carbon atoms is more preferable, and a methyl group or an ethyl group is still more preferable.

Examples of the heteroatom which may replace a part of the above-described carbon atoms include a silicon atom, an oxygen atom, and a nitrogen atom.

Examples of L² include a group represented by Structural Formula K-1-L, a group represented by Structural Formula K-2-L, and a group represented by Structural Formula K-3-L. In the following structural formulae, * represents a bonding position with L¹ in Formula (a1), and ** represents a bonding position with the group represented by —SiR¹¹R¹²R¹³ in Formula (a1).

Among these, from the viewpoint of further improving the adhesiveness to the adjacent layer provided on the surface X of the cured film, L² is preferably a group represented by Structural Formula K-1-L.

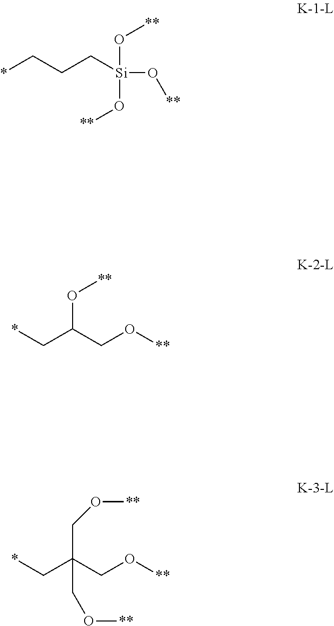

Specific examples of the repeating unit A include repeating units corresponding to monomers represented by Formulae K-1 to K-34.

The monomer represented by Formula K-29 is a mixture of monomers having different numbers of —(O—Si(CH₃)₂)—, and thus the average value thereof is represented as n 11. The same applies to the monomer represented by Formula K-30.

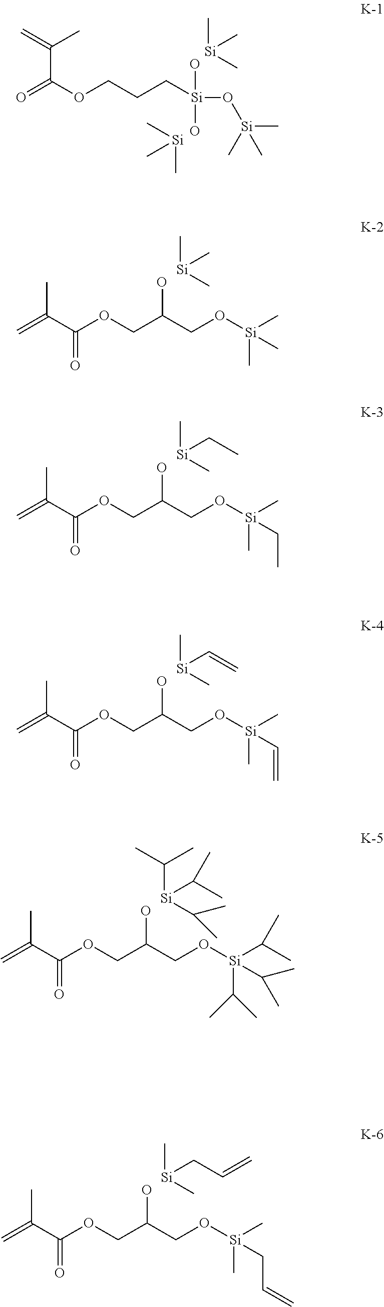

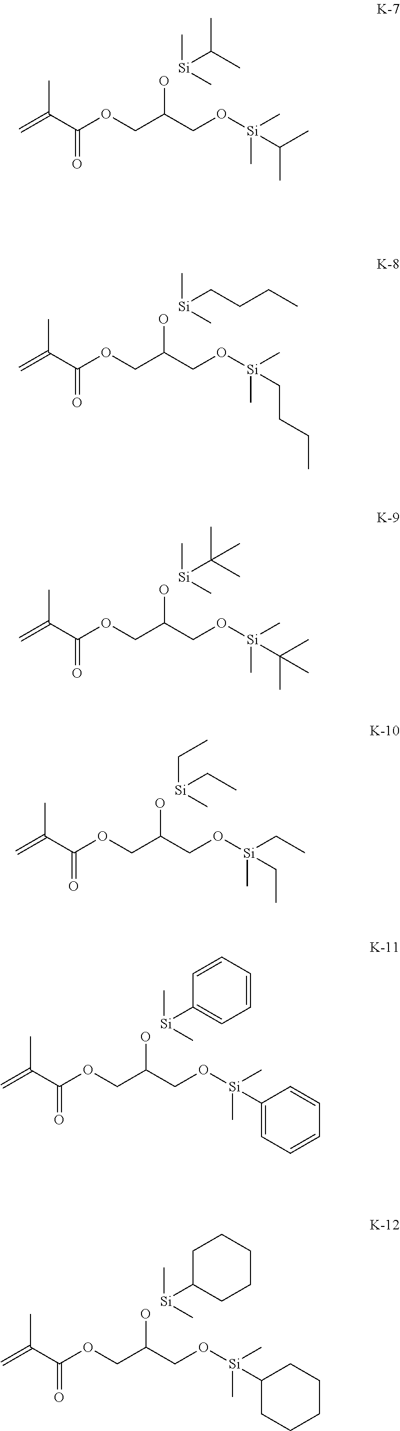

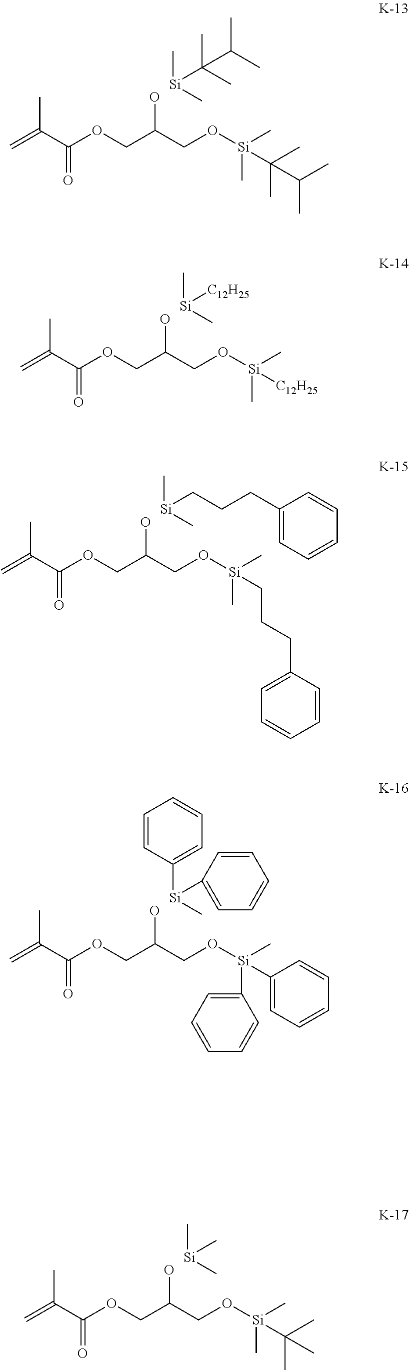

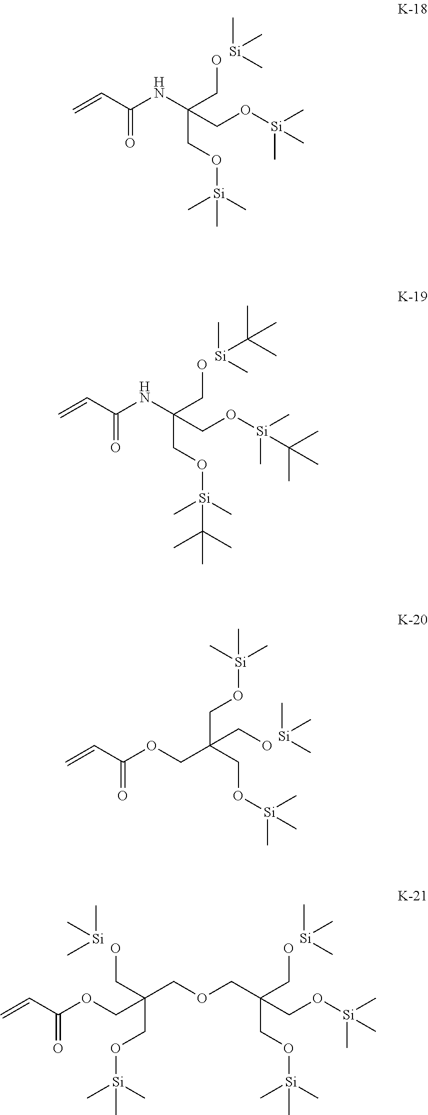

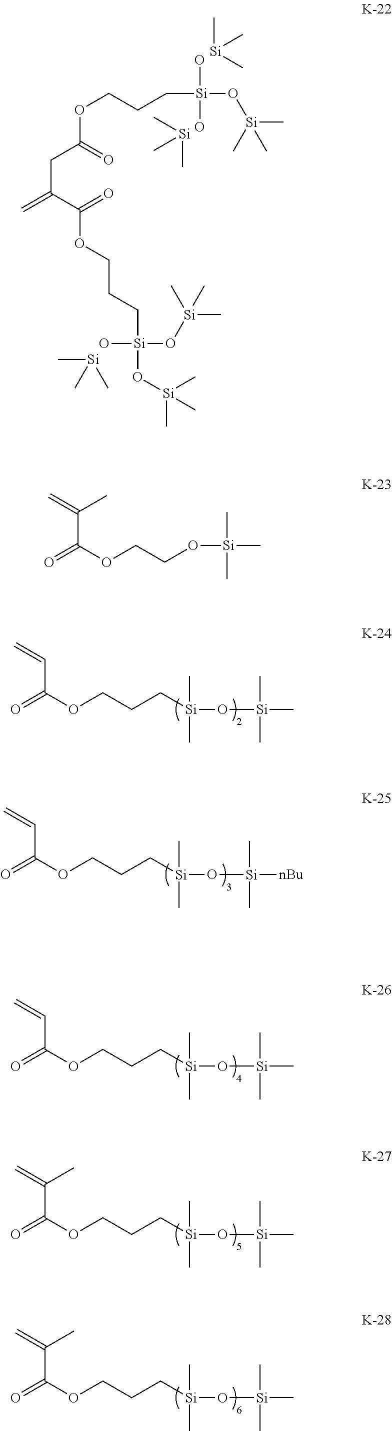

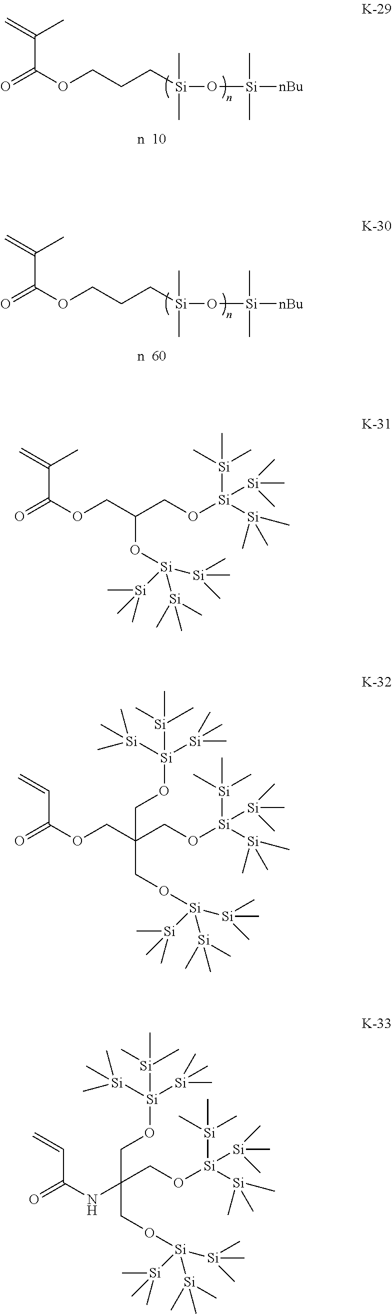

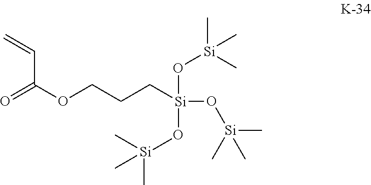 [SMILES: C=CC(=O)OCCC[Si](O[Si](C)(C)C)(O[Si](C)(C)C)O[Si](C)(C)C]

The repeating unit A may be used alone or in combination of two or more kinds thereof.

A content of the repeating unit A is preferably 20% by mass or more, more preferably 30% by mass or more, and still more preferably 35% by mass or more with respect to all repeating units constituting a main chain of the leveling agent (100% by mass). The upper limit of the content of the repeating unit A may be 100% by mass, and is preferably 80% by mass or less, more preferably 70% by mass or less, and still more preferably 60% by mass or less with respect to all repeating units constituting the main chain of the leveling agent (100% by mass).

### (Repeating Unit B)

From the viewpoint of further improving the adhesiveness to the adjacent layer provided on the surface X of the cured film, the leveling agent contained in the composition for forming a cured film is preferably a copolymer having the above-described repeating unit A and a repeating unit B containing a polymerizable group.

Here, the polymerizable group contained in the repeating unit B is not particularly limited, but is preferably a radically polymerizable group or a cationically polymerizable group.

A known radically polymerizable group can be used as the radically polymerizable group, and suitable examples thereof include an acryloyloxy group or a methacryloyloxy group. In this case, it is known that the acryloyloxy group generally has a high polymerization rate, and from the viewpoint of improving productivity, the acryloyloxy group is preferable. However, the methacryloyloxy group can also be used as the polymerizable group.

A known cationically polymerizable group can be used as the cationically polymerizable group, and specific examples thereof include an alicyclic ether group, a cyclic acetal group, a cyclic lactone group, a cyclic thioether group, a spiro orthoester group, and a vinyloxy group. Among these, an alicyclic ether group or a vinyloxy group is suitable, and an epoxy group, an oxetanyl group, or a vinyloxy group is particularly preferable.

Examples of a particularly preferred polymerizable group include a polymerizable group represented by any one of Formulae (P-1) to (P-20).

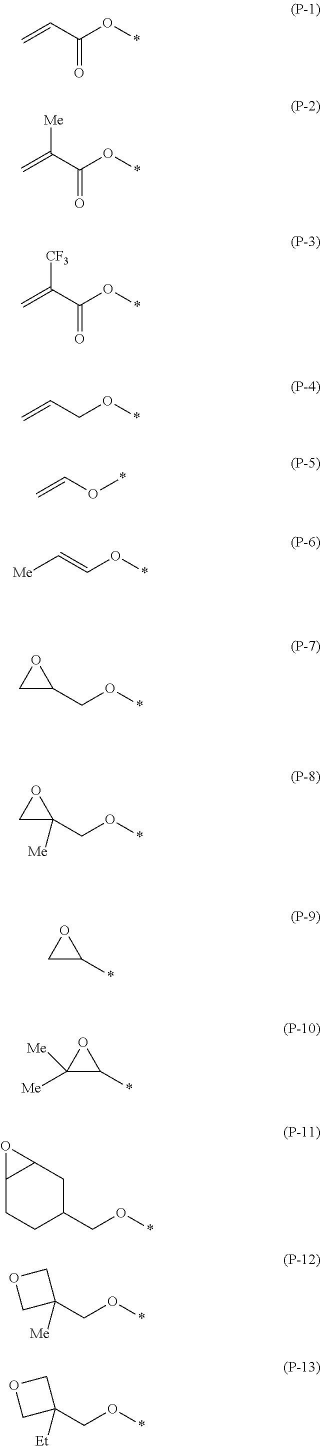

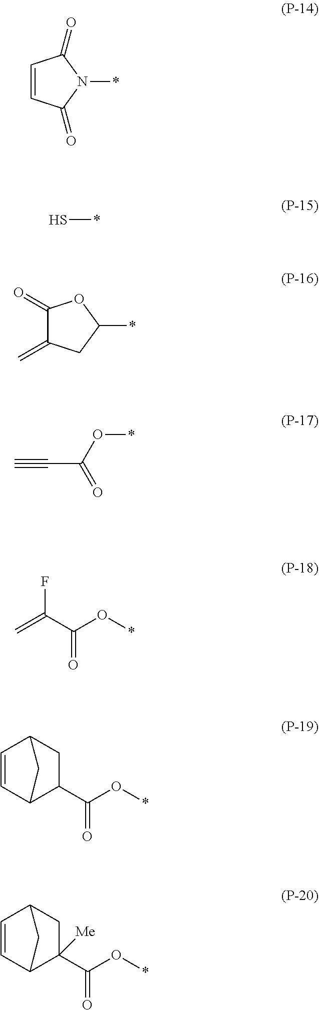

The number of polymerizable groups contained in the repeating unit B is 1 or more, preferably 1 to 3, and more preferably 1 or 2.

From the viewpoint of further improving the compatibility with the polymerizable compound (particularly, the polymerizable liquid crystal compound) described later, the repeating unit B is preferably a repeating unit represented by Formula (b1).

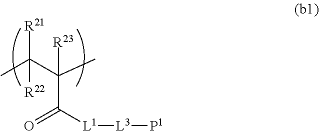

In Formula (b1), R²¹, R²², R²³, and L¹ are the same as those described in Formula (a1) above.

In Formula (b1), L³ represents a single bond or a divalent linking group.

Examples of the above-described divalent linking group include a divalent aliphatic hydrocarbon group having 1 to 20 carbon atoms, which may have a substituent.

As the above-described aliphatic hydrocarbon group having 1 to 20 carbon atoms, an alkylene group having 1 to 15 carbon atoms is preferable, and an alkylene group having 2 to 8 carbon atoms is more preferable.

One or more of —CH₂-'s constituting the above-described divalent aliphatic hydrocarbon group may be each independently replaced with a group selected from —O—, —S—, —CO—, and —N(Q)-. Two or more of —CH₂-'s may be substituted as long as the same group is not adjacent to each other. The definition and suitable aspects of Q are as described above.

Among these, as L³, an alkylene group having 2 to 8 carbon atoms, which may have a substituent, or *-(L³¹-O)ₙ3-* is preferable. * represents a bonding position. n3 represents an integer of 1 to 8. L³¹'s each independently represent an alkylene group having 1 to 6 carbon atoms, which may have a substituent; and an alkylene group having 2 to 4 carbon atoms, which may have a substituent, is preferable.

Examples of the substituent which may be included in the above-described divalent linking group include the substituents described in the above substituent group A; and among these, examples thereof include a hydroxy group, a halogen atom, an amino group, an alkyl group, an alkoxy group, an acyl group, an aryl group, a nitro group, a cyano group, an alkylcarbonyl group, and a sulfonyl group.

In Formula (b1), P¹ represents a polymerizable group. The definition and suitable aspects of the polymerizable group are as described above.

Specific examples of the repeating unit B include repeating units shown below. In the following repeating units, n represents an integer of 1 or more (typically, an integer of 1 to 6).

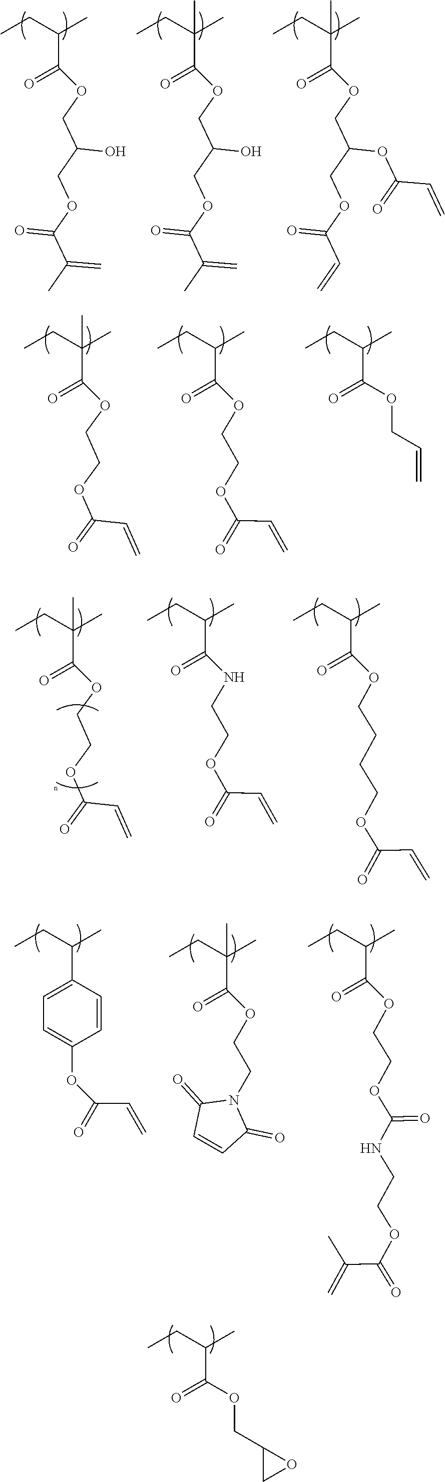

The repeating unit B may be used alone or in combination of two or more kinds thereof.

A content of the repeating unit B is preferably 1% to 50% by mass and more preferably 20% to 49% by mass with respect to all repeating units constituting the main chain of the leveling agent.

In the present invention, from the viewpoint of suppressing the surface unevenness of the cured film and further improving the adhesiveness to the adjacent layer provided on the surface X of the cured film, it is preferable that a mass ratio (a/b) of the content a of the above-described repeating unit A to the content b of the above-described repeating unit B in the leveling agent satisfies the following expression (A).

$$1. 2 < a / b < 3.4 . \qquad ( A )$$

The lower limit value of the above-described expression (A) is preferably 1.3 or more, more preferably 1.4 or more, and still more preferably 1.5 or more. In addition, the upper limit value of the above-described expression (A) is preferably 3.2 or less, more preferably 3.0 or less, and still more preferably 2.8 or less.

### (Repeating Unit C)

From the viewpoint of suppressing the surface unevenness of the cured film, the leveling agent contained in the composition for forming a cured film is preferably a copolymer having the above-described repeating unit A and repeating unit B and a repeating unit C containing a mesogen group.

In addition, from the viewpoint of further improving the adhesiveness to the adjacent layer provided on the surface X of the cured film, the repeating unit C preferably contains the mesogen group and a functional group capable of forming a covalent bond complex with a hydroxyl group, and more preferably contains a boronic acid group or a boronic acid ester group.

Here, as the mesogen group, a known mesogen group can be used, and for example, descriptions particularly on pages 7 to 16 of “Flussige Kristalle in Tabellen II” (VEB Deutsche Verlag fur Grundstoff Industrie, Leipzig, 1984) and descriptions particularly in Chapter 3 of “Liquid Crystal Handbook” (Maruzen, 2000) edited by Liquid Crystals Handbook Editing Committee can be referred to.

As the mesogen group, a group having at least one cyclic structure selected from the group consisting of an aromatic hydrocarbon group, a heterocyclic group, and an alicyclic group is preferable.

From the reason that an alignment degree of the liquid crystal compound is improved, the mesogen group is preferably a group having an aromatic hydrocarbon group which may have a substituent or a group having an alicyclic group which may have a substituent, more preferably a group having two to four aromatic hydrocarbon groups which may have a substituent, and still more preferably a group having two or three aromatic hydrocarbon groups which may have a substituent. The substituent is preferably an alkyl group, an alkoxy group, an alkyl ester group, or an acetyl group, and more preferably a methyl group, a tert-butyl group, a methoxy group, or a methyl ester group.

As the mesogen group, a group represented by Formula (M1-A) is preferable.

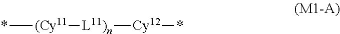

In Formula (M1-A), * represents a bonding position.

In Formula (M1-A), n represents an integer of 1 or more, and is preferably an integer of 1 to 10, more preferably an integer of 1 to 3, and still more preferably 1 or 2.

In Formula (M1-A), Cy¹¹ and Cy¹² each independently represent a divalent ring group which may have a substituent.

The above-described divalent ring group may be a monocyclic ring or a polycyclic ring, and a monocyclic ring is preferable.

The number of ring members in the above-described divalent ring group is preferably 5 to 18, more preferably 5 to 10, and still more preferably 5 or 6.

Examples of the above-described divalent ring group include a divalent aromatic ring group and a divalent alicyclic group.

Examples of the above-described divalent aromatic ring group include a divalent aromatic hydrocarbon ring group obtained by removing two hydrogen atoms from an aromatic hydrocarbon ring, and a divalent aromatic heterocyclic group obtained by removing two hydrogen atoms from an aromatic heterocyclic ring. Examples of the above-described aromatic hydrocarbon ring include a benzene ring, a naphthalene ring, and an anthracene ring, and a phenanthrene ring. Examples of the above-described aromatic heterocyclic ring include a pyridine ring, a pyridazine ring, an imidazole ring, a thiophene ring, a quinoline ring, an isoquinoline ring, an oxazole ring, a thiazole ring, an oxadiazole ring, a benzothiazole ring, a benzothiadiazole ring, a phthalimide ring, a thienothiazole ring, a thiazolothiazole ring, a thienothiophene ring, and a thienooxazole ring. Among these, a group obtained by removing two hydrogen atoms from a benzene ring (for example, a 1,4-phenylene group) is preferable.

Examples of the above-described divalent alicyclic group include a divalent aliphatic hydrocarbon ring group obtained by removing two hydrogen atoms from an aliphatic hydrocarbon ring (for example, a cycloalkane or a cycloalkene), and a divalent aliphatic heterocyclic group obtained by removing two hydrogen atoms from an aliphatic heterocyclic ring. Examples of the aliphatic hydrocarbon ring include a cyclopentane ring, a cyclohexane ring, a cycloheptane ring, a cyclooctane ring, a cyclononane ring, a cyclododecane ring, and a cyclodocosane ring. Examples of the aliphatic heterocyclic ring include a pyrrolidine ring, an oxolane ring, a thiolane ring, a piperidine ring, a tetrahydropyran ring, a thiane ring, a piperazine ring, and a morpholine ring. Among these, a group obtained by removing two hydrogen atoms from a cyclohexane ring (for example, a 1,4-cyclohexylene group) is preferable.

As the above-described divalent ring group, the divalent aromatic ring group or the divalent aliphatic hydrocarbon ring group is preferable, and the divalent aromatic ring group is more preferable.

Examples of the substituent which may be included in the above-described divalent ring group include an alkyl ester group, an alkyl group which may have a halogen atom, an acyl group, an alkoxy group, an alkylthio group, an alkyloxycarbonyl group, a carbamoyl group, an acylamino group, a halogen atom, a cyano group, and a nitro group; and an alkyl ester group, an alkyl group, or an acyl group is preferable, a methyl ester group, a linear alkyl group having 1 to 4 carbon atoms, or an acetyl group is more preferable, and a methyl ester group, a methyl group, or an ethyl group is still more preferable.

In Formula (M1-A), L¹¹'s each independently represent a single bond or a divalent linking group.

Examples of the above-described divalent linking group include —CO—, —O—, —S—, —C(═S)—, —CR^{L1}R^{L2}—, —CR^{L3}═CR^{L4}—, —NR^{L5}—, and a combination of two or more of these groups. R^{L1} to R^{L5} each independently represent a hydrogen atom or a substituent. As the substituent represented by R^{L1} to R^{L5}, a halogen atom, an alkyl group having 1 to 12 carbon atoms, or an alkoxy group having 1 to 12 carbon atoms is preferable.

As L¹¹, —CO—, —O—, —CR^{L1}R^{L2}—, —NR^{L5}—, or a combination of two of these groups is preferable.

In a case where n is an integer of 2 or more and Cy¹¹ represents a phenylene group, from the viewpoint of improving aligning properties in a case where the liquid crystal compound is horizontally aligned, it is preferable that any one of two or more Cy¹¹ is a meta position linkage or an ortho position linkage; and among these, from the viewpoint of improving alignment properties and cissing, a meta position linkage is preferable. On the other hand, in a case where the liquid crystal compound is vertically aligned, in any one of two or more Cy¹¹, a para position linkage is preferable.

From the viewpoint of improving the compatibility with the liquid crystal compound and further improving the leveling, the repeating unit B is preferably a repeating unit represented by Formula (c1) or a repeating unit represented by Formula (c2), and more preferably a repeating unit represented by Formula (c1).

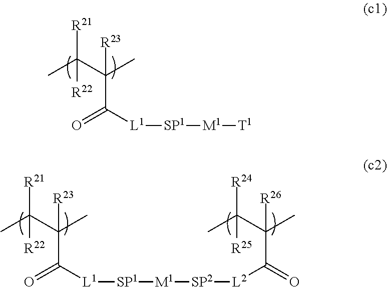

In Formulae (c1) and (c2), R²¹, R²², R²³, and L¹ are the same as those described in Formula (a1) above.

In Formula (c2), R²⁴ and R²⁵ each independently have the same definition as R²¹ and R²² in Formula (a1) described above, and suitable aspects thereof are also the same. R²⁶ has the same definition as R²³ in Formula (a1) described above, and a suitable aspect thereof is also the same. L² has the same definition as L¹ in Formula (a1) described above, and a suitable aspect thereof is also the same.

In Formulae (c1) and (c2), SP¹ and SP² each independently represent a spacer group. The spacer group is not particularly limited as long as it is a divalent linking group which does not have a ring structure; and examples thereof include a divalent chain-like aliphatic hydrocarbon group having 1 to 20 carbon atoms.

As the above-described divalent chain-like aliphatic hydrocarbon group having 1 to 20 carbon atoms, an alkylene group having 1 to 15 carbon atoms is preferable, and an alkylene group having 1 to 8 carbon atoms is more preferable. Specific suitable examples thereof include a methylene group, an ethylene group, a propylene group, a butylene group, a pentylene group, a hexylene group, a methylhexylene group, and a heptylene group.

One or more of —CH₂-'s constituting the above-described divalent chain-like aliphatic hydrocarbon group may be each independently replaced with a group selected from —O—, —S—, —CO—, or —N(Q)-. Two or more of —CH₂-'s may be substituted as long as the same group is not adjacent to each other. Q represents a hydrogen atom or a substituent. Examples of the substituent represented by Q include the substituents described in the above substituent group A; and among these, an alkyl group is preferable, a linear alkyl group having 1 to 4 carbon atoms is more preferable, and a methyl group or an ethyl group is still more preferable.

Among these, as the above-described spacer group, *—(CH₂—CH₂—O)ₙ₁—*, *—(CH₂)ₙ₂—O—*, or *—(CH₂)ₙ₂—O—CO—* is preferable. * represents a bonding position. n1 represents an integer of 1 to 4. n2's each independently represent an integer of 1 to 6, and are preferably an integer of 2 to 4.

In Formulae (c1) and (c2), M¹ represents a mesogen group. The details of the mesogenic group are as described above.

In Formula (c1), T¹ represents a terminal group. The terminal group represents a hydrogen atom or a substituent.

Examples of the above-described substituent include the substituents described in the above substituent group A, and among these, examples thereof include a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—; R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a trialkylsilyloxy group having 3 to 12 carbon atoms, a ureido group having 1 to 10 carbon atoms, and a (meth)acryloyloxy group-containing group. Examples of the above-described (meth)acryloyloxy group-containing group include a group represented by -L^{A}-A (L^{A} represents a single bond or a divalent linking group; examples of the divalent linking group include the same groups as L¹ described above; A represents a (meth)acryloyloxy group).

In addition, examples of T¹ also include a boronic acid group (—B(OH)₂) and a boronic acid ester group (—B(R^{B1})₂).

R^{B1} represents a hydrogen atom, an alkyl group which may have a substituent, an aryl group which may have a substituent, or a heteroaryl group which may have a substituent; and a hydrogen atom or an alkyl group which may have a substituent is preferable.

The number of carbon atoms in the alkyl group is preferably 1 to 10 and more preferably 1 to 5.

The number of carbon atoms in the aryl group is preferably 4 to 20 and more preferably 6 to 12. Examples of the aryl group include a phenyl group.

The number of carbon atoms in the heteroaryl group is preferably 3 to 10 and more preferably 3 to 5. Examples of a heteroatom contained in the heteroaryl group include an oxygen atom, a nitrogen atom, and a sulfur atom.

R^{B1}'s may be bonded to each other to form a ring. The number of ring members in the ring formed by bonding R^{B1}'s to each other is preferably 4 to 8 and more preferably 5 or 6.

Specific examples of the repeating unit C include repeating units represented by the following structural formulae.

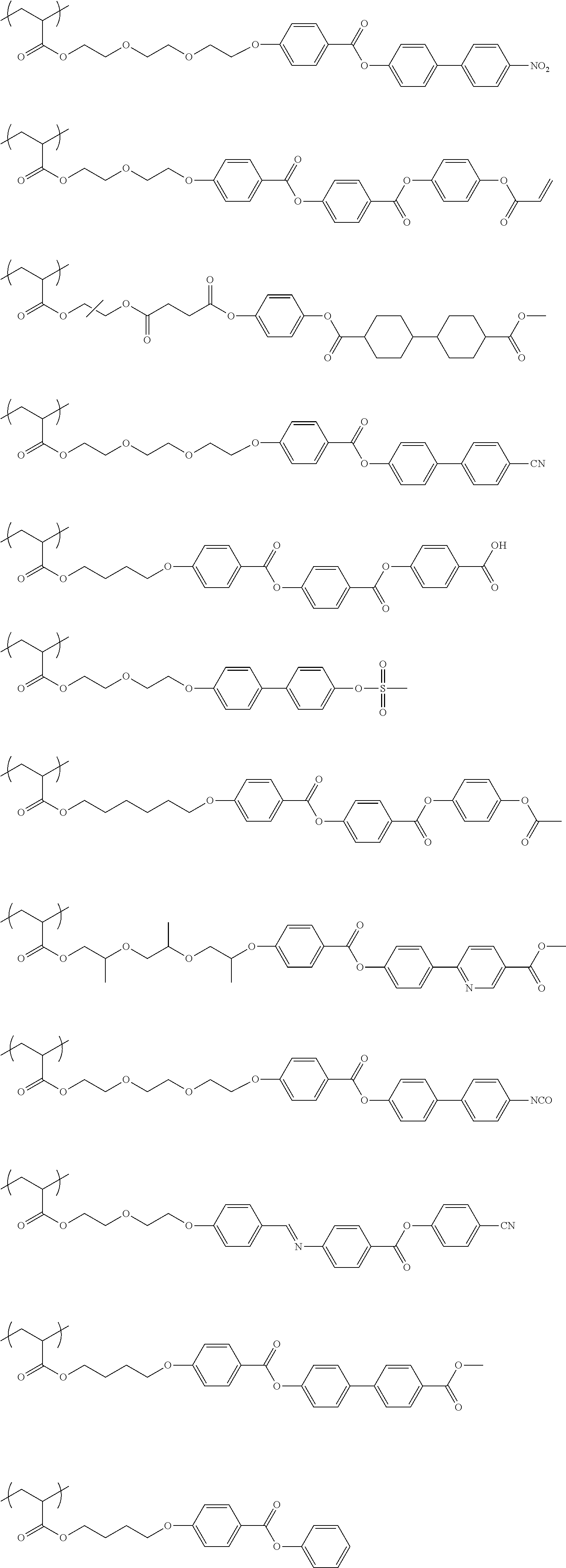

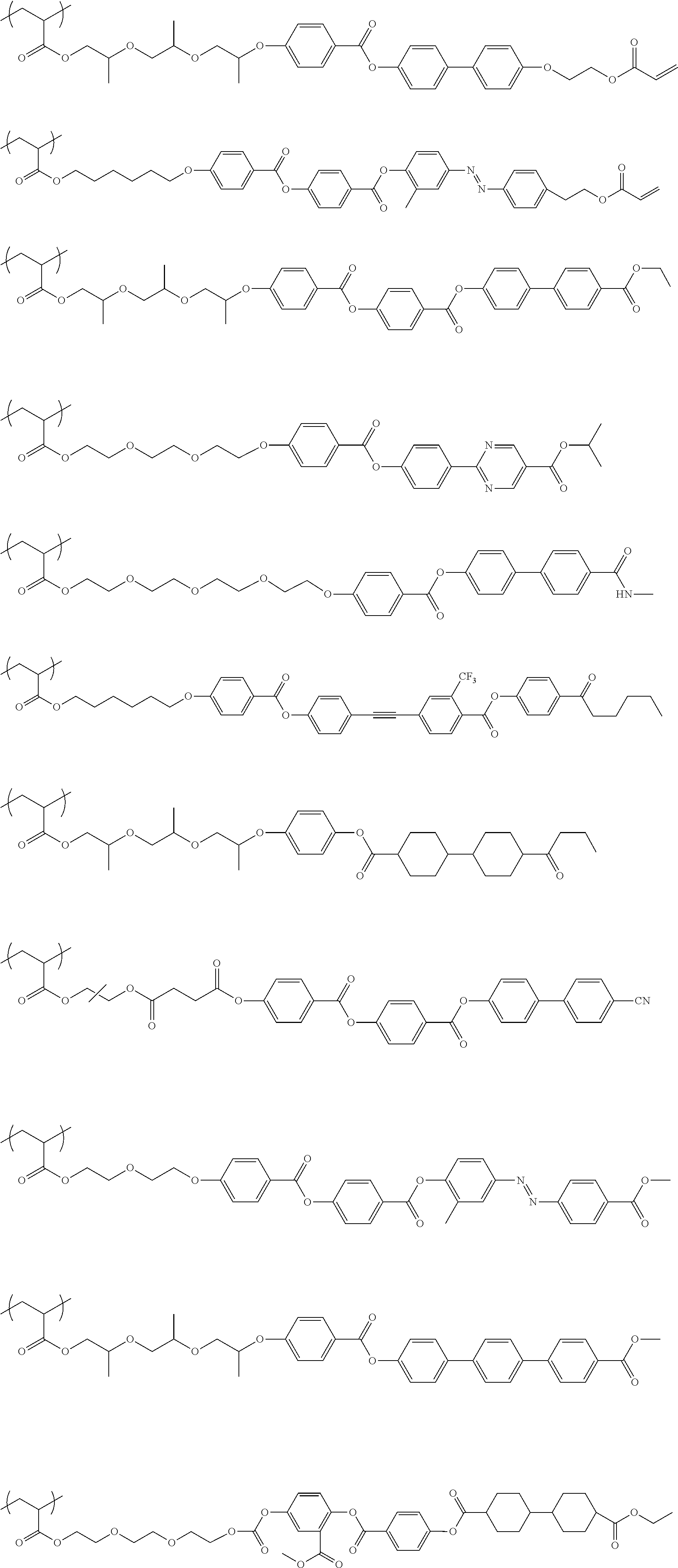

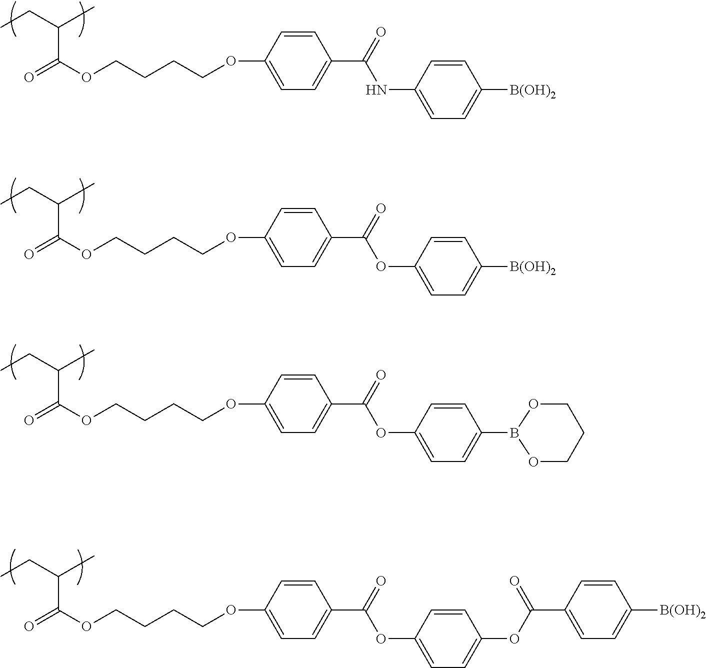

The repeating unit C may be used alone or in combination of two or more kinds thereof.

A content of the repeating unit C is preferably 1% to 50% by mass, more preferably 2% to 40% by mass, and still more preferably 5% to 30% by mass with respect to all repeating units constituting the main chain of the leveling agent (100% by mass).

In the present invention, in a case where the leveling agent is a copolymer having the above-described repeating unit A, repeating unit B, and repeating unit C (particularly, repeating unit C containing a functional group capable of forming a covalent bond complex with a hydroxyl group), from the viewpoint of further improving the adhesiveness to the adjacent layer provided on the surface X of the cured film, it is preferable that the content a of the repeating unit A is 50% to 60% by mass, the content b of the repeating unit B is 24% to 34% by mass, and the content c of the repeating unit C is 11% to 21% by mass with respect to the total mass of the copolymer.

### (Other Repeating Units D)

The leveling agent contained in the composition for forming a cured film may have other repeating units D in addition to the above-described repeating units.

For example, the leveling agent may have a repeating unit containing a polar group from the viewpoint of alignment control. Examples of the polar group include a carboxy group, an amino group, an amide group, a urea group, a urethane group, a sulfonylamino group, a sulfo group, a phospho group, a hydroxy group, a mercapto group, a methylene group substituted with an electron withdrawing group, and a methine group substituted with an electron withdrawing group, and a carboxy group is preferable.

As the repeating unit containing a polar group, a repeating unit represented by Formula (K-1) is preferable.

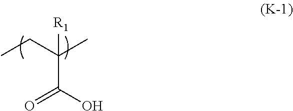

In Formula (K-1), R¹⁰ represents a hydrogen atom or an alkyl group having 1 to 20 carbon atoms; and among these, a hydrogen atom or an alkyl group having 1 to 10 carbon atoms is preferable, a hydrogen atom or an alkyl group having 1 to 4 carbon atoms is more preferable, and a hydrogen atom or a methyl group is still more preferable.

Examples of a monomer forming the above-described repeating unit represented by Formula (K-1) include acrylic acid and methacrylic acid.

A content of the repeating unit having a polar group is preferably 0.05% to 15% by mass, more preferably 0.1% to 10% by mass, and still more preferably 0.1% to 1% by mass with respect to all repeating units constituting the main chain of the leveling agent (100% by mass).

In the present invention, from the viewpoint of suppressing the surface unevenness of the cured film and further improving the adhesiveness to the adjacent layer provided on the surface X of the cured film, a weight-average molecular weight of the leveling agent is preferably 15,000 to 40,000 and more preferably 20,000 to 37,000.

Here, the weight-average molecular weight in the present invention is a value measured by gel permeation chromatography (GPC) under the following conditions.
Solvent (eluent): tetrahydrofuran
Apparatus name: EcoSEC HLC-8320GPC (manufactured by TOSOH Corporation)
Column: three columns of TSKgel SuperHZM-H, TSKgel SuperHZ4000, and TSKgel SuperHZ200 (all manufactured by TOSOH Corporation) are connected and used.
Column Temperature: 40° C.
Sample Concentration: 0.1% by mass
Flow rate: 0.35 ml/min
Calibration curve: TSK standard polystyrene manufactured by TOSOH Corporation; the calibration curve is based on seven samples with Mw=706,000 to 1,013 (Mw/Mn=1.03 to 1.06)

The leveling agent may be used alone or in combination of two or more kinds thereof.

With respect to 100 parts by mass of the polymerizable compound described later, a content of the leveling agent is preferably 0.05 parts by mass or more and 5 parts by mass or less, and from the viewpoint of suppressing the surface unevenness of the cured film and further improving the adhesiveness to the adjacent layer provided on the surface X of the cured film, it is more preferably 0.1 parts by mass or more and 2 parts by mass or less, and still more preferably 0.1 parts by mass or more and 1.5 parts by mass or less.

### <Polymerizable Compound>

The polymerizable compound contained in the composition for forming a cured film is not particularly limited as long as it is a compound having one or more polymerizable groups.

Here, examples of the polymerizable group include those described in the repeating unit B above; and among these, the polymerizable group represented by any of Formulae (P-1) to (P-20) is preferable, and an acryloyloxy group or a methacryloyloxy group is more preferable.

In addition, the polymerizable compound is preferably a compound having two or more polymerizable groups, and more preferably a compound having 2 to 5 polymerizable groups.

In the present invention, from the viewpoint of suppressing the surface unevenness of the cured film, it is preferable that at least one of the polymerizable compounds is a polymerizable liquid crystal compound (that is, a liquid crystal compound having a polymerizable group). In the following, the polymerizable liquid crystal compound is also abbreviated as “liquid crystal compound”.

### (Liquid Crystal Compound)

The liquid crystal compound can be classified into a rod-like type and a disk-like type according to the shape thereof. Each of the types can further be classified into a low-molecular-weight type and a high-molecular-weight type. The “high-molecular-weight” generally refers to a compound having a degree of polymerization of 100 or more (Polymer Physics-Phase Transition Dynamics, written by Masao Doi, p. 2, published by Iwanami Shoten, 1992).

In the present invention, any liquid crystal compound can be used, and it is preferable to use a rod-like liquid crystal compound or a discotic liquid crystal compound (disk-like liquid crystal compound). A mixture of two or more kinds of the rod-like liquid crystal compounds, a mixture of two or more kinds of the disk-like liquid crystal compounds, or a mixture of the rod-like liquid crystal compound and the disk-like liquid crystal compound may be used.

By polymerizing such a liquid crystal compound, the alignment of the liquid crystal compound can be fixed. After immobilizing the liquid crystal compound by polymerization, it is no longer necessary to exhibit liquid crystallinity.

As the rod-like liquid crystal compound, for example, rod-like liquid crystal compounds described in Claim 1 of JP1999-513019A (JP-H11-513019A) or paragraphs [0026] to [0098] of JP2005-289980A can be preferably used; and as the discotic liquid crystal compounds, for example, discotic liquid crystal compounds described in paragraphs [0020] to [0067] of JP2007-108732A or paragraphs [0013] to [0108] of JP2010-244038A can be preferably used, but the liquid crystal compounds are not limited thereto.

In the present invention, from the viewpoint of improving aligning properties of the cured film (in a case where a polymerizable liquid crystal compound is used as the polymerizable compound, the cured film refers to a liquid crystal cured layer; the same applies hereinafter), the polymerizable liquid crystal compound is preferably a rod-like liquid crystal compound, and a difference Δn in refractive index between a major axis direction and a minor axis direction preferably satisfies the following expression (II).

$$Δ n ( 450 ) / Δ n ( 550 ) < 1. \qquad ( II )$$

Here, in the expression (II), Δn(450) represents a difference in refractive index at 450 nm, and Δn(550) represents a difference in refractive index at 550 nm.

In addition, the major axis direction of the rod-like liquid crystal compound refers to an orientation of the longest axis in the molecule, and the minor axis direction refers to an orientation orthogonal to the major axis direction.

In addition, the difference Δn in refractive index refers to a value obtained by dividing a value (nm) of Re(λ) measured by the above-described method for a liquid crystal cured layer produced using the rod-like liquid crystal compound by a value (nm) of a film thickness of the liquid crystal cured layer. As the liquid crystal cured layer to be measured, that is, the liquid crystal cured layer produced using the rod-like liquid crystal compound, a liquid crystal cured layer produced by the following procedure is used.

That is, a liquid crystal composition L having the following formulation is applied onto a glass substrate including a rubbing-treated polyimide alignment film (SE-150 manufactured by Nissan Chemical Industries, Ltd.) by spin coating.

Next, the coating film is heated and aligned at a temperature at which liquid crystallinity is exhibited, thereby forming a liquid crystal layer.

Next, the liquid crystal layer is cooled from the temperature at which the liquid crystallinity is exhibited to a temperature lower than the temperature by 40° C., and alignment is fixed with ultraviolet irradiation of 1,000 mJ/cm² to produce a liquid crystal cured layer.

Liquid crystal composition L

| | |
|---|---|
| Rod-like liquid crystal compound | 15.00 parts by mass |
| Photopolymerization initiator | 0.45 parts by mass |
| (IRGACURE 819, manufactured by BASF) | |
| Fluorine-containing compound | 0.12 parts by mass |
| A shown below | |
| Chloroform | 35.00 parts by mass |

### Fluorine-Containing Compound A

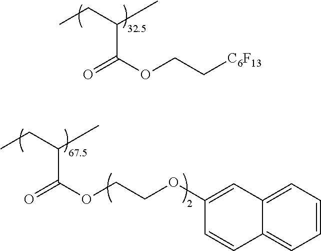

In the present invention, from the reason that the aligning properties of the cured film (liquid crystal cured layer) are favorable, it is preferable that the above-described liquid crystal compound is a compound represented by Formula (I).

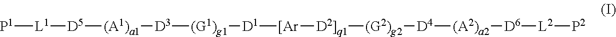

In Formula (I), a1, a2, g1, and g2 each independently represent 0 or 1. Here, at least one of a1 or g1 represents 1 and at least one of a2 or g2 represents 1.

In addition, q1 represents 1 or 2.

In addition, D¹, D², D³, D⁴, D⁵, and D⁶ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms. Here, in a case where q1 is 2, a plurality of D²'s may be the same or different from each other.

In addition, G¹ and G² each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be replaced with —O—, —S—, or —NH—.

In addition, A¹ and A² each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be replaced with —O—, —S—, or —NH—.

In addition, L¹ and L² each independently represent a single bond or a divalent aliphatic hydrocarbon group having 1 to 20 carbon atoms. Here, one or more of —CH₂-'s constituting the aliphatic hydrocarbon group may be replaced with —O—, —S—, —NH—, —N(Q)-, or —CO—. Q represents a substituent.

In addition, P¹ and P² each independently represent a monovalent organic group, where at least one of P¹ or P² represents a polymerizable group. Here, in a case where Ar is an aromatic ring represented by Formula (Ar-3) described later, at least one of P¹ or P², or P³ or P⁴ in Formula (Ar-3) represents a polymerizable group.

In addition, Ar represents an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be replaced with —O—, —S—, or —NH—. Here, in a case where q1 is 2, a plurality of Ar's may be the same or different from each other.

In Formula (I), it is preferable that all of a1, a2, g1, and g2 are 1 for the reason that the liquid crystal composition easily exhibits a liquid crystalline state of a smectic phase.

In addition, it is preferable that both a1 and a2 are 0 and both g1 and g2 are 1 for the reason that durability of the liquid crystal cured layer to be formed is improved.

In Formula (I), q1 is preferably 1.

In Formula (I), examples of the divalent linking group represented by one aspect of D¹, D², D³, D⁴, D⁵, and D⁶ include —CO—, —O—, —CO—O—, —C(═S)O—, —CR¹R²—, —CR¹R²—CR¹R²—, —O—CR¹R²—, —CR¹R²—O—CR¹R²—, —CO—O—CR¹R²—, —O—CO—CR¹R²—, —CR¹R²—O—CO—CR¹R²—, —CR¹R²—CO—O—CR¹R²—, —NR⁵—CR¹R²—, and —CO—NR⁵—. R¹, R², and R⁵ each independently represent a hydrogen atom, a fluorine atom, or an alkyl group having 1 to 12 carbon atoms.

Among these, any of —CO—, —O—, or —CO—O— is preferable.

In Formula (I), examples of the aromatic ring having 6 to 20 carbon atoms, represented by one aspect of G¹ and G², include aromatic hydrocarbon rings such as a benzene ring, a naphthalene ring, an anthracene ring, and a phenanthrene ring; and aromatic heterocyclic rings such as a furan ring, a pyrrole ring, a thiophene ring, a pyridine ring, a thiazole ring, and a benzothiazole ring. Among these, a benzene ring (for example, a 1,4-phenyl group) is preferable.

In Formula (I), the divalent alicyclic hydrocarbon group having 5 to 20 carbon atoms, represented by one aspect of G¹ and G², is preferably a 5-membered ring or a 6-membered ring. In addition, the alicyclic hydrocarbon group may be saturated or unsaturated, but a saturated alicyclic hydrocarbon group is preferable. As the divalent alicyclic hydrocarbon group represented by G¹ and G², for example, the description of paragraph [0078] of JP2012-21068A can be referred to, the contents of which are incorporated herein by reference.

In the present invention, G¹ and G² in Formula (I) are each preferably a cycloalkane ring for the reason that durability of the liquid crystal cured layer to be formed is improved.

Specific examples of the cycloalkane ring include a cyclohexane ring, a cycloheptane ring, a cyclooctane ring, a cyclododecane ring, and a cyclodocosane ring.

Among these, a cyclohexane ring is preferable, a 1,4-cyclohexylene group is more preferable, and a trans-1,4-cyclohexylene group is still more preferable.

In addition, with regard to G¹ and G² in Formula (I), examples of the substituent which may be included in the aromatic ring having 6 to 20 carbon atoms and the divalent alicyclic hydrocarbon group having 5 to 20 carbon atoms include the substituents described in the above substituent group A; and among these, an alkyl group, an alkoxy group, an alkoxycarbonyl group, an alkylcarbonyloxy group, or a halogen atom is preferable.

In Formula (I), examples of the aromatic ring having 6 to 20 carbon atoms, represented by one aspect of A¹ and A², include the same aromatic rings as those described for G¹ and G² in Formula (I).

In addition, in Formula (I), examples of the divalent alicyclic hydrocarbon group having 5 to 20 carbon atoms, represented by one aspect of A¹ and A², include the same groups as those described for G¹ and G² in Formula (I).

With regard to A¹ and A², examples of the substituent which may be included in the aromatic ring having 6 to 20 carbon atoms and the divalent alicyclic hydrocarbon group having 5 to 20 carbon atoms include the substituents described in the above substituent group A; and among these, an alkyl group, an alkoxy group, an alkoxycarbonyl group, an alkylcarbonyloxy group, or a halogen atom is preferable.

Examples of the divalent aliphatic hydrocarbon group having 1 to 20 carbon atoms, represented by one aspect of L¹ and L² in Formula (I), include a linear or branched alkylene group having 1 to 20 carbon atoms, a linear or branched alkenylene group having 1 to 20 carbon atoms, and a linear or branched alkynylene group having 1 to 20 carbon atoms.

As the linear or branched alkylene group having 1 to 20 carbon atoms, an alkylene group having 1 to 12 carbon atoms is preferable and an alkylene group having 1 to 10 carbon atoms is more preferable; and suitable examples thereof include a methylene group, an ethylene group, a propylene group, a butylene group, a pentylene group, and a hexylene group.

As the linear or branched alkenylene group having 1 to 20 carbon atoms, an alkenylene group having 2 to 10 carbon atoms is preferable and an alkenylene group having 2 to 4 carbon atoms is more preferable; and suitable examples thereof include an ethenylene group.

As the linear or branched alkynylene group having 1 to 20 carbon atoms, an alkynylene group having 2 to 10 carbon atoms is preferable and an alkynylene group having 2 to 4 carbon atoms is more preferable; and suitable examples thereof include an ethynylene group.

As described above, one or more of —CH₂-'s constituting the aliphatic hydrocarbon group may be substituted with —O—, —S—, —NH—, —N(Q)-, or —CO—; and examples of the substituent represented by Q include the substituents described in the above substituent group A. Among these, an alkyl group, an alkoxy group, an alkoxycarbonyl group, an alkylcarbonyloxy group, or a halogen atom is preferable.

In Formula (I), examples of the monovalent organic group represented by P¹ and P² include the substituents described in the above substituent group A; and among these, examples thereof include an alkyl group, an aryl group, a heteroaryl group, an alkoxy group, a cyano group, and a carboxy group.

The alkyl group may be linear, branched, or cyclic, but is preferably linear. The number of carbon atoms in the alkyl group is preferably 1 to 30, more preferably 1 to 20, and still more preferably 1 to 10.

In addition, the aryl group may be monocyclic or polycyclic, but is preferably monocyclic. The number of carbon atoms in the aryl group is preferably 6 to 25 and more preferably 6 to 10.

In addition, the heteroaryl group may be monocyclic or polycyclic. The number of heteroatoms constituting the heteroaryl group is preferably 1 to 3. The heteroatom constituting the heteroaryl group is preferably a nitrogen atom, a sulfur atom, or an oxygen atom. The number of carbon atoms in the heteroaryl group is preferably 6 to 18 and more preferably 6 to 12.

In addition, the alkyl group, the aryl group, and the heteroaryl group may be unsubstituted or may have a substituent. Examples of the substituent include the substituents described in the above substituent group A; and among these, an alkyl group, an alkoxy group, an alkoxycarbonyl group, an alkylcarbonyloxy group, or a halogen atom is preferable.

Examples of the polymerizable group represented by at least one of P¹ or P² in Formula (I) include those described in the repeating unit B above; and among these, the polymerizable group represented by any of Formulae (P-1) to (P-20) is preferable, and an acryloyloxy group or a methacryloyloxy group is more preferable.

On the other hand, in Formula (I), examples of the aromatic ring having 6 to 20 carbon atoms, represented by one aspect of Ar, include the same aromatic rings as those described in G¹ and G² in Formula (I).

In addition, in Formula (I), examples of the divalent alicyclic hydrocarbon group having 5 to 20 carbon atoms, represented by one aspect of Ar, include the same groups as those described for G¹ and G² in Formula (I).

With regard to Ar, examples of the substituent which may be included in the aromatic ring having 6 to 20 carbon atoms and the divalent alicyclic hydrocarbon group having 5 to 20 carbon atoms include the substituents described in the above substituent group A; and among these, an alkyl group, an alkoxy group, an alkoxycarbonyl group, an alkylcarbonyloxy group, or a halogen atom is preferable.

In the present invention, from the reason that the aligning properties of the cured film (liquid crystal cured layer) are more favorable, it is preferable that the above-described liquid crystal compound is a compound having any aromatic ring selected from the group consisting of groups represented by Formulae (Ar-1) to (Ar-5), and it is more preferable that the above-described liquid crystal compound is represented by Formula (I) described above and Ar in Formula (I) represents any aromatic ring selected from the group consisting of groups represented by Formulae (Ar-1) to (Ar-5). In Formulae (Ar-1) to (Ar-5), * represents a bonding position; but in a case where Ar in Formula (I) represents any aromatic ring selected from the group consisting of groups represented by Formulae (Ar-1) to (Ar-5), * represents a bonding position to D¹ or D².

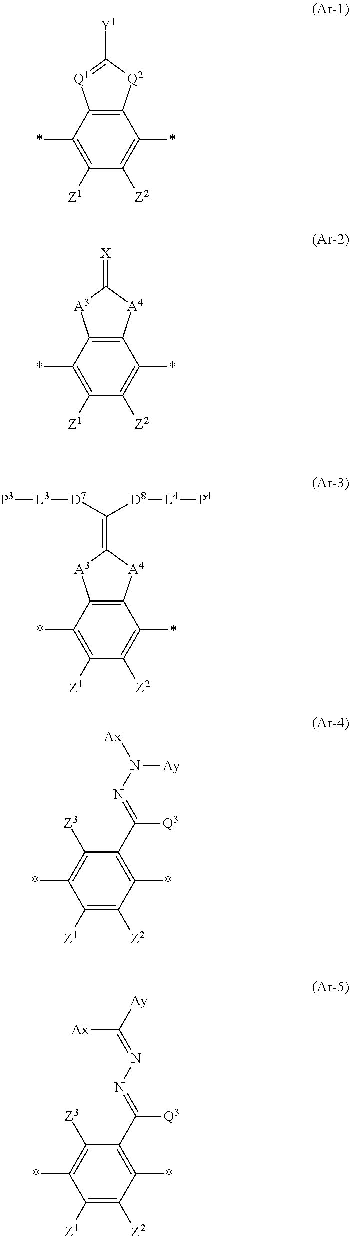

In Formula (Ar-1), Q¹ represents N or CH, Q² represents —S—, —O—, or —N(R⁶)—, where R⁶ represents a hydrogen atom or an alkyl group having 1 to 6 carbon atoms, Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, and one or more of —CH₂-'s constituting the alicyclic hydrocarbon group may be substituted with —O—, —S—, or —NH—.

Examples of the alkyl group having 1 to 6 carbon atoms, represented by R⁶, include a methyl group, an ethyl group, a propyl group, an isopropyl group, a n-butyl group, an isobutyl group, a sec-butyl group, a tert-butyl group, a n-pentyl group, and a n-hexyl group.

Examples of the aromatic hydrocarbon group having 6 to 12 carbon atoms, represented by Y¹, include aryl groups such as a phenyl group, a 2,6-diethylphenyl group, and a naphthyl group.

Examples of the aromatic heterocyclic group having 3 to 12 carbon atoms, represented by Y¹, include a heteroaryl group such as a thienyl group, a thiazolyl group, a furyl group, a pyridyl group, a benzothiazolyl group, and a benzofuryl group; and a group obtained by removing one hydrogen atom from any of an indole ring, a benzofuran ring, a benzothiophene ring, a benzimidazole ring, a benzothiazole ring, or a benzoxazole ring. Among these, as the aromatic heterocyclic group having 3 to 12 carbon atoms, represented by Y¹, a group obtained by removing one hydrogen atom from a benzofuran ring or a benzothiazole ring is preferable.

Examples of the alicyclic hydrocarbon group having 6 to 20 carbon atoms, represented by Y¹, include a cyclohexylene group, a cyclopentylene group, a norbornylene group, and an adamantylene group.

In addition, examples of the substituent which may be included in Y¹ include the substituents described in the above substituent group A; and among these, an alkyl group, an alkoxy group, an alkoxycarbonyl group, an alkylcarbonyloxy group, or a halogen atom is preferable.

In addition, in Formulae (Ar-1) to (Ar-5), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —NR⁸R⁹, —SR¹⁰, —COOR¹¹, or —COR¹², where R⁷ to R¹² each independently represent a hydrogen atom or an alkyl group having 1 to 6 carbon atoms and Z¹ and Z² may be bonded to each other to form an aromatic ring.

As the monovalent aliphatic hydrocarbon group having 1 to 20 carbon atoms, an alkyl group having 1 to 15 carbon atoms is preferable, an alkyl group having 1 to 8 carbon atoms is more preferable; and specifically, a methyl group, an ethyl group, an isopropyl group, a tert-pentyl group (1,1-dimethylpropyl group), a tert-butyl group, or 1,1-dimethyl-3,3-dimethyl-butyl group is still more preferable and a methyl group, an ethyl group, or a tert-butyl group is particularly preferable.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and a cyclodecadiene group; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Specific examples of the monovalent aromatic hydrocarbon group having 6 to 20 carbon atoms include a phenyl group, a 2,6-diethylphenyl group, a naphthyl group, and a biphenyl group, and an aryl group having 6 to 12 carbon atoms (particularly, a phenyl group) is preferable.

Specific examples of the monovalent aromatic heterocyclic group having 6 to 20 carbon atoms include a 4-pyridyl group, a 2-furyl group, a 2-thienyl group, a 2-pyrimidinyl group, and a 2-benzothiazolyl group.

Examples of the halogen atom include a fluorine atom, a chlorine atom, a bromine atom, and an iodine atom, and among these, a fluorine atom, a chlorine atom, or a bromine atom is preferable.

On the other hand, specific examples of the alkyl group having 1 to 6 carbon atoms represented by one aspect of R⁷ to R¹⁰ include a methyl group, an ethyl group, a propyl group, an isopropyl group, a n-butyl group, an isobutyl group, a sec-butyl group, a tert-butyl group, a n-pentyl group, and a n-hexyl group.

As described above, Z¹ and Z² may be bonded to each other to form an aromatic ring, and examples of a structure in a case where Z¹ and Z² in Formula (Ar-1) are bonded to each other to form an aromatic ring include a group represented by Formula (Ar-la). In Formula (Ar-la), * represents a bonding position to D¹ or D² in Formula (I) described above.

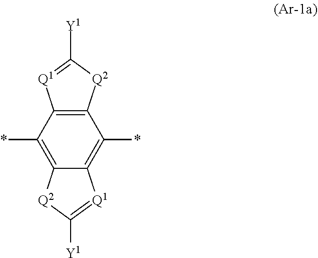

Here, in Formula (Ar-la), examples of Q¹, Q², and Y¹ include the same as those described in Formula (Ar-1) above.

In addition, in Formulae (Ar-2) and (Ar-3), A³ and A⁴ each independently represent a group selected from the group consisting of —O—, —N(R¹³)—, —S—, and —CO—, and R¹³ represents a hydrogen atom or a substituent.

Examples of the substituent represented by R¹³ include the substituents described in the above substituent group A; and among these, an alkyl group, an alkoxy group, an alkoxycarbonyl group, an alkylcarbonyloxy group, or a halogen atom is preferable.

In addition, in Formula (Ar-2), X represents a non-metal atom of Group 14 to Group 16. Here, a hydrogen atom or a substituent may be bonded to the non-metal atom.

In addition, examples of the non-metal atom of Groups 14 to 16, represented by X, include an oxygen atom, a sulfur atom, a nitrogen atom to which a hydrogen atom or a substituent is bonded [═N—R^{N1}, R^{N1} represents a hydrogen atom or a substituent], and a carbon atom to which a hydrogen atom or a substituent is bonded [═C—(R^{C1})₂, R^{C1} represents a hydrogen atom or a substituent].

Examples of the substituent include the substituents described in the above substituent group A; and among these, examples thereof include an alkyl group, an alkoxy group, an alkyl-substituted alkoxy group, a cyclic alkyl group, an aryl group (for example, a phenyl group, a naphthyl group, or the like), a cyano group, an amino group, a nitro group, an alkylcarbonyl group, a sulfo group, and a hydroxyl group.

In addition, in Formula (Ar-3), D⁷ and D⁸ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms.

Here, specific examples of the divalent linking group include the same groups as those described for D¹, D², D³, D⁴, D⁵, and D⁶ in Formula (I) above.

In addition, in Formula (Ar-3), L³ and L⁴ each independently represent a single bond or a divalent aliphatic hydrocarbon group having 1 to 20 carbon atoms. Here, one or more of —CH₂-'s constituting the aliphatic hydrocarbon group may be replaced with —O—, —S—, —NH—, —N(Q)-, or —CO—. Q represents a substituent. Examples of the substituent include the substituents described in the above substituent group A; and among these, an alkyl group, an alkoxy group, an alkoxycarbonyl group, an alkylcarbonyloxy group, or a halogen atom is preferable.

Here, examples of the aliphatic hydrocarbon group include the same groups as those described for L¹ and L² in Formula (I) above.

In addition, in Formula (Ar-3), P³ and P⁴ each independently represent a monovalent organic group, where at least one of P³ or P⁴ represents a polymerizable group.

Examples of the monovalent organic group include the same groups as those described for P¹ and P² in Formula (I) above.

In addition, examples of the polymerizable group include the same groups as those described for P¹ and P² in Formula (I) above.

In addition, in Formulae (Ar-4) and (Ar-5), Ax represents an organic group having 2 to 30 carbon atoms, which has at least one aromatic ring selected from the group consisting of an aromatic hydrocarbon ring and an aromatic heterocyclic ring.

In addition, in Formulae (Ar-4) and (Ar-5), Ay represents a hydrogen atom, an alkyl group having 1 to 12 carbon atoms, which may have a substituent, or an organic group having 2 to 30 carbon atoms which has at least one aromatic ring selected from the group consisting of an aromatic hydrocarbon ring and an aromatic heterocyclic ring.

Here, the aromatic rings in Ax and Ay may have a substituent, and Ax and Ay may be bonded to each other to form a ring.

In addition, Q³ represents a hydrogen atom or an alkyl group having 1 to 6 carbon atoms, which may have a substituent.

Examples of Ax and Ay include those described in paragraphs [0039] to [0095] of WO2014/010325A.

In addition, specific examples of the alkyl group having 1 to 20 carbon atoms, represented by Q³, include a methyl group, an ethyl group, a propyl group, an isopropyl group, a n-butyl group, an isobutyl group, a sec-butyl group, a tert-butyl group, a n-pentyl group, and a n-hexyl group; and examples of the substituent include the substituents described in the above substituent group A. Among these, an alkyl group, an alkoxy group, an alkoxycarbonyl group, an alkylcarbonyloxy group, or a halogen atom is preferable.

Examples of the compound represented by Formula (I) include polymerizable compounds described in paragraphs [0019] to [0023] of JP2019-139222A, polymerizable compounds described in paragraphs [0059] to [0061] of WO2019/160014A, polymerizable compounds described in paragraph [0055] of WO2019/160016A, compounds (1-1) to (1-19) represented by the following formulae; and compounds (2-1) to (2-5) represented by the following formulae. A group adjacent to an acryloyloxy group in a structure of the compound (1-14) represents a propylene group (a group obtained by substituting a methyl group with an ethylene group), and the compound (1-14) represents a mixture of regioisomers in which the positions of the methyl groups are different.

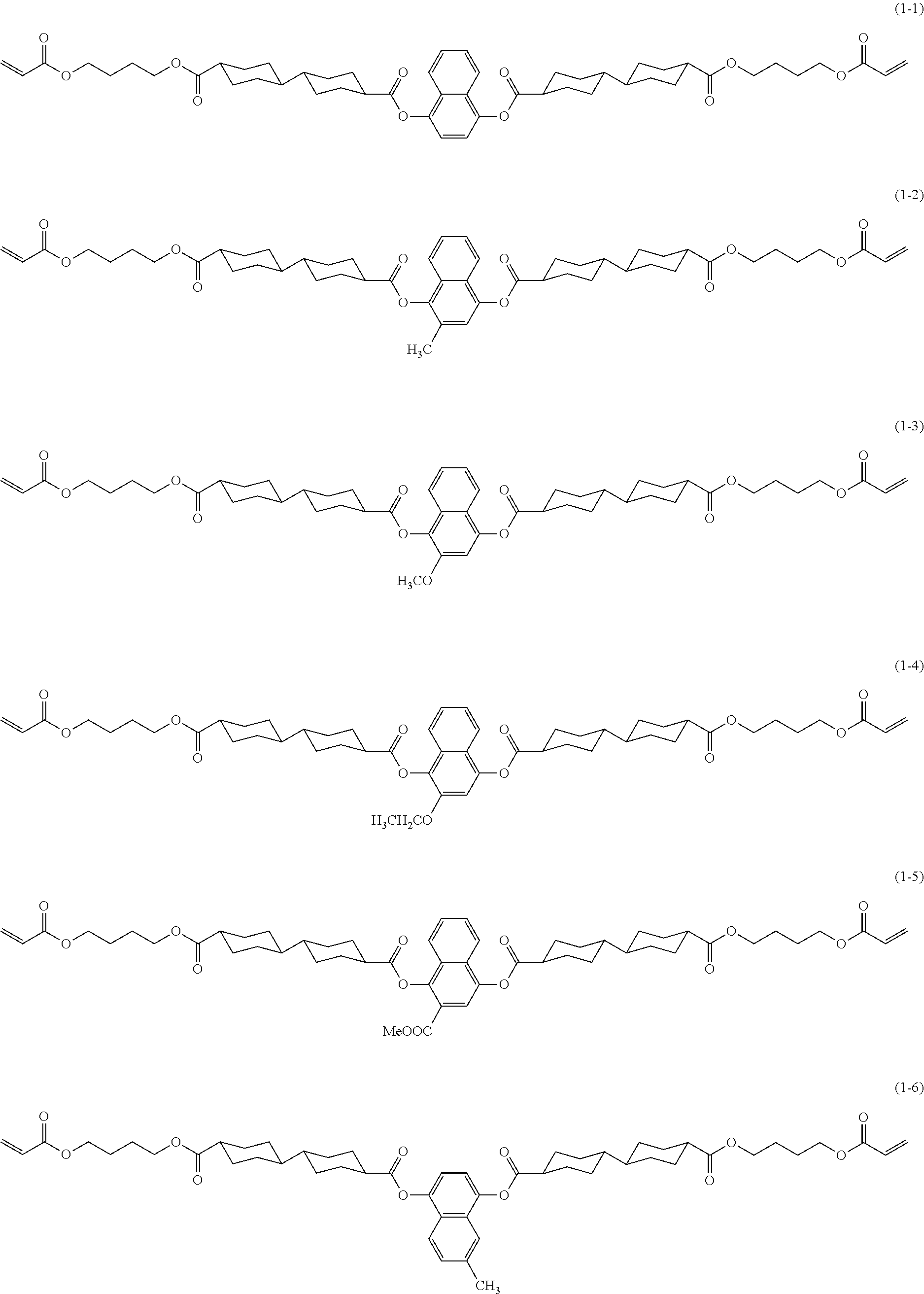

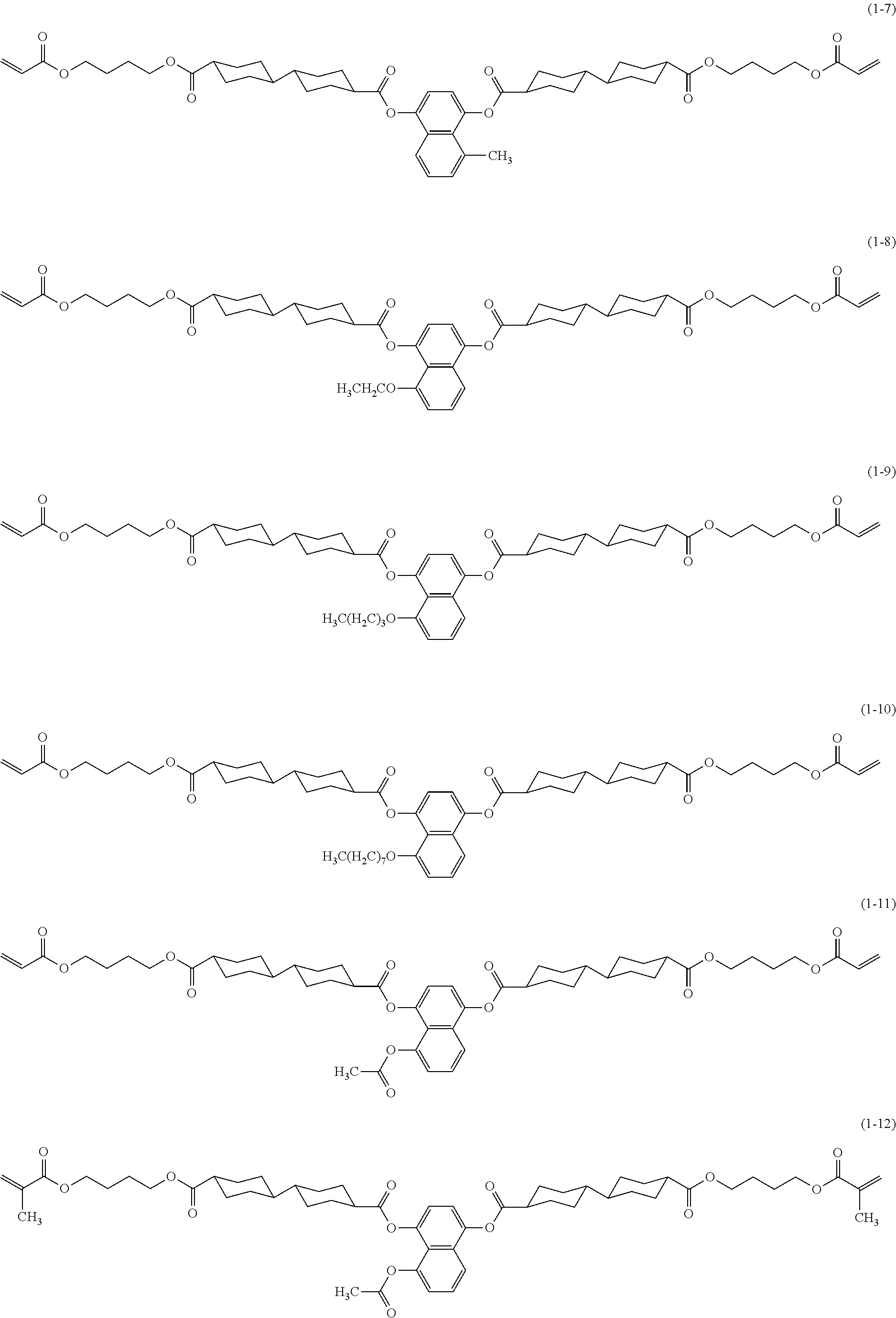

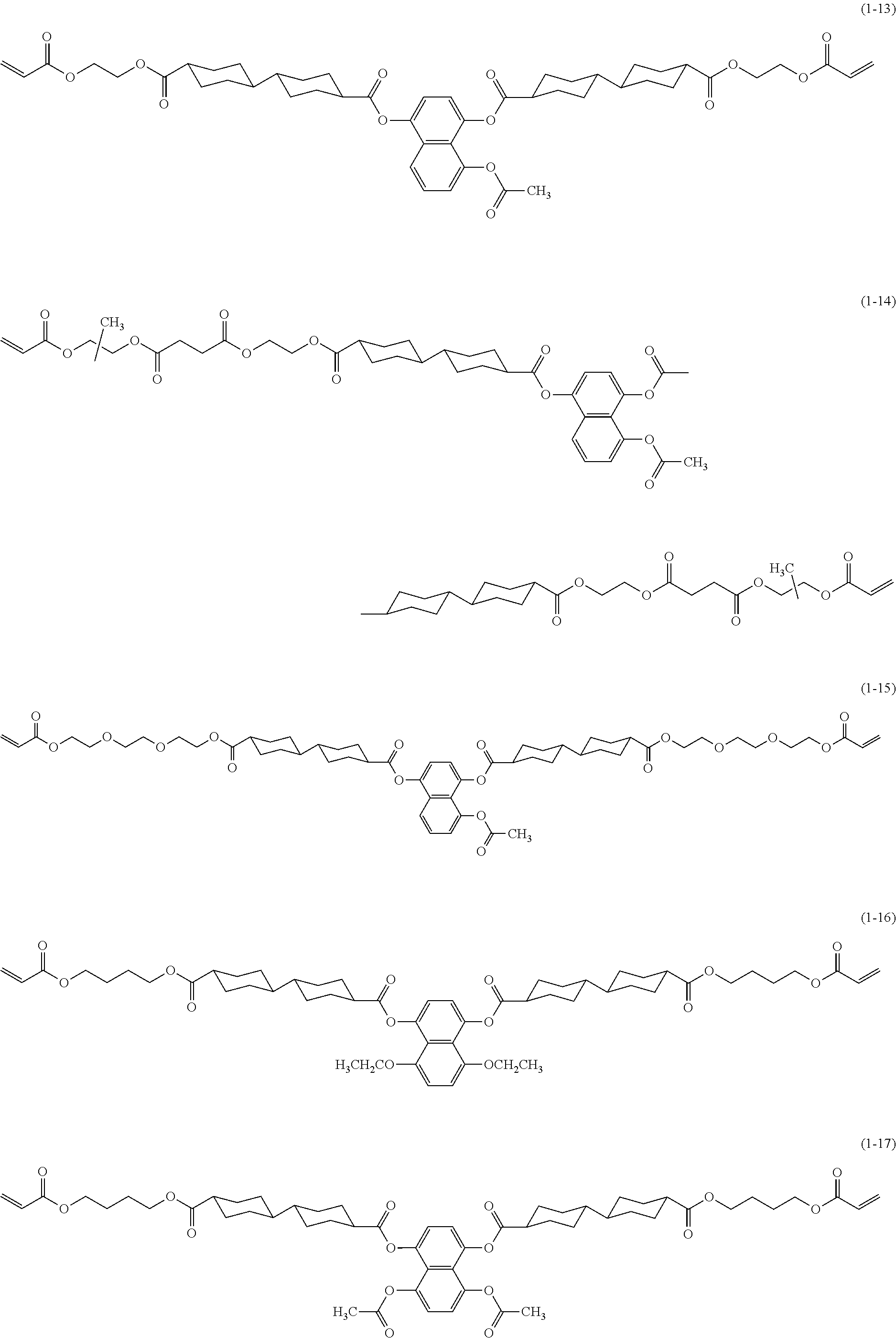

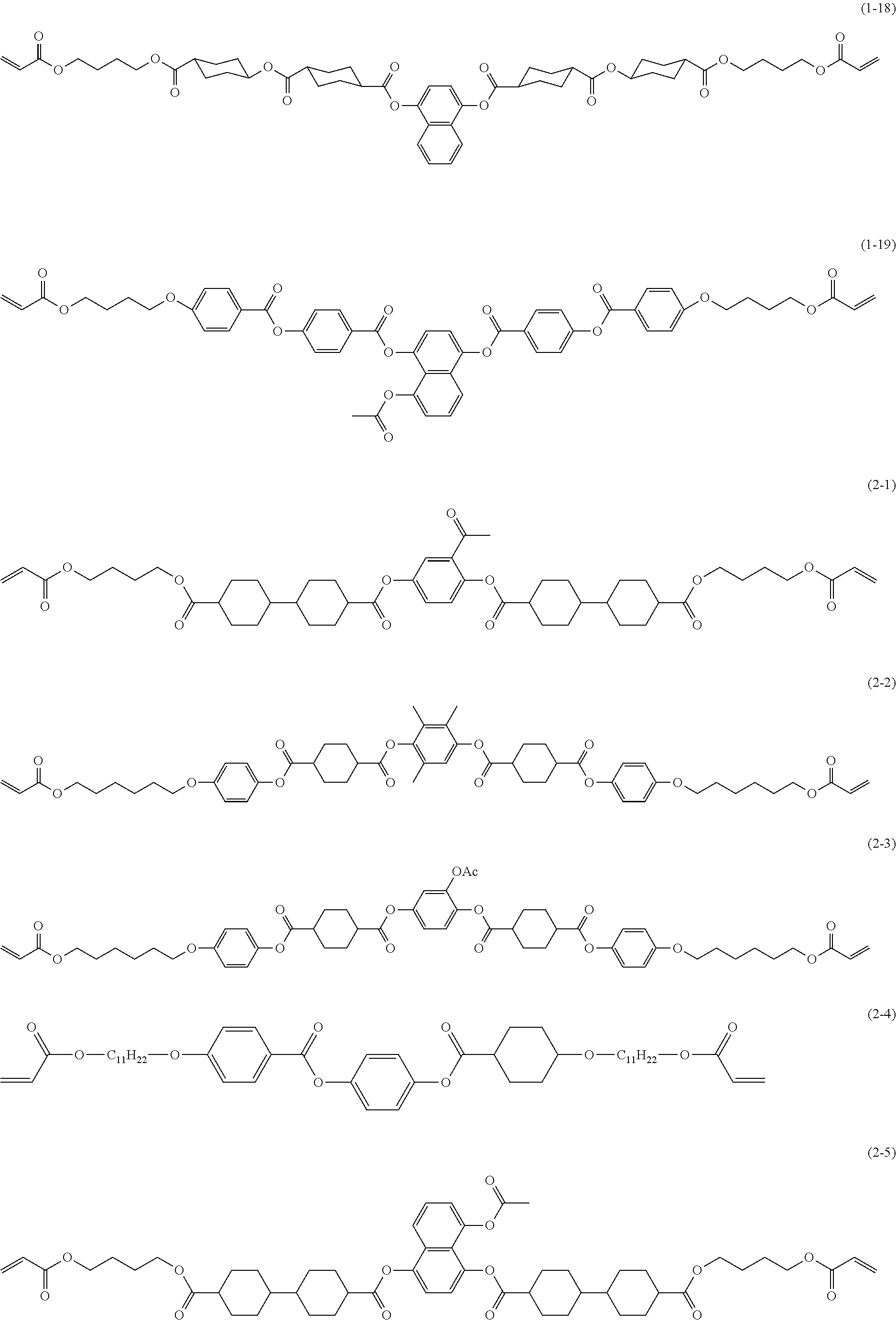

In addition, examples of the compound represented by Formula (I) include a compound represented by General Formula (1) described in JP2010-084032A (particularly, a compound described in paragraphs [0067] to [0073]), a compound represented by General Formula (II) described in JP2016-053709A (particularly, a compound described in paragraphs [0036] to [0043]), a compound represented by General Formula (1) described in JP2016-081035A (particularly, a compound described in paragraphs [0043] to [0055]), and a compound described in paragraphs [0025] to [0056] of WO2021/060427A.

### <Solvent>

The composition for forming a cured film preferably contains a solvent.

Examples of the solvent include ketones [for example, acetone, 2-butanone, methyl ethyl ketone (MEK), methyl isobutyl ketone, cyclohexanone, cyclopentanone (CPO), and the like], ethers [for example, dioxane, tetrahydrofuran (THF), propylene glycol monomethyl ether acetate (PGMEA), and the like], aliphatic hydrocarbons [for example, hexane and the like], alicyclic hydrocarbons [for example, cyclohexane and the like], aromatic hydrocarbons [for example, toluene, xylene, trimethylbenzene, and the like], halogenated carbons [for example, dichloromethane, dichloroethane, dichlorobenzene, chlorotoluene, and the like], esters [for example, methyl acetate, ethyl acetate, butyl acetate, and the like], water, alcohols [for example, methanol (MeOH), ethanol, isopropyl alcohol (IPA), butanol, cyclohexanol, and the like], cellosolves [for example, methyl cellosolve, ethyl cellosolve, and the like], cellosolve acetates, sulfoxides [for example, dimethyl sulfoxide and the like], and amides [for example, dimethylformamide, dimethylacetamide, and the like].

These solvents may be used alone or in combination of two or more kinds thereof.

### <Polymerization Initiator>

The composition for forming a cured film preferably contains a polymerization initiator.

The polymerization initiator is preferably a photopolymerization initiator capable of initiating a polymerization reaction by ultraviolet irradiation.

Examples of the photopolymerization initiator include a-carbonyl compounds (described in U.S. Pat. Nos. 2,367,661A and 2,367,670A), acyloin ethers (described in U.S. Pat. No. 2,448,828A), a-hydrocarbon-substituted aromatic acyloin compounds (described in U.S. Pat. No. 2,722,512A), polynuclear quinone compounds (described in U.S. Pat. Nos. 3,046,127A and 2,951,758A), combinations of triarylimidazole dimer and p-aminophenyl ketone (described in U.S. Pat. No. 3,549,367A), acridine and phenazine compounds (described in JP1985-105667A (JP-S60-105667A) and U.S. Pat. No. 4,239,850A), oxadiazole compounds (described in U.S. Pat. No. 4,212,970A), and acyl phosphine oxide compounds (described in JP1988-40799B (JP-S63-40799B), JP1993-29234B (JP-H05-29234B), JP1998-95788A (JP-H10-95788A), and JP1998-29997A (JP-H10-29997A)).

As the polymerization initiator, an oxime-type polymerization initiator is also preferable. Specific examples thereof include initiators described in paragraphs [0049] to [0052] of WO2017/170443A.

### <Other Components>

The composition for forming a cured film may contain a component other than the above-described components. Examples of other components include a tilt angle control agent, a plasticizer, and a crosslinking agent.

[Method for forming cured film (liquid crystal cured layer)]

Examples of a method for forming the cured film according to the embodiment of the present invention include a method of forming the cured film using the above-described composition for forming a cured film, and immobilizing the liquid crystal compound by polymerization after setting the liquid crystal compound to a desired alignment state.

Here, conditions for setting the desired alignment state are not particularly limited; but it is preferable to perform a heat treatment, and it is more preferable to perform a cooling treatment after the heat treatment. From the viewpoint of manufacturing suitability, a heating temperature in the heat treatment is preferably 10° C. to 250° C., more preferably 50° C. to 200° C., and still more preferably 70° C. to 150° C. In addition, a heating time in the heat treatment is preferably 1 to 300 seconds and more preferably 1 to 60 seconds. In addition, a temperature in the cooling treatment after the heat treatment is not particularly limited as long as it is lower than the heating temperature in the heat treatment, but is preferably room temperature (23° C.) to 80° C.

In addition, conditions for the above-described polymerization are not particularly limited, but ultraviolet rays are preferably used in the polymerization by light irradiation. An irradiation amount is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm². In order to promote the polymerization reaction, the treatment may be performed under heating conditions.

The alignment state of the liquid crystal compound in the cured film according to the embodiment of the present invention may be any of a horizontal alignment state, a vertical alignment state, a tilted alignment state, or a twisted alignment state; but from the viewpoint of suppressing the surface unevenness of the cured film, the cured film according to the embodiment of the present invention is preferably a liquid crystal cured layer obtained by immobilizing the polymerizable liquid crystal compound in a vertically aligned state.

Here, the vertical alignment in a case where the liquid crystal compound is a rod-like liquid crystal compound is also referred to as a homeotropic alignment, and means an alignment in which an angle between a surface (main surface) of the optically anisotropic layer and a director of the rod-like liquid crystal compound is within a range of 70° to 90°. An alignment in which the above-described angle is within a range of 80° to 90° is preferable, and an alignment in which the above-described angle is within a range of 85° to 90° is more preferable.

In addition, the vertical alignment in a case where the liquid crystal compound is a disk-like liquid crystal compound means an alignment in which an angle between a surface (main surface) of the optically anisotropic layer and a disc plane of the disk-like liquid crystal compound is within a range of 70° to 90°. An alignment in which the above-described angle is within a range of 800 to 900 is preferable, and an alignment in which the above-described angle is within a range of 850 to 900 is more preferable.

The cured film according to the embodiment of the present invention is preferably a positive C-plate.

Here, the positive C-plate is defined as follows.

That is, the positive C-plate satisfies a relationship of an expression (C1) in a case where a refractive index in the slow axis direction in a film plane (in a direction such that the in-plane refractive index is maximum) is defined as nx, a refractive index in the in-plane direction orthogonal to the in-plane slow axis is defined as ny, and a thickness-direction refractive index is defined as nz. In the positive C-plate, Rth exhibits a negative value.

$$nz > nx \approx ny \qquad Expression ( C1 )$$

The symbol “≈” encompasses not only a case where both sides are completely the same as each other but also a case where the both sides are substantially the same as each other. As the expression “substantially the same”, for example, “nx≈ny” includes a case where (nx−ny)×d (here, d is a thickness of the film) is 0 to 10 nm, preferably 0 to 5 nm.

In the present invention, a thickness of the cured film according to the embodiment of the present invention is not particularly limited, but is preferably 0.1 to 10 m and more preferably 0.5 to 5 m.

### [Optical Film]

The optical film according to the embodiment of the present invention is an optical film including the cured film according to the embodiment of the present invention.

### [Substrate]

The optical film according to the embodiment of the present invention may include a substrate for supporting the cured film according to the embodiment of the present invention.

Such a substrate is preferably transparent. The term “transparent” in the present invention indicates that the transmittance of visible light is 60% or more, preferably 80% or more and more preferably 90% or more.

In the present invention, from the viewpoint of improving display performance in a case of being used in an image display device (particularly, in a liquid crystal display device), the substrate is preferably a positive A-plate.

Here, in the present specification, the positive A-plate is defined as follows.

That is, the positive A-plate satisfies a relationship of an expression (A1) in a case where a refractive index in the slow axis direction in a film plane (in a direction such that the in-plane refractive index is maximum) is defined as nx, a refractive index in the in-plane direction orthogonal to the in-plane slow axis is defined as ny, and a thickness-direction refractive index is defined as nz. In the positive A-plate, Rth indicates a positive value.

$$n x > ny \approx nz \qquad Expression ( A 1 )$$

The symbol “≈” encompasses not only a case where both sides are completely the same as each other but also a case where the both sides are substantially the same as each other. As the expression “substantially the same”, for example, “ny≈nz” includes a case where (ny−nz)×d (here, d is a thickness of the film) is −10 to 10 nm, preferably −5 to 5 nm.

In addition, in the present invention, it is preferable that the above-described substrate is a liquid crystal cured layer (particularly, an optically anisotropic layer) different from the cured film according to the embodiment of the present invention.

Examples of the liquid crystal cured layer include a liquid crystal cured layer obtained by fixing an alignment state (particularly, a horizontal alignment state) of a liquid crystal compound contained in a liquid crystal composition not containing the above-described surfactant.

Here, regarding the horizontal alignment, the horizontal alignment in a case where the liquid crystal compound is a rod-like liquid crystal compound is also referred to as a homogeneous alignment, and means an alignment in which an angle between a surface (main surface) of the liquid crystal cured layer and a director of the rod-like liquid crystal compound is within a range of 0° to 20°. An alignment in which the above-described angle is within a range of 0° to 100 is preferable, and an alignment in which the above-described angle is within a range of 0° to 5° is more preferable.

In addition, the horizontal alignment in a case where the liquid crystal compound is a disk-like liquid crystal compound means an alignment in which an angle between a surface (main surface) of the liquid crystal cured layer and a disc plane of the disk-like liquid crystal compound is within a range of 0° to 20°. An alignment in which the above-described angle is within a range of 0° to 100 is preferable, and an alignment in which the above-described angle is within a range of 0° to 5° is more preferable.

The optical film according to the embodiment of the present invention may have such a liquid crystal cured layer as a layer configuration other than the above-described substrate.

Furthermore, in the present invention, a polymer film described in a support, which will be described later, may be used as the above-described substrate, and an alignment film described later may be used.

### [Support]

In a case where the optical film according to the embodiment of the present invention includes the above-described other liquid crystal cured layer (optically anisotropic layer) as the above-described substrate, the optical film may include a support for supporting the other liquid crystal cured layer.

Such a support is preferably transparent. The term “transparent” in the present invention indicates that the transmittance of visible light is 60% or more, preferably 80% or more and more preferably 90% or more.

Examples of the above-described support include a glass substrate and a polymer film.

Examples of a material of the polymer film include cellulose-based polymers; acrylic polymers having an acrylic acid ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

A thickness of the above-described support is not particularly limited, but is preferably 1 to 200 m and more preferably 2 to 100 m.

### [Alignment Film]

The cured film of the optical film according to the embodiment of the present invention and any other liquid crystal cured layer may be formed on a surface of an alignment film (particularly, a photo-alignment film described later).

The alignment film may be any film as long as it has a function of aligning the liquid crystal compound contained in the composition.

The alignment film generally contains a polymer as a main component. A polymer material for the alignment film is described in many documents, and many commercially available products can be used.

As the polymer material for the alignment film, a polyvinyl alcohol, a polyimide, or a derivative thereof is preferable, and a modified or unmodified polyvinyl alcohol is more preferable.

Examples of the alignment film which may be included in the optical film include alignment films described in Line 24 on Page 43 to Line 8 on Page 49 of WO01/88574A; alignment films consisting of modified polyvinyl alcohols described in paragraphs [0071] to [0095] of JP3907735B; and liquid crystal alignment films formed using a liquid crystal aligning agent described in JP2012-155308A.

Since an object does not come into contact with a surface of the alignment film in the formation of the alignment film and the deterioration of a surface condition can be prevented, it is preferable to use a photo-alignment film as the alignment film.

The photo-alignment film is not particularly limited; but an alignment film formed by a polymer material such as a polyamide compound and a polyimide compound described in paragraphs [0024] to [0043] of WO2005/096041A, a liquid crystal alignment film formed by a liquid crystal aligning agent having a photo-aligned group described in JP2012-155308A, trade name LPP-JP265CP manufactured by Rolic Technologies Ltd., or the like can be used.

A thickness of the above-described alignment film is not particularly limited, but is preferably 0.01 to 10 m, more preferably 0.01 to 1 m, and still more preferably 0.01 to 0.5 m.

### [Polarizing Plate]

A polarizing plate is preferably a polarizing plate including the above-described optical film according to the embodiment of the present invention and a polarizer.

### [Polarizer]

The polarizer included in the polarizing plate is not particularly limited as long as the polarizer is a member having a function of converting light into specific linearly polarized light, and a known absorptive type polarizer and reflective type polarizer in the related art can be used.

An iodine-based polarizer, a dye-based polarizer using a dichroic dye, a polyene-based polarizer, or the like is used as the absorptive type polarizer. The iodine-based polarizer and the dye-based polarizer include a coating type polarizer and a stretching type polarizer, and any one of these polarizers can be applied. However, a polarizer which is produced by allowing polyvinyl alcohol to adsorb iodine or a dichroic dye and performing stretching is preferable.

In addition, examples of a method of obtaining a polarizer by performing stretching and dyeing in a state of a laminated film in which a polyvinyl alcohol layer is formed on a substrate include methods disclosed in JP5048120B, JP5143918B, JP4691205B, JP4751481B, and JP4751486B, and known technologies related to these polarizers can be preferably used.

A polarizer in which thin films having different birefringence are laminated, a wire grid type polarizer, a polarizer in which a cholesteric liquid crystal having a selective reflection range and a ¼ wavelength plate are combined, or the like is used as the reflective type polarizer.

Among these, from the viewpoint of more excellent adhesiveness, a polarizer containing a polyvinyl alcohol-based resin (polymer including —CH₂—CHOH— as a repeating unit; in particular, at least one selected from the group consisting of polyvinyl alcohol and an ethylene-vinyl alcohol copolymer) is preferable.

In the present invention, a thickness of the polarizer is not particularly limited, but is preferably 5 to 40 m, more preferably 5 to 30 m, and still more preferably 5 to 20 m. With the above-described thickness, it is possible to reduce the thickness of a display device.

### [Image Display Device]

The image display device according to the embodiment of the present invention is an image display device including the optical film according to the embodiment of the present invention or the polarizing plate (hereinafter, collectively referred to as “optical film or the like according to the embodiment of the present invention”).

A display element used in the image display device is not particularly limited, and examples thereof include a liquid crystal cell, an organic electroluminescent (hereinafter, simply referred to as “EL”) display panel, and a plasma display panel. Among these, a liquid crystal cell or an organic EL display panel is preferable, and a liquid crystal cell is more preferable.

That is, as the image display device, a liquid crystal display device using a liquid crystal cell as the display element or an organic EL display device using an organic EL display panel as the display element is preferable, and the liquid crystal display device is more preferable.

### [Liquid Crystal Display Device]

A liquid crystal display device as an example of the image display device is a liquid crystal display device including the optical film or the like according to the embodiment of the present invention and a liquid crystal cell.

Among polarizing plates provided on both sides of the liquid crystal cell, it is preferable that the optical film or the like according to the embodiment of the present invention is used as a polarizing plate on the front side, and it is more preferable that the optical film or the like according to the embodiment of the present invention is used as polarizing plates on the front and rear sides.

Hereinafter, the liquid crystal cell constituting the liquid crystal display device will be described in detail.

### <Liquid Crystal Cell>

It is preferable that the liquid crystal cell used in the liquid crystal display device is in a vertical alignment (VA) mode, an optically compensated bend (OCB) mode, an in-plane-switching (IPS) mode, a fringe-field-switching (FFS) mode, or a twisted nematic (TN) mode, but is not limited thereto.

In the liquid crystal cell in a TN mode, rod-like liquid crystal molecules are substantially horizontally aligned at the time of no voltage application and further twisted and aligned at 600 to 120°. The liquid crystal cell in a TN mode is most frequently used as a color TFT liquid crystal display device and is described in a plurality of documents.

In the liquid crystal cell in a VA mode, rod-like liquid crystal molecules are substantially vertically aligned at the time of no voltage application. The concept of the liquid crystal cell in a VA mode includes (1) a liquid crystal cell in a VA mode in a narrow sense where rod-like liquid crystal molecules are aligned substantially vertically at the time of no voltage application and substantially horizontally at the time of voltage application (described in JP1990-176625A (JP-H2-176625A)), (2) a liquid crystal cell (in an MVA mode) (SID97, described in Digest of tech. Papers (proceedings) 28 (1997) 845) in which the VA mode is formed to have multi-domain in order to widen the viewing angle, (3) a liquid crystal cell in a mode (n-ASM mode) in which rod-like liquid crystal molecules are substantially vertically aligned at the time of no voltage application and twistedly multi-domain aligned at the time of voltage application (described in proceedings of Japanese Liquid Crystal Conference, pp. 58 to 59 (1998)), and (4) a liquid crystal cell in a SURVIVAL mode (presented at LCD International 98). In addition, the liquid crystal cell in the VA mode may be any of a patterned vertical alignment (PVA) type, an optical alignment type, or a polymer-sustained alignment (PSA) type. The details of these modes are described in JP2006-215326A and JP2008-538819A.

In an IPS mode liquid crystal cell, rod-like liquid crystal molecules are substantially aligned parallel to a substrate and application of an electric field parallel to a surface of the substrate causes the liquid crystal molecules to respond planarly. In the IPS mode, black display is carried out in a state where no electric field is applied, and absorption axes of a pair of upper and lower polarizing plates are orthogonal to each other. A method of reducing light leakage during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), JP1998-307291A (JP-H10-307291A), and the like.

### [Organic EL Display Device]

Examples of an organic EL display device as an example of the image display device include an aspect in which the polarizing plate according to the embodiment of the present invention (a polarizing plate in which the polarizer is disposed on a viewing side) and an organic EL display panel are provided in this order from a viewing side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to Examples. The materials, amounts used, proportions, treatment contents, treatment procedures, and the like shown in the following examples can be modified as appropriate in the range of not departing from the spirit of the present invention. Therefore, the scope of the present invention should not be construed as being limited to Examples.

### Example 1

### [Production of Cellulose Acylate Film 1 (Support)]

### <Preparation of Core Layer Cellulose Acylate Dope 1>

The following composition was put into a mixing tank and stirred to dissolve the respective components, thereby preparing a core layer cellulose acylate dope 1.

Core layer cellulose acylate dope 1

| | |
|---|---|
| Cellulose acetate having acetyl | 100 parts by mass |
| substitution degree of 2.88 | |
| Polyester shown below | 12 parts by mass |
| Durability improver shown below | 4 parts by mass |
| Methylene chloride (first solvent) | 430 parts by mass |
| Methanol (second solvent) | 64 parts by mass |

### Polyester (Number-Average Molecular Weight: 800)

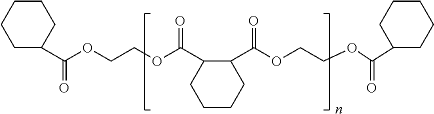

### Durability Improver

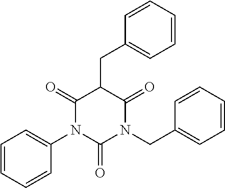 [SMILES: O=C1C(Cc2ccccc2)C(=O)N(c2ccccc2)C(=O)N1Cc1ccccc1]

### <Preparation of Outer Layer Cellulose Acylate Dope 1>

10 parts by mass of the following matting agent dispersion liquid 1 was added to 90 parts by mass of the above-described core layer cellulose acylate dope 1, thereby preparing an outer layer cellulose acylate dope 1.

Matting agent dispersion liquid 1

| | |
|---|---|
| Silica particles with average particle | 2 parts by mass |
| size of 20 nm (AEROSIL R972, manufactured | |
| by Nippon Aerosil Co., Ltd.) | |
| Methylene chloride (first solvent) | 76 parts by mass |
| Methanol (second solvent) | 11 parts by mass |
| Core layer cellulose acylate dope 1 | 1 part by mass |

### <Production of Cellulose Acylate Film 1 (Support)>

The above-described core layer cellulose acylate dope 1 and the above-described outer layer cellulose acylate dope 1 were filtered using a filter paper with an average hole diameter of 34 m and a sintered metal filter with an average hole diameter of 10 m. Thereafter, the above-described core layer cellulose acylate dope 1 and the outer layer cellulose acylate dopes 1 on both sides thereof were cast simultaneously on a drum at 20° C. from a casting port in three layers, using a band casting machine.

Subsequently, a film was peeled off from the drum in a state in which a solvent content of the film on the drum was approximately 20% by mass. Both ends of the obtained film in a width direction were fixed with tenter clips, and the film was dried while being stretched 1.1 times in the width direction in a state in which the solvent content of the film was 3% to 15% by mass.

Thereafter, the obtained film was further dried while being transported between rolls of a heat treatment device, thereby producing a cellulose acylate film 1 (support) having a film thickness of 40 m. As a result of measuring a phase difference (retardation) of the cellulose acylate film 1 (support), Re=1 nm and Rth=−5 nm were obtained.

### [Production of Photo-Alignment Film 1 and Optically Anisotropic Layer 1 (Substrate)]

### <Preparation of Composition 1 for Forming Photo-Alignment Film>

A composition 1 for forming a photo-alignment film, having the following formulation, was prepared.

Composition 1 for forming photo-alignment film

| | |
|---|---|
| Copolymer C1 shown below | 100 parts by mass |
| Thermal acid generator D1 shown below | 3.57 parts by mass |
| Stabilizer DIPEA shown below | 0.36 parts by mass |
| Butyl acetate | 714 parts by mass |
| Methyl ethyl ketone | 476 parts by mass |

### Copolymer C1 (Weight-Average Molecular Weight: 40,000)

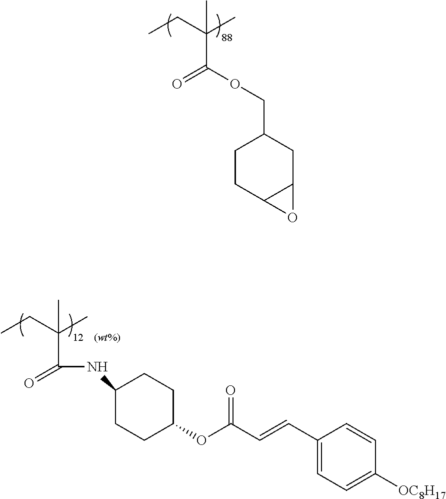

### Thermal Acid Generator D1

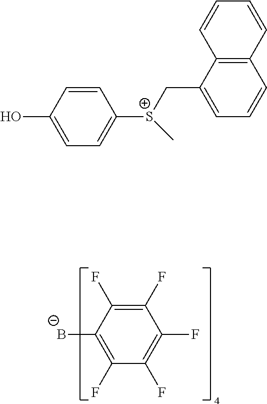

### Stabilizer DIPEA

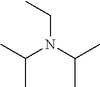

### <Preparation of Liquid Crystal Composition 1>

A liquid crystal composition 1 for forming an optically anisotropic layer, having the following formulation, was prepared.

Liquid crystal composition 1

| | |
|---|---|
| Liquid crystal compound R1 shown below | 27.00 parts by mass |
| Liquid crystal compound R2 shown below | 20.00 parts by mass |
| Liquid crystal compound R3 shown below | 20.00 parts by mass |
| Liquid crystal compound R4 shown below | 16.50 parts by mass |
| Liquid crystal compound R5 shown below | 16.50 parts by mass |
| Liquid crystal compound R6 shown below | 15.00 parts by mass |
| Additive M1 shown below | 3.00 parts by mass |
| Polymerization initiator S1 shown below | 0.50 parts by mass |
| Leveling agent P1 shown below | 0.09 parts by mass |
| Cyclopentanone | 179.67 parts by mass |
| Methyl ethyl ketone | 53.67 parts by mass |

Liquid crystal compound R1 [Δn(450)/Δn(550): 0.58]

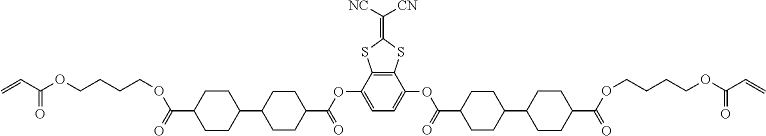 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]

Liquid crystal compound R2 (in the following formula, t-Bu represents a tert-butyl group) [Δn(450)/Δn(550): 0.68]

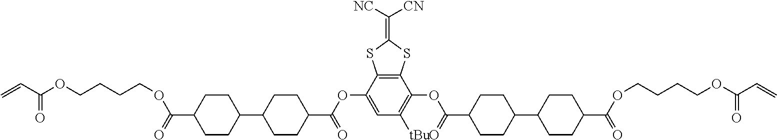 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]

Liquid crystal compound R3 [in the following formula, a group adjacent to an acryloyloxy group represents a propylene group (a group in which a methyl group is substituted with an ethylene group)][Δn(450)/Δn(550): 0.80]

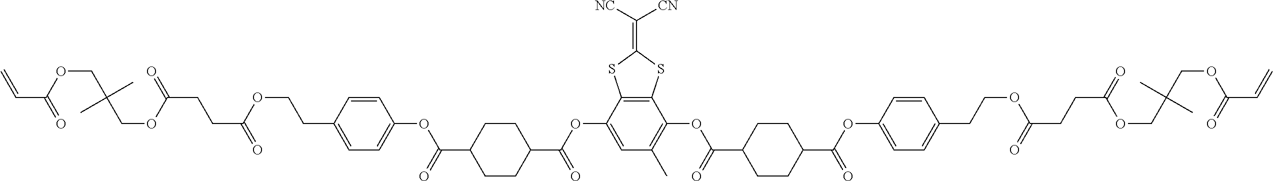 [SMILES: C=CC(=O)OCC(C)(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]

Liquid crystal compound R4 [Δn(450)/Δn(550): 1.03]

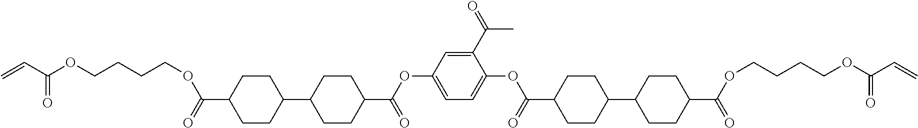 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c(C(C)=O)c3)CC2)CC1]

Liquid crystal compound R5 [Δn(450)/Δn(550): 1.02]

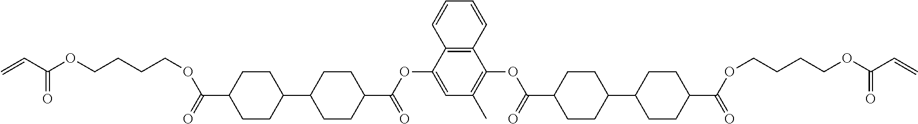 [SMILES: C=CC(=O)OCCCCOC(=O)C1CCC(C2CCC(C(=O)Oc3cc(C)c(OC(=O)C4CCC(C5CCC(C(=O)OCCCCOC(=O)C=C)CC5)CC4)c4ccccc34)CC2)CC1]

Liquid crystal compound R6 [Δn(450)/Δn(550): 1.03]

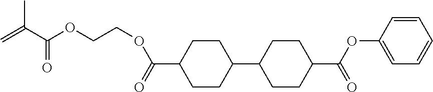 [SMILES: C=C(C)C(=O)OCCOC(=O)C1CCC(C2CCC(C(=O)Oc3ccccc3)CC2)CC1]

### Polymerization Initiator S1

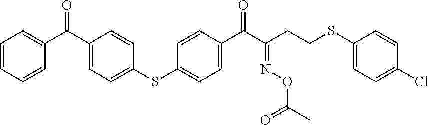 [SMILES: CC(=O)O/N=C(\CCSc1ccc(Cl)cc1)C(=O)c1ccc(Sc2ccc(C(=O)c3ccccc3)cc2)cc1]

Additive M1

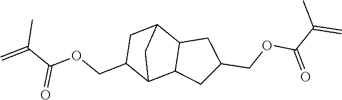 [SMILES: C=C(C)C(=O)OCC1CC2C3CC(COC(=O)C(=C)C)C(C3)C2C1]

Leveling agent P1 [the numerical value in the following formula indicates the content (% by mass) of each repeating unit with respect to all repeating units in the leveling agent P1]

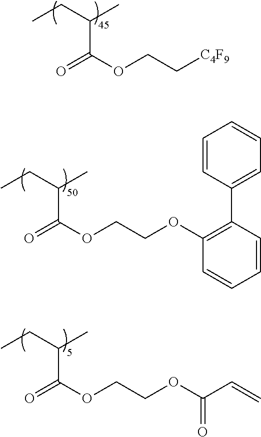

### <Production of Photo-Alignment Film 1 and Optically Anisotropic Layer 1 (Substrate)>

The composition 1 for a photo-alignment film prepared above was applied onto one surface of the produced cellulose acylate film 1 (support) with a bar coater. After the application, the solvent was removed by drying in a heating zone at 120° C. for 1 minute to form a 0.3 m-thick photoisomerization composition layer.

Next, a photo-alignment film 1 was formed through irradiation with polarized ultraviolet rays (10 mJ/cm², using an ultra-high pressure mercury lamp) while winding a mirror-treated backup roll.

Subsequently, the liquid crystal composition 1 prepared above was applied onto the photo-alignment film 1 formed in a long shape with a bar coater to form a composition layer. In addition, a temperature of the coating chamber was set to 23° C. The formed composition layer was heated to 120° C. in a heating zone, and then cooled to 60° C. Thereafter, the alignment was fixed by carrying out ultraviolet irradiation (300 mJ/cm², using an ultra-high pressure mercury lamp) in a nitrogen atmosphere (oxygen concentration: 100 ppm) while maintaining the temperature, thereby forming an optically anisotropic layer 1 (substrate) having a thickness of 2.2 m.

In the obtained optically anisotropic layer 1 (substrate), a peeling force at an interface with the photo-alignment film 1 was 0.05 N/25 mm; and in a case where measurement was performed on the peeled optically anisotropic layer 1, it was confirmed that a slow axis direction was a longitudinal direction of the film, an in-plane retardation Re(550) was 130 nm, Re(450)/Re(550) was 0.85, and the optically anisotropic layer 1 was a positive A-plate.

### [Formation of Cured Film 1 (Production of Optical Film)]

### <Preparation of Composition 1 for Forming Cured Film>

A composition 1 for forming a cured film, having the following formulation, was prepared.

Composition 1 for forming cured film

| | |
|---|---|
| Liquid crystal compound R1 shown above | 24.80 parts by mass |
| Liquid crystal compound R2 shown above | 24.80 parts by mass |
| Liquid crystal compound R3 shown above | 10.00 parts by mass |
| Liquid crystal compound R4 shown above | 20.20 parts by mass |
| Liquid crystal compound R5 shown above | 20.20 parts by mass |
| Liquid crystal compound R6 shown above | 15.00 parts by mass |
| Boronic acid monomer B1 shown below | 3.00 parts by mass |
| DPHA-76 (manufactured by Osaka | 8.00 parts by mass |
| Organic Chemical Industry Ltd.) | |
| shown below | |
| Polymerization initiator S1 shown above | 3.00 parts by mass |
| Leveling agent P2-1 shown below | 0.21 parts by mass |
| Cyclopentanone | 232.96 parts by mass |
| Methyl ethyl ketone | 116.48 parts by mass |
| Isopropyl alcohol | 19.41 parts by mass |
| Methanol | 19.41 parts by mass |

### Boronic Acid Monomer B1

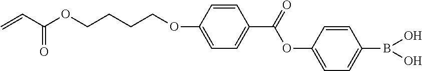 [SMILES: C=CC(=O)OCCCCOc1ccc(C(=O)Oc2ccc(B(O)O)cc2)cc1]

### DPHA-76

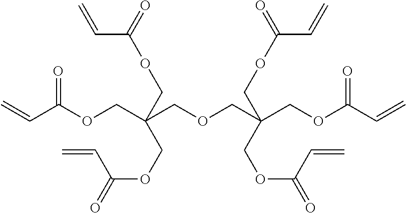 [SMILES: C=CC(=O)OCC(COCC(COC(=O)C=C)(COC(=O)C=C)COC(=O)C=C)(COC(=O)C=C)COC(=O)C=C]

Leveling agent P2-1 [weight-average molecular weight: 36,500; the numerical value in the following formula indicates the content (% by mass) of each repeating unit with respect to all repeating units in the leveling agent P2-1]

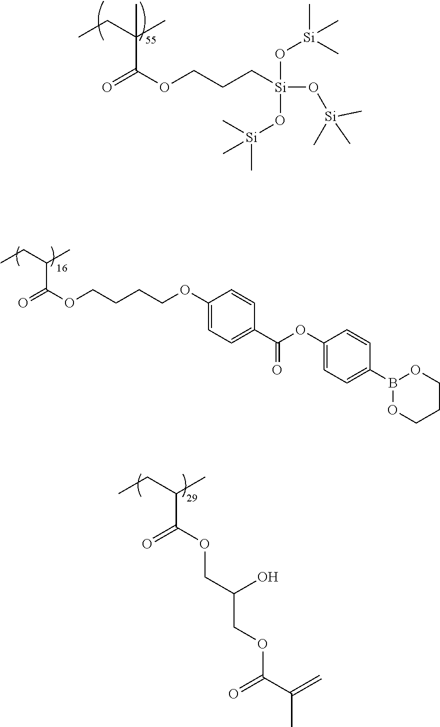

### <Formation of Cured Film 1>

The surface of the optically anisotropic layer 1 (substrate) on the air-interface side (side opposite to the photo-alignment film 1) was subjected to a corona treatment at a discharge amount of 150 W min/m².

Next, the composition 1 for forming a cured film prepared above was applied onto the surface subjected to the corona treatment with a die coater to form a composition layer. Thereafter, for drying the solvent of the composition and for alignment maturation of the liquid crystal compound, the composition layer was heated at 65° C. for 60 seconds. The alignment was fixed by performing ultraviolet irradiation (150 mJ/cm²) at 50° C. in a nitrogen purge atmosphere with an oxygen concentration of 100 ppm to form a cured film 1 having a thickness of 1.5 m, thereby producing an optical film [layer configuration: cellulose acylate film 1 (support)/photo-alignment film 1/optically anisotropic layer 1 (substrate)/cured film 1].

In a case where a laminate of the optically anisotropic layer 1 and the cured film 1 was peeled off from the produced optical film, a phase difference of the laminate was measured, and the phase difference of the optically anisotropic layer 1 measured in advance was subtracted to calculate a phase difference of the cured film 1, it was confirmed that a thickness direction retardation RthC(550) was −90 nm, RthC(450)/RthC(550) was 0.88, and the cured film 1 was a positive C-plate (nz>nx=ny).

### Examples 2 to 10 and Comparative Examples 1 and 2

A cured film was formed and an optical film was produced by the same method as in Example 1, except that the type and content (parts by mass) of the leveling agent contained in the composition for forming a cured film were set to the type and content shown in Table 1.

### Example 11

### [Production of Optically Anisotropic Layer 2]

### <Preparation of Liquid Crystal Composition 2>

A liquid crystal composition 2 for forming an optically anisotropic layer, having the following formulation, was prepared.

Liquid crystal composition 2

| | |
|---|---|
| Liquid crystal compound R7 shown below | 100.0 parts by mass |
| Photopolymerization initiator S2 shown below | 5.0 parts by mass |
| Photopolymerization initiator S3 shown below | 2.0 parts by mass |
| Alignment assistant A1 shown below | 2.0 parts by mass |
| Boronic acid monomer B1 shown above | 4.5 parts by mass |
| A-TMMT (manufactured by Shin-Nakamura | 8.0 parts by mass |
| Chemical Co., Ltd.) shown below | |
| Leveling agent P1-2 shown below | 0.4 parts by mass |
| Leveling agent P1-3 shown below | 0.5 parts by mass |
| Acetone | 426.0 parts by mass |
| PGMEA | 49.0 parts by mass |
| Methanol | 14.7 parts by mass |

Liquid crystal compound R7 (mixture of the following liquid crystal compounds (RA), (RB), and (RC) at a mass ratio of 83:15:2; Me in the following liquid crystal compounds (RB) and (RC) represents a methyl group]

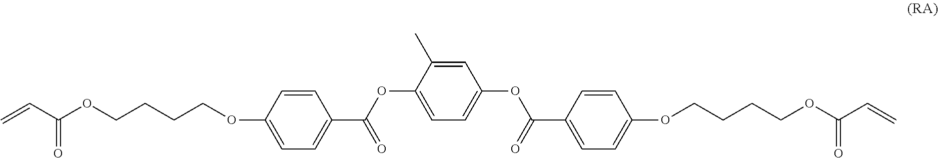 [SMILES: C=CC(=O)OCCCCOc1ccc(C(=O)Oc2ccc(OC(=O)c3ccc(OCCCCOC(=O)C=C)cc3)c(C)c2)cc1]

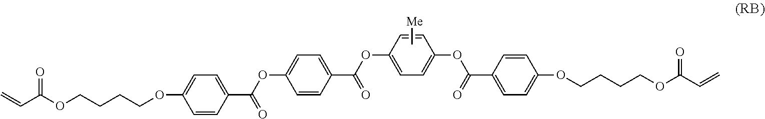

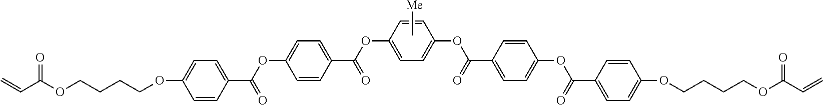

### Photopolymerization Initiator S2

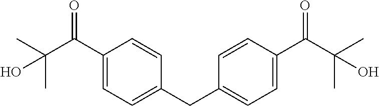 [SMILES: CC(C)(O)C(=O)c1ccc(Cc2ccc(C(=O)C(C)(C)O)cc2)cc1]

### Photopolymerization Initiator S3

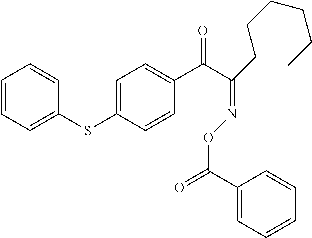 [SMILES: CCCCCC/C(=N/OC(=O)c1ccccc1)C(=O)c1ccc(Sc2ccccc2)cc1]

### Alignment Assistant A1

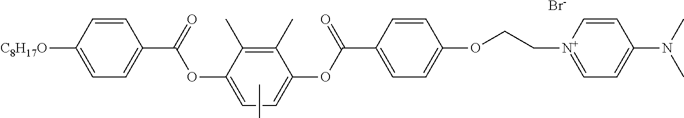

### A-TMMT (Manufactured by Shin-Nakamura Chemical Co., Ltd.)

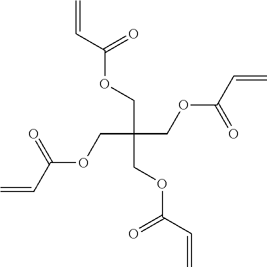 [SMILES: C=CC(=O)OCC(COC(=O)C=C)(COC(=O)C=C)COC(=O)C=C]

Leveling agent P1-2 [weight-average molecular weight. 15,000; the numerical value in the following formula indicates the content (% by mass) of each repeating unit with respect to all repeating units]

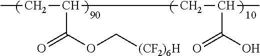

Leveling agent P1-3 [weight-average molecular weight. 11,200; the numerical value in the following formula indicates the content (% by mass) of each repeating unit with respect to all repeating units]

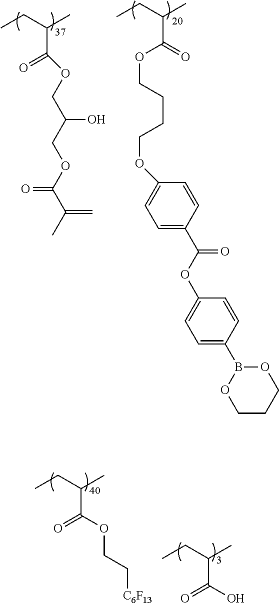

### <Production of Optically Anisotropic Layer 2>

One surface of a cycloolefin polymer (COP) film (Re=125 nm, Rth=63 nm, manufactured by JSR Corporation) was subjected to a corona treatment at a discharge amount of 125 W·min/m², and the liquid crystal composition 2 prepared above was applied onto the surface subjected to the corona treatment with a #3.0 wire bar.

Next, for drying the solvent of the composition and for alignment maturation of the liquid crystal compound, the composition was heated with hot air at 70° C. for 90 seconds, and then ultraviolet irradiation (300 mJ/cm²) was carried out at 40° C. under nitrogen purge at an oxygen concentration of 0.1% to fix the alignment of the liquid crystal compound, thereby producing an optically anisotropic layer 2.

In a case where a phase difference of the laminate of the obtained optically anisotropic layer 2 and the COP film was measured, an in-plane retardation Re(550) was 125 nm, and a thickness direction retardation Rth(550) was −25 nm. In addition, Re(450)/Re(550) was 1.01 and Rth(450)/Rth(550) was 1.06.

### [Formation of Cured Film 11 (Production of Optical Film)]

### <Preparation of Composition 11 for Forming Cured Film>

A composition 11 for forming a cured film, having the following formulation, was prepared.

Composition 11 for forming cured film

| | |
|---|---|
| A-TMMT (manufactured by Shin-Nakamura | 71.8 parts by mass |
| Chemical Co., Ltd.) shown above | |
| A-600 (manufactured by Shin-Nakamura | 23.9 parts by mass |
| Chemical Co., Ltd.) shown below | |
| Boronic acid monomer B1 shown above | 4.3 parts by mass |
| Photopolymerization initiator S2 shown above | 5.0 parts by mass |
| Leveling agent P2-1 shown above | 0.5 parts by mass |
| Acetone | 382.8 parts by mass |
| PGMEA | 44.0 parts by mass |
| Methanol | 13.2 parts by mass |

A-600 (manufactured by Shin-Nakamura Chemical Co., Ltd.)

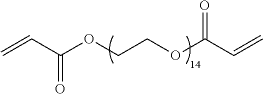

### <Formation of Cured Film 11>

The surface of the COP film (substrate) opposite to the optically anisotropic layer 2 was subjected to a corona treatment at a discharge amount of 125 W min/m².

Next, the composition 11 for forming a cured film prepared above was applied onto the surface subjected to the corona treatment with a #3.0 wire bar.

Next, for drying the solvent of the composition, the composition was heated with hot air at 70° C. for 90 seconds, and then ultraviolet irradiation (300 mJ/cm²) was carried out at 40° C. in a nitrogen purge atmosphere with an oxygen concentration of 0.1% to form a cured film 11, thereby producing an optical film [layer configuration: optically anisotropic layer 2/COP film (substrate)/cured film 11].

In a case where a phase difference of the optical film was measured, an in-plane retardation Re(550) was 125 nm, and a thickness direction retardation Rth(550) was −25 nm. In addition, Re(450)/Re(550) was 1.01, Rth(450)/Rth(550) was 1.06, and a change A in phase difference from the laminate of the optically anisotropic layer 2 and the COP film was ΔRe=0 nm and ΔRth=0 nm.

### Example 12

### [Formation of Cured Film 12 (Production of Optical Film)]

<Preparation of composition 12 for forming cured film>

A composition 12 for forming a cured film, having the following formulation, was prepared.

Composition 12 for forming cured film

| | |
|---|---|
| Liquid crystal compound R1 shown above | 27.00 parts by mass |
| Liquid crystal compound R2 shown above | 20.00 parts by mass |
| Liquid crystal compound R3 shown above | 20.00 parts by mass |
| Liquid crystal compound R4 shown above | 16.50 parts by mass |
| Liquid crystal compound R5 shown above | 16.50 parts by mass |
| Liquid crystal compound R6 shown above | 15.00 parts by mass |
| Additive M1 shown above | 3.00 parts by mass |
| Polymerization initiator S1 shown above | 0.50 parts by mass |
| Leveling agent P2-1 shown above | 0.21 parts by mass |
| Cyclopentanone | 179.67 parts by mass |
| Methyl ethyl ketone | 53.67 parts by mass |

### <Formation of Cured Film 12>

The photo-alignment film 1 was formed on the cellulose acylate film 1 (support) by the same method as in Example 1.

Next, the composition 12 for forming a cured film prepared above was applied onto the photo-alignment film 1 as a substrate with a bar coater to form a composition layer. In addition, a temperature of the coating chamber was set to 23° C. The formed composition layer was heated to 120° C. in a heating zone, and then cooled to 60° C. Thereafter, the alignment was fixed by carrying out ultraviolet irradiation (300 mJ/cm², using an ultra-high pressure mercury lamp) in a nitrogen atmosphere (oxygen concentration: 100 ppm) while maintaining the temperature, thereby forming a cured film 12 having a thickness of 2.2 m, and producing an optical film [layer configuration: cellulose acylate film 1 (support)/photo-alignment film 1 (substrate)/cured film 12].

In the obtained cured film 12, a peeling force at an interface with the liquid crystal alignment film was 0.05 N/25 mm, and it was confirmed that, in a case where the cured film 12 was peeled off and measured, a slow axis direction was the longitudinal direction of the film, an in-plane retardation Re(550) was 130 nm, Re(450)/Re(550) was 0.85, and the cured film 12 was a positive A-plate.

### Example 13

A cured film was formed and an optical film was produced by the same method as in Example 1, except that the six kinds of liquid crystal compounds used in the composition 1 for forming a cured film were changed to the following liquid crystal compound R8, and a blending amount thereof was set to 100 parts by mass.

### <Liquid Crystal Compound R8 (Me in the Following Formula Represents a Methyl Group)>

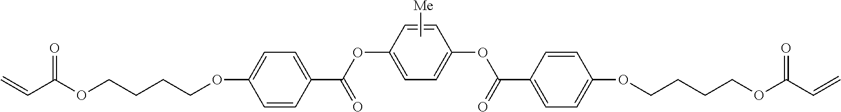

### Example 14

A cured film was formed and an optical film was produced by the same method as in Example 1, except that the six kinds of liquid crystal compounds used in the composition 1 for forming a cured film were changed to the following liquid crystal compound R9, and a blending amount thereof was set to 100 parts by mass.

### <Liquid Crystal Compound R9>

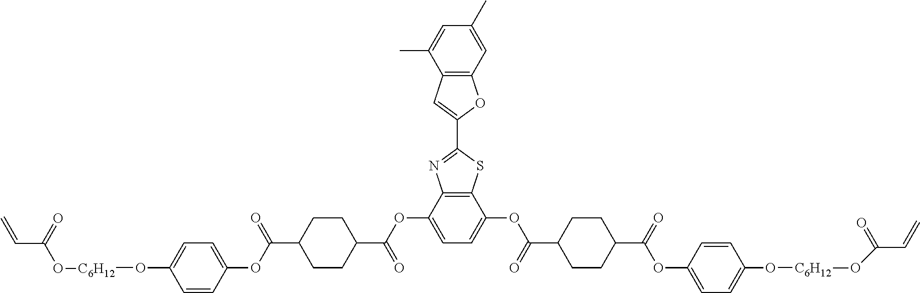

### Example 15

### [Production of Optically Anisotropic Layer 3 (Substrate)]

<Preparation of liquid crystal composition 3>

A liquid crystal composition 3 for forming an optically anisotropic layer, having the following formulation, was prepared.

Liquid crystal composition 3

| | |
|---|---|
| Liquid crystal compound R10 shown below | 42.00 parts by mass |
| Liquid crystal compound R3 shown above | 42.00 parts by mass |
| Liquid crystal compound R11 shown below | 12.00 parts by mass |
| Liquid crystal compound R12 shown below | 4.00 parts by mass |
| Polymerization initiator S1 shown above | 0.50 parts by mass |
| Leveling agent P1-4 shown below | 0.20 parts by mass |
| HISOLVE MTEM (manufactured by TOHO | 2.00 parts by mass |
| Chemical Industry Co., Ltd.) | |
| NK Ester A-200 (manufactured by Shin- | 1.00 part by mass |
| Nakamura Chemical Co., Ltd.) | |
| Methyl ethyl ketone | 424.80 parts by mass |

A group adjacent to the acryloyloxy group of the following liquid crystal compound R10 represents a propylene group (group in which the methyl group is substituted with an ethylene group), and the following liquid crystal compound R10 represents a mixture of regioisomers with different positions of methyl groups.

Liquid crystal compound R10 [Δn(450)/Δn(550): 0.75]

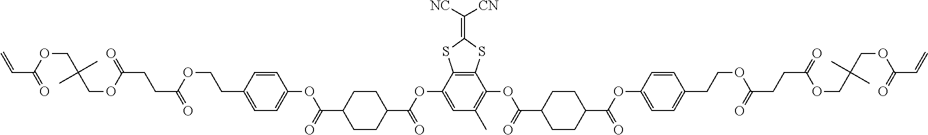 [SMILES: C=CC(=O)OCC(C)(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]

Liquid crystal compound R11 [Δn(450)/Δn(550): 1.03]

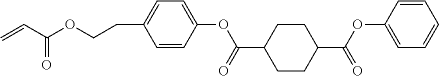 [SMILES: C=CC(=O)OCCc1ccc(OC(=O)C2CCC(C(=O)Oc3ccccc3)CC2)cc1]

Liquid crystal compound R12 [Δn(450)/Δn(550): 1.03]

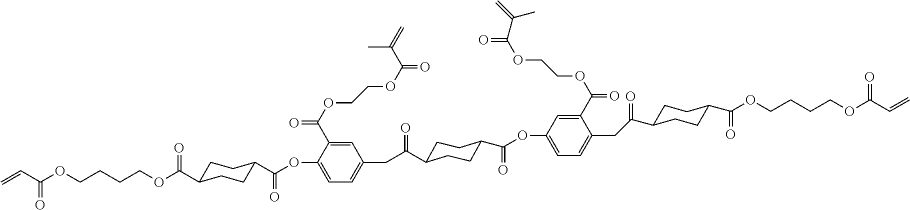 [SMILES: C=CC(=O)OCCCCOC(=O)C1CCC(C(=O)Cc2ccc(OC(=O)C3CCC(C(=O)Cc4ccc(OC(=O)C5CCC(C(=O)OCCCCOC(=O)C=C)CC5)c(C(=O)OCCOC(=O)C(=C)C)c4)CC3)cc2C(=O)OCCOC(=O)C(=C)C)CC1]

Leveling agent P1-4 [32.5 and 67.5 in the following formula indicate the content (% by mass) of each repeating unit with respect to all repeating units in the leveling agent P1-4]

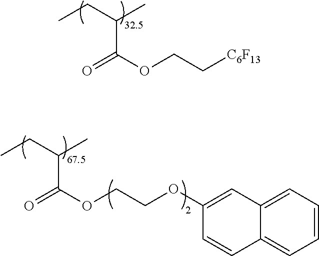

### <Production of Optically Anisotropic Layer 3 (Substrate)>

The photo-alignment film 1 was formed on the cellulose acylate film 1 (support) by the same method as in Example 1.

Next, the liquid crystal composition 3 prepared above was applied onto the photo-alignment film 1 with a die coater to form a composition layer. The formed composition layer was heated to a temperature at which an isotropic phase was exhibited, and then cooled to stabilize the alignment at a temperature at which a smectic phase was exhibited. Thereafter, the alignment was fixed by carrying out ultraviolet irradiation (500 mJ/cm², using an ultra-high pressure mercury lamp) in a nitrogen atmosphere (oxygen concentration: 100 ppm) while maintaining the temperature, thereby forming an optically anisotropic layer 3 (substrate) having a thickness of 2 m.

In the obtained optically anisotropic layer 3, a peeling force at an interface with the liquid crystal alignment film was 0.05 N/25 mm; and in a case where a phase difference of the peeled optically anisotropic layer 3 was measured, it was confirmed that a slow axis direction was a longitudinal direction of the film, an in-plane retardation Re(550) was 130 nm, Re(450)/Re(550) was 0.85, and the optically anisotropic layer 3 was a positive A-plate.

### [Formation of Cured Film 15 (Production of Optical Film)]

<Preparation of composition 15 for forming cured film>

A composition 15 for forming a cured film, having the following formulation, was prepared.

Composition 15 for forming cured film

| | |
|---|---|
| Liquid crystal compound R10 shown above | 10.00 parts by mass |
| Liquid crystal compound R3 shown above | 54.00 parts by mass |
| Liquid crystal compound R7 shown above | 28.00 parts by mass |
| Liquid crystal compound R11 shown above | 8.00 parts by mass |
| Boronic acid monomer B1 | 4.50 parts by mass |
| NK Ester A-600 (manufactured by Shin- | 12.00 parts by mass |
| Nakamura Chemical Co., Ltd.) | |
| Polymerization initiator S1 shown above | 1.50 parts by mass |
| Leveling agent P2-1 shown above | 0.17 parts by mass |
| Methyl ethyl ketone | 225.00 parts by mass |
| Methanol | 25.00 parts by mass |

### <Formation of Cured Film 15>

The surface of the optically anisotropic layer 3 (substrate) on the air-interface side (side opposite to the photo-alignment film 1) was subjected to a corona treatment at a discharge amount of 150 W min/m².

Next, the composition 15 for forming a cured film prepared above was applied onto the surface subjected to the corona treatment with a die coater to form a composition layer. Thereafter, for drying the solvent of the composition and for alignment maturation of the liquid crystal compound, the composition layer was heated at 65° C. for 60 seconds. The alignment was fixed by performing ultraviolet irradiation (150 mJ/cm²) at 50° C. in a nitrogen purge atmosphere with an oxygen concentration of 100 ppm to form a cured film 15 having a thickness of 1.5 m, thereby producing an optical film [layer configuration: cellulose acylate film 1 (support)/photo-alignment film 1/optically anisotropic layer 3 (substrate)/cured film 15].

In a case where a laminate of the optically anisotropic layer 3 and the cured film 15 was peeled off from the produced optical film, a phase difference of the laminate was measured, and the phase difference of the optically anisotropic layer 3 measured in advance was subtracted to calculate a phase difference of the cured film 15, it was confirmed that a thickness direction retardation RthC(550) was −90 nm, RthC(450)/RthC(550) was 0.88, and the cured film 15 was a positive C-plate (nz>nx=ny).

### Example 16

### [Formation of Cured Film 16 (Production of Optical Film)]

<Preparation of composition 16 for forming cured film>

A composition 16 for forming a cured film, having the following formulation, was prepared.

Composition 16 for forming cured film

| | |
|---|---|
| Liquid crystal compound R7 shown above | 100.0 parts by mass |
| Photopolymerization initiator S2 shown above | 5.0 parts by mass |
| Photopolymerization initiator S3 shown above | 2.0 parts by mass |
| Alignment assistant A1 shown above | 2.0 parts by mass |
| Boronic acid monomer B1 shown above | 4.5 parts by mass |
| A-TMMT (manufactured by Shin-Nakamura | 8.0 parts by mass |
| Chemical Co., Ltd.) | |
| Leveling agent P2-1 shown above | 0.5 parts by mass |
| Acetone | 426.0 parts by mass |
| PGMEA | 49.0 parts by mass |
| Methanol | 14.7 parts by mass |

### <Formation of Cured Film 16>

One surface of a cycloolefin polymer film (Re=134 nm, Rth=67 nm, manufactured by JSR Corporation) as a substrate was subjected to a corona treatment at a discharge amount of 125 W min/m², and the composition 16 for forming a cured film prepared above was applied onto the surface subjected to the corona treatment with a #3.6 wire bar.

Next, for drying the solvent of the composition and for alignment maturation of the liquid crystal compound, the composition was heated with hot air at 70° C. for 90 seconds, and then ultraviolet irradiation (300 mJ/cm²) was carried out at 40° C. in a nitrogen purge atmosphere with an oxygen concentration of 0.1% to fix an alignment of the liquid crystal compound and to form a cured film 16, thereby producing an optical film [layer configuration: COP film (substrate)/cured film 16].

In a case where a phase difference of the optical film was measured, an in-plane retardation Re(550) was 134 nm, and a thickness direction retardation Rth(550) was −28 nm. In addition, Re(450)/Re(550) was 1.01 and Rth(450)/Rth(550) was 1.06. That is, it was confirmed that an in-plane retardation Re(550) of the cured film 16 was 0 nm, a thickness direction retardation Rth(550) was −95 nm, and the cured film 16 was a positive C-plate (nz>nx=ny).

### Example 17

### [Formation of Cured Film 17 (Production of Optical Film)]

The composition 15 for forming a cured film prepared in Example 15 was applied onto one surface of the support with a die coater in a state in which a commercially available product of a polycarbonate film (PURE ACE RM-147, Re(550)=146 nm, Rth(550)=111 nm, manufactured by Teijin Limited), which had been subjected to a biaxial stretching treatment, was not subjected to a surface treatment.

Next, for drying the solvent of the composition and for alignment maturation of the liquid crystal compound, the film was heated for 60 seconds with hot air at 60° C. Ultraviolet irradiation (300 mJ/cm²) was carried out at 25° C. in a nitrogen purge atmosphere with an oxygen concentration of 100 ppm to fix the alignment of the liquid crystal compound, thereby forming a cured film 17 and producing an optical film [layer configuration: polycarbonate film (substrate)/cured film 17].

As a result of estimating optical characteristics of the cured film 17 from a change amount in optical characteristics before and after the application, it was confirmed that the cured film 17 had Re(550)=0 nm, Rth(550)=−120 nm, and Rth(450)/Rth(550)=0.93, and that the cured film 17 was a positive C-plate (nz>nx=ny).

### Example 18

A cured film was formed and an optical film was produced by the same method as in Example 1, except that the type and content (parts by mass) of the leveling agent contained in the composition for forming a cured film were set to the type and content shown in Table 2.

### Example 19

A cured film was formed and an optical film was produced by the same method as in Example 15, except that the type and content (parts by mass) of the leveling agent contained in the composition for forming a cured film were set to the type and content shown in Table 2.

### Example 20

A cured film was formed and an optical film was produced by the same method as in Example 11, except that the type and content (parts by mass) of the leveling agent contained in the composition for forming a cured film were set to the type and content shown in Table 2.

### Example 21

A cured film was formed and an optical film was produced by the same method as in Example 16, except that the type and content (parts by mass) of the leveling agent contained in the composition for forming a cured film were set to the type and content shown in Table 2.

### Example 22

A cured film was formed and an optical film was produced by the same method as in Example 17, except that the type and content (parts by mass) of the leveling agent contained in the composition for forming a cured film were set to the type and content shown in Table 2.

### Example 23

A cured film was formed and an optical film was produced by the same method as in Example 11, except that the type and content (parts by mass) of the leveling agent contained in the composition for forming a cured film were set to the type and content shown in Table 2.

### Example 24

### [Production of Optically Anisotropic Layer 4]

<Preparation of liquid crystal composition 4>

A liquid crystal composition 4 for forming an optically anisotropic layer, having the following formulation, was prepared.

Liquid crystal composition 4

| | |
|---|---|
| Liquid crystal compound R7 shown above | 100.0 parts by mass |
| Photopolymerization initiator S2 shown above | 5.0 parts by mass |
| Photopolymerization initiator S3 shown above | 2.0 parts by mass |
| Alignment assistant A1 shown above | 2.0 parts by mass |
| Boronic acid monomer B1 shown above | 4.5 parts by mass |
| A-TMMT (manufactured by Shin-Nakamura | 8.0 parts by mass |
| Chemical Co., Ltd.) shown above | |
| Leveling agent P2-1 shown above | 0.75 parts by mass |
| Acetone | 426.0 parts by mass |
| PGMEA | 49.0 parts by mass |
| Methanol | 14.7 parts by mass |

### <Production of Optically Anisotropic Layer 4>

One surface of a cycloolefin polymer (COP) film (Re=125 nm, Rth=63 nm, manufactured by JSR Corporation) was subjected to a corona treatment at a discharge amount of 125 W min/m², and the liquid crystal composition 4 prepared above was applied onto the surface subjected to the corona treatment with a #3.0 wire bar.

Next, for drying the solvent of the composition and for alignment maturation of the liquid crystal compound, the composition was heated with hot air at 70° C. for 90 seconds, and then ultraviolet irradiation (300 mJ/cm²) was carried out at 40° C. under nitrogen purge at an oxygen concentration of 0.1% to fix the alignment of the liquid crystal compound, thereby producing an optically anisotropic layer 4.

In a case where a phase difference of the laminate of the obtained optically anisotropic layer 4 and the COP film was measured, an in-plane retardation Re(550) was 125 nm, and a thickness direction retardation Rth(550) was −25 nm. In addition, Re(450)/Re(550) was 1.01 and Rth(450)/Rth(550) was 1.06.

### [Formation of Cured Film 24 (Production of Optical Film)]

<Preparation of composition 24 for forming cured film>

A composition 24 for forming a cured film, having the following formulation, was prepared.

Composition 24 for forming cured film

| | |
|---|---|
| A-TMMT (manufactured by Shin-Nakamura | 71.8 parts by mass |
| Chemical Co., Ltd.) shown above | |
| A-600 (manufactured by Shin-Nakamura | 23.9 parts by mass |
| Chemical Co., Ltd.) shown above | |
| Boronic acid monomer B1 shown above | 4.3 parts by mass |
| Photopolymerization initiator S2 shown above | 5.0 parts by mass |
| Leveling agent P2-1 shown above | 0.35 parts by mass |
| Acetone | 382.8 parts by mass |
| PGMEA | 44.0 parts by mass |
| Methanol | 13.2 parts by mass |

### <Formation of Cured Film 24>

The surface of the COP film (substrate) opposite to the optically anisotropic layer 4 was subjected to a corona treatment at a discharge amount of 125 W min/m².

Next, the composition 24 for forming a cured film prepared above was applied onto the surface subjected to the corona treatment with a #3.0 wire bar.

Next, for drying the solvent of the composition, the composition was heated with hot air at 70° C. for 90 seconds, and then ultraviolet irradiation (300 mJ/cm²) was carried out at 40° C. in a nitrogen purge atmosphere with an oxygen concentration of 0.1% to form a cured film 24, thereby producing an optical film [layer configuration: optically anisotropic layer 4/COP film (substrate)/cured film 24].

In a case where a phase difference of the optical film was measured, an in-plane retardation Re(550) was 125 nm, and a thickness direction retardation Rth(550) was −25 nm. In addition, Re(450)/Re(550) was 1.01, Rth(450)/Rth(550) was 1.06, and a change A in phase difference from the laminate of the optically anisotropic layer 4 and the COP film was ΔRe=0 nm and ΔRth=0 nm.

### [Evaluation]

### (1) Surface Elastic Modulus of Cured Film

A surface elastic modulus of the cured film produced in Examples 1 to 24 and Comparative Examples 1 and 2 was measured by the above-described method. The results are shown in Tables 1 and 2.

### (2) Change Amount of Surface Elastic Modulus of Composition

Regarding the leveling agent blended in the composition for forming a cured film prepared in Examples 1 to 24 and Comparative Examples 1 and 2, the surface elastic modulus E¹⁰⁰ (unit: kPa) of the above-described composition Si and the surface elastic modulus E⁵⁰ (unit: kPa) of the above-described composition S2 were measured by the above-described method, and the change amount (E⁵⁰-E¹⁰⁰) was calculated. The results are shown in Tables 1 and 2.

### (3) Surface Unevenness

The cured films produced in Examples 1 to 24 and Comparative Examples 1 and 2 (hereinafter abbreviated as “cured film X” in this paragraph), and the cured films produced by subjecting the composition for forming a cured film prepared in Examples 1 to 24 and Comparative Examples 1 and 2 to forced drying under the following conditions (hereinafter abbreviated as “cured film Y” in this paragraph) were each inserted between polarizing plates. The samples were observed under crossed Nicols and evaluated according to the following standard. The results are shown in Tables 1 and 2.

### (Conditions for Forced Drying)

After the application using a die coater, drying was carried out under a wind speed condition of 0.5 m/s.

### <Evaluation Standard>

AA: no unevenness was visually recognized in either the cured film X or the cured film Y.

A: unevenness was visually recognized in the cured film Y, but unevenness was not visually recognized in the cured film X.

B: unevenness was visually recognized in the cured film X, but an area thereof was less than 10%.

C: unevenness was visually recognized in the cured film X, and an area thereof was 10% or more.

### (4) Adhesiveness to Adjacent Layer

A cellulose acylate film (manufactured by FUJIFILM Corporation, FUJITAC TD40ULC) was immersed in a 1.5 mol/L sodium hydroxide aqueous solution (saponification solution) adjusted to 37° C. for 1 minute, and the film was washed with water, immersed in a 0.05 mol/L sulfuric acid aqueous solution for 30 seconds, and then further washed with water. After repeating water removal with an air knife three times and allowing the excess water to drip off, the film was dried by being held in a drying zone at 70° C. for 15 seconds, thereby producing a saponified cellulose acylate film.

Next, according to Example 1 of JP2001-141926A, a polarizer having a thickness of 12 m was produced by applying a difference in circumferential speed between two pairs of nip rolls and stretching in the longitudinal direction.

Next, after placing the polarizer produced above between the cured film produced in Examples 1 to 17 and Comparative Examples 1 and 2 and the saponified cellulose acylate film produced above, lamination was carried out in a roll-to-roll manner using a 3% aqueous solution of polyvinyl alcohol (manufactured by Kuraray Co., Ltd., PVA-117H) as an adhesive so that the absorption axis of the polarizer was parallel to the longitudinal directions of the film and the cured film (layer configuration: cured film/polyvinyl alcohol/polarizer/polyvinyl alcohol/cellulose acylate film).

Here, the polarizer was disposed such that, on one side thereof, the coated surface of the above-described cured film faced the polarizer, and on the other side thereof, the above-described cellulose acylate film was provided.

Next, in Examples 1 to 10, 12 to 15, 18, and 19 and Comparative Examples 1 and 2, the polarizing plate for evaluation was produced by peeling off the cellulose acylate film on the cured film side after curing by drying at 70° C. for 10 minutes after the lamination.

In addition, in Examples 11, 16, 17, and 20 to 24, the polarizing plate for evaluation was produced by curing by drying at 70° C. for 10 minutes after the lamination.

For the produced polarizing plate, 100 grid marks were made on the surface of the produced cured film at 1 mm intervals, and an adhesion test was performed using cellophane tape (manufactured by NICHIBAN Co., Ltd.). After sticking a new cellophane tape, the peeling was determined according to the following standard. The grid marks were made by cutting from the cured film side until the cuts reached the surface of the polarizer. The results are shown in Tables 1 and 2.

A: no peeling occurred in any of squares in the grid marks.

B: squares of the grid marks which did not peel off were 50% or more and less than 100%.

C: squares of the grid marks which did not peel off were less than 50%.

TABLE 1

| | | Composition for forming cured film | | | | | | | | | | | | | | | | | |
|---|---|---|---|---|---|---|---|---|---|---|---|---|---|---|---|---|---|---|---|
| | | Leveling agent | | | | | | | | | | | | | | | | | |
| | | | Repeating unit A | | Repeating unit B | | Repeating unit C | | Repeating unit D | | | | | | | | | | |
| | | | | Compo- | | Compo- | | Compo- | | Compo- | | | | | | | Change | Performance | |
| | | | | sitional | | sitional | | sitional | | sitional | | Weight- | | | | | amount | | Adhesive- |
| | | | | ratio | | ratio | | ratio | | ratio | | average | | Surface | | | (E⁵⁰ − | Surface | ness |
| | | | | (% by | | (% by | | (% by | | (% by | | molecular | Part by | elastic | E¹⁰⁰ | E⁵⁰ | E¹⁰⁰) | uneven- | to adjacent |
| | Substrate | Name | Type | mass) | Type | mass) | Type | mass) | Type | mass) | a/b | weight | mass | modulus | (kPa) | (kPa) | [kPa] | ness | layer |
| Example 1 | Optically | P-2-1 | a1 | 55 | b1 | 29 | c1 | 16 | d1 | 0 | 1.90 | 36500 | 0.21 | 5.2 | 0.56 | 1.21 | 0.65 | A | A |
| | anisotropic | | | | | | | | | | | | | | | | | | |
| | layer 1 | | | | | | | | | | | | | | | | | | |
| Example 2 | Optically | P-2-9 | a1 | 35 | b1 | 49 | c1 | 16 | d1 | 0 | 0.71 | 20900 | 0.5 | 9.2 | 0.80 | 1.65 | 0.85 | C | A |
| | anisotropic | | | | | | | | | | | | | | | | | | |
| | layer 1 | | | | | | | | | | | | | | | | | | |
| Example 3 | Optically | P-2-2 | a1 | 65 | b1 | 19 | c1 | 16 | d1 | 0 | 3.42 | 28500 | 0.21 | 3.9 | 0.56 | 1.18 | 0.62 | A | B |
| | anisotropic | | | | | | | | | | | | | | | | | | |
| | layer 1 | | | | | | | | | | | | | | | | | | |
| Example 4 | Optically | P-2-3 | a1 | 45 | b1 | 39 | c1 | 16 | d1 | 0 | 1.15 | 30900 | 0.21 | 6.2 | 0.78 | 1.56 | 0.78 | B | A |
| | anisotropic | | | | | | | | | | | | | | | | | | |
| | layer 1 | | | | | | | | | | | | | | | | | | |
| Example 5 | Optically | P-2-4 | a1 | 70 | b1 | 25 | c1 | 0 | d1 | 5 | 2.80 | 36200 | 0.21 | 5 | 0.56 | 1.21 | 0.65 | A | B |
| | anisotropic | | | | | | | | | | | | | | | | | | |
| | layer 1 | | | | | | | | | | | | | | | | | | |
| Example 6 | Optically | P-2-5 | a1 | 55 | b1 | 29 | c1 | 16 | d1 | 0 | 1.90 | 12000 | 0.21 | 4.1 | 0.56 | 1.21 | 0.65 | A | B |
| | anisotropic | | | | | | | | | | | | | | | | | | |
| | layer 1 | | | | | | | | | | | | | | | | | | |
| Example 7 | Optically | P-2-6 | a1 | 55 | b1 | 29 | c1 | 16 | d1 | 0 | 1.90 | 41000 | 0.21 | 5.8 | 0.56 | 1.21 | 0.65 | B | A |
| | anisotropic | | | | | | | | | | | | | | | | | | |
| | layer 1 | | | | | | | | | | | | | | | | | | |
| Example 8 | Optically | P-2-1 | a1 | 55 | b1 | 29 | c1 | 16 | d1 | 0 | 1.90 | 36500 | 0.05 | 6 | 0.56 | 1.21 | 0.65 | B | A |
| | anisotropic | | | | | | | | | | | | | | | | | | |
| | layer 1 | | | | | | | | | | | | | | | | | | |
| Example 9 | Optically | P-2-1 | a1 | 55 | b1 | 29 | c1 | 16 | d1 | 0 | 1.90 | 36500 | 3 | 4.2 | 0.56 | 1.21 | 0.65 | A | B |
| | anisotropic | | | | | | | | | | | | | | | | | | |
| | layer 1 | | | | | | | | | | | | | | | | | | |
| Example 10 | Optically | P-2-7 | a2 | 55 | b1 | 29 | c1 | 16 | d1 | 0 | 1.90 | 20000 | 0.21 | 5.1 | 0.56 | 1.20 | 0.64 | A | A |
| | anisotropic | | | | | | | | | | | | | | | | | | |
| | layer 1 | | | | | | | | | | | | | | | | | | |
| Comparative | Optically | P-1-2 | a3 | 65 | b1 | 18.5 | c1 | 10 | d1 | 6.5 | 3.51 | 13100 | 0.6 | 2.9 | 0.59 | 1.09 | 0.51 | A | C |
| Example 1 | anisotropic | P-1-3 | a4 | (90/40) | | (0/37) | | (0/20) | | (10/3) | | (15000/ | (0.3/0.3) | | | | | | |
| | layer 1 | | | | | | | | | | | 11200) | | | | | | | |
| Comparative | Optically | P-2-8 | a1 | 78 | b1 | 14 | c1 | 8 | d1 | 0 | 5.57 | 25500 | 0.5 | 1.8 | 0.56 | 1.21 | 0.65 | A | C |
| Example 2 | anisotropic | | | | | | | | | | | | | | | | | | |
| | layer 1 | | | | | | | | | | | | | | | | | | |

TABLE 2

| | | Composition for forming cured film | | | | | | | | | | | | | | | | | |
|---|---|---|---|---|---|---|---|---|---|---|---|---|---|---|---|---|---|---|---|
| | | Leveling agent | | | | | | | | | | | | | | | | | |
| | | | Repeating unit A | | Repeating unit B | | Repeating unit C | | Repeating unit D | | | | | | | | | | |
| | | | | Compo- | | Compo- | | Compo- | | Compo- | | | | | | | Change | Performance | |
| | | | | sitional | | sitional | | sitional | | sitional | | Weight- | | | | | amount | | Adhesive- |
| | | | | ratio | | ratio | | ratio | | ratio | | average | | Surface | | | (E⁵⁰ − | Surface | ness |
| | | | | (% by | | (% by | | (% by | | (% by | | molecular | Part by | elastic | E¹⁰⁰ | E⁵⁰ | E¹⁰⁰) | uneven- | to adjacent |
| | Substrate | Name | Type | mass) | Type | mass) | Type | mass) | Type | mass) | a/b | weight | mass | modulus | (kPa) | (kPa) | [kPa] | ness | layer |
| Example | COP film | P-2-1 | a1 | 55 | b1 | 29 | c1 | 16 | d1 | 0 | 1.90 | 36500 | 0.5 | 5.2 | 0.56 | 1.21 | 0.65 | B | A |
| 11 | | | | | | | | | | | | | | | | | | | |
| Example | Photo- | P-2-1 | a1 | 55 | b1 | 29 | c1 | 16 | d1 | 0 | 1.90 | 36500 | 0.21 | 5.2 | 0.56 | 1.21 | 0.65 | B | A |
| 12 | alignment | | | | | | | | | | | | | | | | | | |
| | film 1 | | | | | | | | | | | | | | | | | | |
| Example | Optically | P-2-1 | al | 55 | b1 | 29 | c1 | 16 | d1 | 0 | 1.90 | 36500 | 0.21 | 5.2 | 0.56 | 1.21 | 0.65 | B | A |
| 13 | anisotropic | | | | | | | | | | | | | | | | | | |
| | layer 1 | | | | | | | | | | | | | | | | | | |
| Example | Optically | P-2-1 | a1 | 55 | b1 | 29 | c1 | 16 | d1 | 0 | 1.90 | 36500 | 0.21 | 5.2 | 0.56 | 1.21 | 0.65 | A | A |
| 14 | anisotropic | | | | | | | | | | | | | | | | | | |
| | layer 1 | | | | | | | | | | | | | | | | | | |
| Example | Optically | P-2-1 | a1 | 55 | b1 | 29 | c1 | 16 | d1 | 0 | 1.90 | 36500 | 0.17 | 5.2 | 0.56 | 1.21 | 0.65 | A | A |
| 15 | anisotropic | | | | | | | | | | | | | | | | | | |
| | layer 3 | | | | | | | | | | | | | | | | | | |
| Example | COP film | P-2-1 | a1 | 55 | b1 | 29 | c1 | 16 | d1 | 0 | 1.90 | 36500 | 0.5 | 5.2 | 0.56 | 1.21 | 0.65 | B | A |
| 16 | | | | | | | | | | | | | | | | | | | |
| Example | Poly- | P-2-1 | a1 | 55 | b1 | 29 | c1 | 16 | d1 | 0 | 1.90 | 36500 | 0.17 | 5.2 | 0.56 | 1.21 | 0.65 | A | A |
| 17 | carbonate | | | | | | | | | | | | | | | | | | |
| | film | | | | | | | | | | | | | | | | | | |
| Example | Optically | P-2-10 | a2 | 63 | b1 | 29 | c1 | 8 | d1 | 0 | 2.17 | 18700 | 0.21 | 5.1 | 0.57 | 0.67 | 0.10 | AA | A |
| 18 | anisotropic | | | | | | | | | | | | | | | | | | |
| | layer 1 | | | | | | | | | | | | | | | | | | |
| Example | Optically | P-2-10 | a2 | 63 | b1 | 29 | c1 | 8 | d1 | 0 | 2.17 | 18700 | 0.17 | 5.0 | 0.57 | 0.67 | 0.10 | AA | A |
| 19 | anisotropic | | | | | | | | | | | | | | | | | | |
| | layer 3 | | | | | | | | | | | | | | | | | | |
| Example | COP film | P-2-10 | a2 | 63 | b1 | 29 | c1 | 8 | d1 | 0 | 2.17 | 18700 | 0.50 | 5.2 | 0.57 | 0.67 | 0.10 | AA | A |
| 20 | | | | | | | | | | | | | | | | | | | |
| Example | COP film | P-2-10 | a2 | 63 | b1 | 29 | c1 | 8 | d1 | 0 | 2.17 | 18700 | 0.50 | 5.1 | 0.57 | 0.67 | 0.10 | AA | A |
| 21 | | | | | | | | | | | | | | | | | | | |
| Example | Poly- | P-2-10 | a2 | 63 | b1 | 29 | c1 | 8 | d1 | 0 | 2.17 | 18700 | 0.17 | 5.2 | 0.57 | 0.67 | 0.10 | AA | A |
| 22 | carbonate | | | | | | | | | | | | | | | | | | |
| | film | | | | | | | | | | | | | | | | | | |
| Example | COP film | P-2-7 | a2 | 55 | b1 | 29 | c1 | 16 | d1 | 0 | 1.90 | 20000 | 0.5 | 5.1 | 0.56 | 1.20 | 0.64 | B | A |
| 23 | | | | | | | | | | | | | | | | | | | |
| Example | COP film | P-2-1 | a1 | 55 | b1 | 29 | c1 | 16 | d1 | 0 | 1.90 | 36500 | 0.35 | 5.2 | 0.56 | 1.21 | 0.65 | B | A |
| 24 | | | | | | | | | | | | | | | | | | | |

In Tables 1 and 2, structures of the liquid crystal compound, the boronic acid monomer, the alignment assistant, the monomer 1, the monomer 2, and the compound used as the polymerization initiator are as described above, and structures of repeating units constituting the leveling agent are shown below.

### Repeating Unit a1

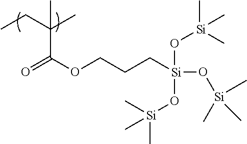

### Repeating Unit a2

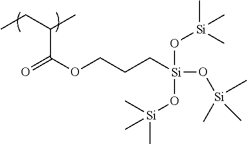

### Repeating Unit a3 (Used in Comparative Example 1)

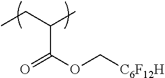

### Repeating Unit a4 (Used in Comparative Example 1)

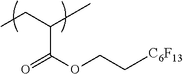

### Repeating Unit b1

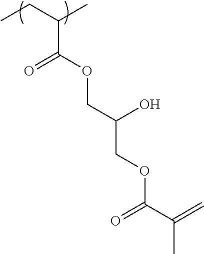

### Repeating Unit c1

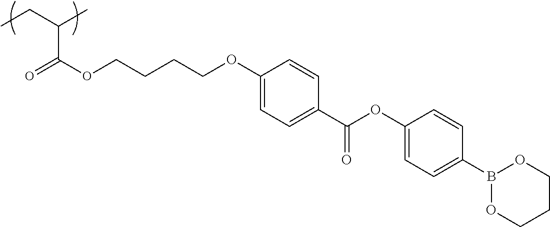

### Repeating Unit d1

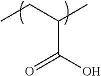

From the results shown in Tables 1 and 2, it was found that, in a case where the surface elastic modulus (X) on the surface X of the cured film was 3.0 GPa or less, the adhesiveness to the adjacent layer provided on the surface X of the cured film was deteriorated (Comparative Examples 1 and 2).

On the other hand, it was found that, in a case where the surface elastic modulus (X) on the surface X of the cured film was more than 3.0 GPa, the adhesiveness to the adjacent layer provided on the surface X of the cured film was improved (Examples 1 to 24).

In particular, from the comparison of Examples 1 to 4, it was found that, in a case where the surface elastic modulus (X) on the surface X of the cured film was less than 9.0 GPa, the surface unevenness of the cured film was suppressed; and in a case where the surface elastic modulus (X) on the surface X of the cured film was 6.0 GPa or less, the surface unevenness of the cured film was further suppressed. In addition, it was found that, in a case where the surface elastic modulus (X) on the surface X of the cured film was 4.0 GPa or more, the adhesiveness to the adjacent layer provided on the surface X of the cured film was further improved. Similarly, from the comparison of Examples 1 to 4, it was found that, in a case where the mass ratio (a/b) of the content a of the above-described repeating unit A to the content b of the above-described repeating unit B in the leveling agent was more than 1.2 and less than 3.4, the surface unevenness of the cured film was suppressed, and the adhesiveness to the adjacent layer provided on the surface X of the cured film was further improved.

In addition, from the comparison of Example 1 and Example 5, it was found that, in a case where the leveling agent had the repeating unit C containing a mesogen group and a functional group capable of forming a covalent bond complex with a hydroxyl group, the adhesiveness to the adjacent layer provided on the surface X of the cured film was further improved.

In addition, from the comparison of Example 1 and Examples 6 and 7, it was found that, in a case where the weight-average molecular weight of the leveling agent was 15,000 to 40,000, the surface unevenness of the cured film was suppressed, and the adhesiveness to the adjacent layer provided on the surface X of the cured film was further improved.

In addition, from the comparison of Example 1 and Examples 8 and 9, it was found that, in a case where the content of the leveling agent was 0.1 parts by mass or more and 2 parts by mass or less with respect to 100 parts by mass of the polymerizable compound, the surface unevenness of the cured film was suppressed, and the adhesiveness to the adjacent layer provided on the surface X of the cured film was further improved.

In addition, from the comparison of Example 1 and Example 11, it was found that, in a case where the polymerizable compound was a polymerizable liquid crystal compound (that is, a liquid crystal compound having a polymerizable group), the surface unevenness of the cured film was suppressed.

In addition, from the comparison of Example 1 and Example 12, it was found that, in a case where the cured film was a liquid crystal cured layer obtained by immobilizing the polymerizable liquid crystal compound in a vertically aligned state, the surface unevenness of the cured film was suppressed.

In addition, from the comparison of Example 1 and Example 18, the comparison of Example 15 and Example 19, the comparison of Example 16 and Example 21, the comparison of Example 17 and Example 22, and the comparison of Example 11 and Example 23, it was found that, in a case where the change amount (E⁵⁰-E¹⁰⁰) of the surface elastic modulus E¹⁰⁰ (unit: kPa) and the surface elastic modulus E⁵⁰ (unit: kPa) was 0.5 kPa or less, the surface unevenness of the cured film was suppressed.

What is claimed is:

1. A cured film which is provided on a substrate, and is a film obtained by curing a composition containing a leveling agent containing a silicon atom and a polymerizable compound,
wherein a surface elastic modulus on a surface of the cured film opposite to the substrate is more than 3.0 GPa.

2. The cured film according to claim 1,
wherein the surface elastic modulus is less than 9.0 GPa.

3. The cured film according to claim 1,
wherein the surface elastic modulus is 4.0 GPa or more and 6.0 GPa or less.

4. The cured film according to claim 1,
wherein the leveling agent is a copolymer having a repeating unit A containing a silicon atom and a repeating unit B containing a polymerizable group.

5. The cured film according to claim 4,
wherein a mass ratio of a content a of the repeating unit A to a content b of the repeating unit B satisfies the following expression (A),
$$1. 2 < a / b < 3.4 . \qquad ( A )$$

6. The cured film according to claim 4,
wherein the copolymer further has a repeating unit C containing a mesogen group.

7. The cured film according to claim 6,
wherein the repeating unit C further contains a functional group capable of forming a covalent bond complex with a hydroxyl group.

8. The cured film according to claim 7,
wherein, with respect to a total mass of the copolymer, a content a of the repeating unit A is 50% to 60% by mass, a content b of the repeating unit B is 24% to 34% by mass, and a content c of the repeating unit C is 11% to 21% by mass.

9. The cured film according to claim 1,
wherein a weight-average molecular weight of the leveling agent is 15,000 or more and 40,000 or less.

10. The cured film according to claim 1,
wherein a content of the leveling agent is 0.1 parts by mass or more and 2 parts by mass or less with respect to 100 parts by mass of the polymerizable compound.

11. The cured film according to claim 1,
wherein the polymerizable compound is a polymerizable liquid crystal compound.

12. The cured film according to claim 11,
wherein the cured film is a film obtained by immobilizing the polymerizable liquid crystal compound in a vertically aligned state.

13. The cured film according to claim 11,
wherein the polymerizable liquid crystal compound is a compound represented by Formula (I), 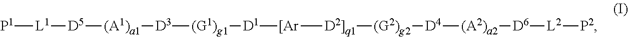
in Formula (I),
a1, a2, g1, and g2 each independently represent 0 or 1,
provided that at least one of a1 or g1 represents 1 and at least one of a2 or g2 represents 1,
q1 represents 1 or 2,
D¹, D², D³, D⁴, D⁵, and D⁶ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms, provided that, in a case where q1 is 2, a plurality of D²'s may be the same or different from each other,
G¹ and G2 each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be replaced with —O—, —S—, or —NH—,
A¹ and A² each independently represent an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be replaced with —O—, —S—, or —NH—,
L¹ and L² each independently represent a single bond or a divalent aliphatic hydrocarbon group having 1 to 20 carbon atoms, provided that one or more of —CH₂-'s constituting the aliphatic hydrocarbon group may be replaced with —O—, —S—, —NH—, —N(Q)-, or —CO—, Q represents a substituent,
P¹ and P² each independently represent a monovalent organic group, where at least one of P¹ or P² represents a polymerizable group, and
Ar represents an aromatic ring having 6 to 20 carbon atoms, which may have a substituent, or a divalent alicyclic hydrocarbon group having 5 to 20 carbon atoms, which may have a substituent, where one or more of —CH₂-'s constituting the alicyclic hydrocarbon group may be replaced with —O—, —S—, or —NH—, provided that, in a case where q1 is 2, a plurality of Ar's may be the same or different from each other.

14. The cured film according to claim 13,
wherein Ar in Formula (I) represents any aromatic ring selected from the group consisting of groups represented by Formulae (Ar-1) to (Ar-5), 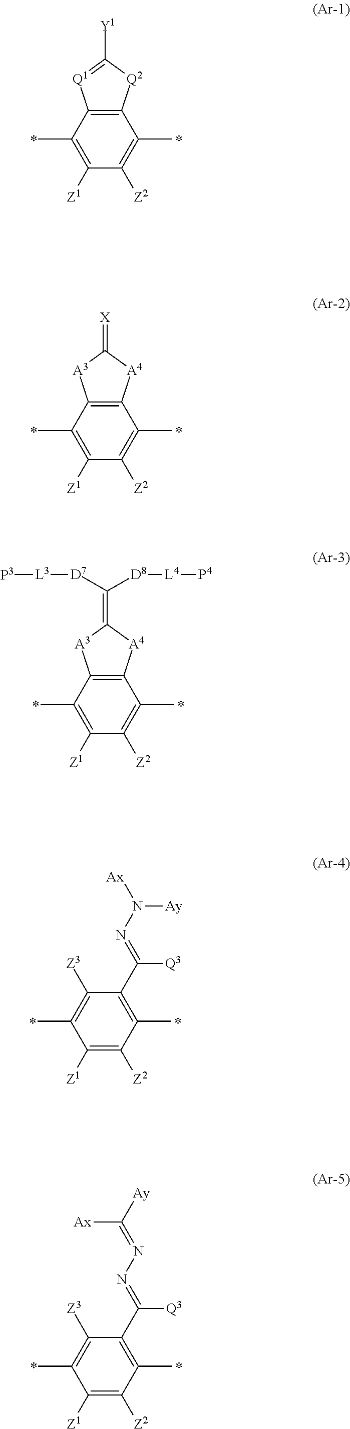
in Formulae (Ar-1) to (Ar-5),
* represents a bonding position,
Q¹ represents N or CH,
Q² represents —S—, —O—, or —N(R⁶)—, where R⁶ represents a hydrogen atom or an alkyl group having 1 to 6 carbon atoms,
Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, where one or more of —CH₂-'s constituting the alicyclic hydrocarbon group may be replaced with —O—, —S—, or —NH—,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —NR⁸R⁹, —SR¹⁰, —COOR¹¹, or —COR¹², where R⁷ to R¹² each independently represent a hydrogen atom or an alkyl group having 1 to 6 carbon atoms and Z¹ and Z² may be bonded to each other to form an aromatic ring,
A³ and A⁴ each independently represent a group selected from the group consisting of —O—, —N(R¹³)—, —S—, and —CO—, where R¹³ represents a hydrogen atom or a substituent,
X represents a non-metal atom of Groups 14 to 16, where a hydrogen atom or a substituent may be bonded to the non-metal atom,
D⁷ and D⁸ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms,
L³ and L⁴ each independently represent a single bond or a divalent aliphatic hydrocarbon group having 1 to 20 carbon atoms, where one or more of —CH₂-'s constituting the aliphatic hydrocarbon group may be replaced with —O—, —S—, —NH—, —N(Q)-, or —CO—, Q represents a substituent,
P³ and P⁴ each independently represent a monovalent organic group, where at least one of P³ or P⁴ represents a polymerizable group,
Ax represents an organic group having 2 to 30 carbon atoms, which has at least one aromatic ring selected from the group consisting of an aromatic hydrocarbon ring and an aromatic heterocyclic ring,
Ay represents a hydrogen atom, an alkyl group having 1 to 12 carbon atoms, which may have a substituent, or an organic group having 2 to 30 carbon atoms, which has at least one aromatic ring selected from the group consisting of an aromatic hydrocarbon ring and an aromatic heterocyclic ring,
where the aromatic rings in Ax and Ay may have a substituent, and Ax and Ay may be bonded to each other to form a ring, and
Q³ represents a hydrogen atom or an alkyl group having 1 to 20 carbon atoms, which may have a substituent.

15. The cured film according to claim 11,
wherein the polymerizable liquid crystal compound is a rod-like liquid crystal compound, and
a difference Δn in refractive index between a major axis direction and a minor axis direction of the rod-like liquid crystal compound satisfies the following expression (II),
$$Δ n ( 450 ) / Δ n ( 550 ) < 1. , \qquad ( II )$$
in the expression (II), Δn(450) represents a difference in refractive index at 450 nm, and Δn(550) represents a difference in refractive index at 550 nm.

16. The cured film according to claim 1,
wherein E¹⁰⁰ (unit: kPa) representing a surface elastic modulus of the following composition Si containing the leveling agent and E⁵⁰ (unit: kPa) representing a surface elastic modulus of the following composition S2 containing the leveling agent satisfy the following expression (P),
$${E}^{50} - {E}^{100} \leq 0.5 kPa , \qquad ( P )$$
the composition Si:
a composition containing 100.0 parts by mass of the following liquid crystal compound X, 426.0 parts by mass of acetone, and 0.5 parts by mass of the leveling agent,
the composition S2:
a composition containing 100.0 parts by mass of the following liquid crystal compound X, 160.0 parts by mass of acetone, and 0.5 parts by mass of the leveling agent,
the liquid crystal compound X:
a mixture obtained by mixing the following liquid crystal compounds (RA), (RB), and (RC) at a mass ratio of 83:15:2 (Me in Formulae (RB) and (RC) represents a methyl group),

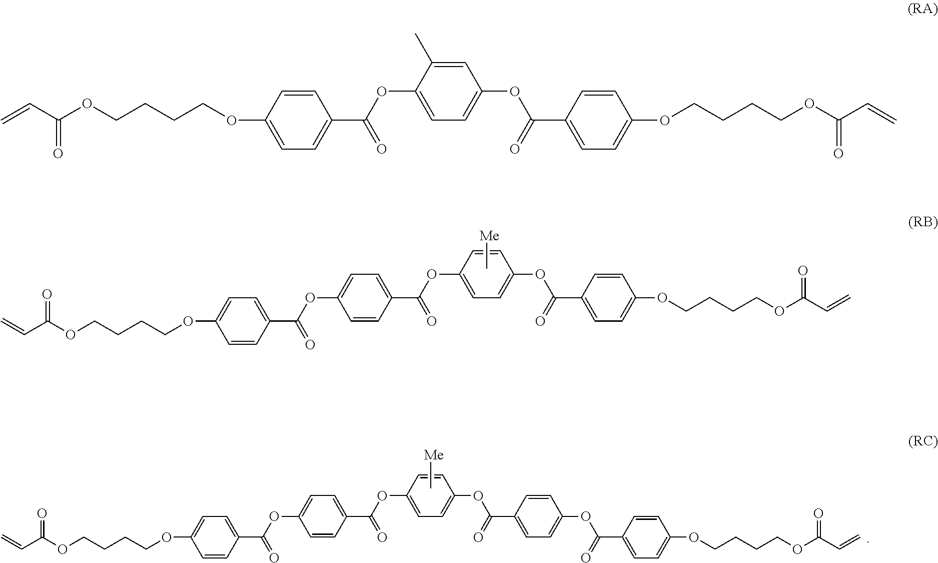

17. An optical film comprising:
the cured film according to claim 1.

18. An image display device comprising:
the optical film according to claim 17.

19. The image display device according to claim 18,
wherein the image display device is a liquid crystal display device.

20. The image display device according to claim 18,
wherein the image display device is an organic electroluminescent display device.
